(19) United States
(12) Patent Application Publication
(10) Pub. No.: US 2022/0359157 A1
(43) Pub. Date: Nov. 10, 2022

(54) SYSTEM AND PROCESS IMPLEMENTING A WIDE RIBBON BEAM ION SOURCE TO IMPLANT IONS IN MATERIAL TO MODIFY MATERIAL PROPERTIES

(71) Applicant: Malachite Technologies, Inc., San Francisco, CA (US)

(72) Inventors: Alexander David WELSH, San Francisco, CA (US); Robert WEISS, San Francisco, CA (US); David BROWN, San Francisco, CA (US); Nicholas WHITE, Manchester, MA (US)

(21) Appl. No.: 17/737,079

(22) Filed: May 5, 2022

Related U.S. Application Data
(60) Provisional application No. 63/184,454, filed on May 5, 2021.

(51) Int. Cl. H01J 37/317; H01J 37/08

(52) U.S. Cl. CPC H01J 37/3171; H01J 37/08; H01J 2237/24585

(57) ABSTRACT

A treatment system and process includes a ribbon beam ion source that is configured to implant ions into a product to modify a portion of the product; multiple means of controlling the temperature of the product; the means including radiative conduction, gas conduction to a heatsink by means of a gas cushion, adjustment of the ion beam density at the product, adjustment of the ion beam intensity at the product and ion beam acceleration parameters, and adjustment of the ion dose to the product b; and a product movement system configured to move the product through the treatment system past the ribbon beam ion source. The treatment system further includes a system controller configured to control at least one the following: the gas cushion system, the ribbon beam ion source, the temperature control system, the heatsink, and the product movement system.

### CROSS-REFERENCE TO RELATED APPLICATIONS

This application claims the benefit from U.S. Provisional Application No. 63/184,454 filed on May 5, 2021, which is hereby incorporated by reference in its entirety for all purposes as if fully set forth herein.

### STATEMENT REGARDING FEDERALLY SPONSORED RESEARCH OR DEVELOPMENT

This invention was made with government support under contract #1853254 awarded by the National Science Foundation. The government has certain rights in the invention.

### FIELD OF THE DISCLOSURE

The disclosure relates to a system implementing a wide ribbon beam ion source to implant ions in glass. The disclosure further relates to a process implementing a wide ribbon beam ion source to implant ions in glass. More particularly, a system implementing a wide ribbon beam ion source to implant ions in glass to reduce reflective properties of the glass; and a process implementing a wide ribbon beam ion source to implant ions in glass to reduce reflective properties of the glass. Additionally, the disclosure relates to a system implementing a wide ribbon beam ion source to implant ions in other materials; and a process implementing a wide ribbon beam ion source to implant ions in other materials. Moreover, the disclosure relates to a system implementing a wide ribbon beam ion source to implant ions for industrial processes; and a process implementing a wide ribbon beam ion source to implant ions for industrial processes.

### BACKGROUND OF THE DISCLOSURE

Ion beam implantation of positive ions can be used to modify a surface of optically transparent materials (glass, sapphire, quartz) such that the surface becomes substantially non-reflecting. However, the process has never been commercialized because ion implantation has not been scalable for volume manufacturing. In particular, the inability to scale a single source beam to lengths greater than about 12 inches has presented substantial engineering challenges, cost challenges, and/or the like that have prevented the implantation process from serving a demand for anti-reflective glass. Instead, anti-reflective glass has been provided mainly by either using an organic polymeric or a thin film sputtered coating. Both solutions utilize coatings on the glass rather than being part of the glass. Moreover, both solutions typically lack the environmental robustness of the surface modification approach of implantation.

U.S. Pat. No. 9,711,318 to Nicholas White enables an expansion of a ribbon ion beam to an arbitrary length, effectively functioning as a line source similar in form to other sources (sputter, pre-treatment, vapor deposition) commonly used in large scale glass processing equipment. The White patent references limited application possibilities including semiconductor doping, sputtering, ion beam assisted sputtering, surface hardening, and control of surface charging. In particular, the White patent does not disclose glass surface modification. Moreover, the White patent fails to address other challenges in glass processing including excessive heating of the glass, tailoring of an implantation profile in the glass to achieve an optimized result, and/or the like.

Accordingly, a system and process implementing a wide ribbon beam ion source to implant ions in materials, such as glass to reduce reflective properties of the glass, that addresses numerous manufacturing issues is needed.

### SUMMARY OF THE DISCLOSURE

The foregoing needs are met, to a great extent, by the disclosure, wherein in one aspect a system and process implementing a wide ribbon beam ion source to implant ions in glass to reduce reflective properties of the glass.

One aspect includes a treatment system that is configured to provide a vacuum environment such that an ion source may be operated and product may be transported within the vacuum environment with the ion source and attendant process includes at least two of the following features a ribbon beam ion source such that the ion source provides energetic ions to bombard or implant into a product to modify a surface region of the product; a temperature control system that includes a heatsink configured to control a temperature of the product during ion bombardment by the ribbon beam ion source; a gas cushion system configured to provide a gas cushion to the product such that the gas cushion promotes heat transfer from the product to the heatsink; a product movement system configured to move the product through the treatment system past the ribbon beam ion source; a mounting system for the ribbon ion source allowing a distance from the source to the product to be configured and the angle between the source and the product to be configured to provide distance from source to product of two to twenty inches and to provide an incident angle of the ion beam to the product to be chosen as between thirty degrees and ninety degrees; and a system controller configured to control at least one the following: the gas cushion system, the ribbon beam ion source, the temperature control system, the heatsink, and the product movement system.

One aspect includes a process for treating a product, the process for treating a product implementing a treatment system, the process for treating a product includes implanting ions into a product to modify a portion of the product with a ribbon beam ion source; controlling a temperature of the product during ion implantation by the ribbon beam ion source with a temperature control system that includes a heatsink; providing a gas cushion to the product with a gas cushion system; moving the product through the treatment system past the ribbon beam ion source with a product movement system; and controlling with a system controller at least one the following: the gas cushion system, the ribbon beam ion source, the temperature control system, the heatsink, and the product movement system.

One aspect includes a treatment system that includes a ribbon beam ion source that is configured to implant ions into a product to modify a portion of the product; a temperature control system that includes a heatsink configured to control a temperature of the product during ion implantation by the ribbon beam ion source; an gas cushion system configured to provide an gas cushion to the product; a product movement system configured to move the product through the treatment system past the ribbon beam ion source; and a system controller configured to control at least one the following: the gas cushion system, the ribbon beam ion source, the temperature control system, the heatsink, and the product movement system.

One aspect includes a process for treating a product, the process for treating a product implementing a treatment system, the process for treating a product includes implanting ions into a product to modify a portion of the product with a ribbon beam ion source; controlling a temperature of the product during ion implantation by the ribbon beam ion source with a temperature control system that includes a heatsink; providing a gas cushion to the product with a gas cushion system; moving the product through the treatment system past the ribbon beam ion source with a product movement system; and controlling with a system controller at least one the following: the gas cushion system, the ribbon beam ion source, the temperature control system, the heatsink, and the product movement system.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1A illustrates a perspective view of a treatment system according to the disclosure.

FIG. 1B illustrates a more detailed perspective view of the treatment system according to FIG. 1A.

FIG. 1C illustrates a more detailed perspective view of the treatment system according to FIG. 1B.

FIG. 2A illustrates a side view of a glass surface treatment system according to the disclosure.

FIG. 2B illustrates an end view of the glass surface treatment system according to FIG. 2A.

FIG. 2C illustrates a perspective view of the glass surface treatment system according to FIG. 2A.

FIG. 2D illustrates another end view of the glass surface treatment system according to FIG. 2A.

FIG. 2E illustrates another side view of the glass surface treatment system according to FIG. 2A.

FIG. 2F illustrates another side view of the glass surface treatment system according to FIG. 2A.

FIG. 2G illustrates a schematic of the glass surface treatment system according to FIG. 2A.

FIG. 3A illustrates an exemplary processing device that may be utilized at least in part for the processes according to the disclosure.

FIG. 3B illustrates an exemplary process in accordance with aspects of the disclosure.

FIG. 4 is a cross sectional view of a source assembly according to an aspect of the disclosure.

FIG. 5A is a perspective sectional view of an arc discharge chamber according to FIG. 4.

FIG. 5B is a perspective overhead view of a magnetic field generating yoke subassembly according to FIG. 4.

FIG. 6 is an exploded section view showing structural arrangements of and aligned inter-fittings for an arc discharge chamber and a primary electron trap assembly that includes an intervening partition barrier and a magnetic field generating yoke subassembly according to FIG. 4.

FIG. 7A is a partially exploded section view of an ion source according to the disclosure.

FIG. 7B shows a perspective view of an ion source, partially disassembled, according to FIG. 7A.

FIG. 8A is a perspective view of a second aspect which shows a positioning of extraction electrodes according to the disclosure.

FIG. 8B is a cross section view of the second aspect showing the detailed mounting of the extraction electrodes according to FIG. 8A.

FIG. 9 is a partially exploded cross-sectional view of a third aspect of the ion source according to the disclosure.

FIG. 10 shows lines of magnetic flux superimposed over a cross-section of an arc discharge chamber in the first aspect according to FIG. 4.

FIG. 11 shows contours of magnetic field strength and a null point at zero value in the magnetic field superimposed on the cross section of the arc discharge chamber in the first aspect according to FIG. 4.

FIG. 12 shows a portion of the spatial zone within the cavity volume of the arc discharge chamber in which primary electrons from the thermionic cathode are trapped by the combined magnetic fields, superimposed on the cross section of the arc discharge chamber in the first aspect according to FIG. 4.

### DETAILED DESCRIPTION

The disclosure will now be described with reference to the drawing figures, in which like reference numerals refer to like parts throughout. Aspects of the disclosure advantageously provide a device and process implementing a wide ribbon beam ion source to implant ions in glass to reduce reflective properties of the glass.

The disclosed system and process enables implementation of a ribbon beam ion source for surface treatment of glass in a high-volume manufacturing environment as described herein. In aspects, the disclosed system and process may implement a temperature control system to control the temperature of the glass during the ion implantation, such as a means to control the temperature of the glass during the ion implantation process. In this regard, a bombardment of the glass by highly energetic ions causes substantial heating of the glass. In a typical industrial glass coater, the glass might reach temperatures that can cause breakage, warping, melting, and/or the like. The disclosed temperature control system may utilize a heat sink, for example a water-cooled plate, for energy removal from the glass so that the glass temperature can be controlled.

In aspects, the disclosed temperature control system that may utilize the heat sink, for example a water-cooled plate, may include a high emissivity coating adjacent to the backside of the glass but not physically touching the glass. In further aspects, the disclosed temperature control system may address the heating problem by replacing a roller transport system used in typical glass processing equipment with a gas cushion system, which may be implemented as a gas cushion transport system. In this regard, a cooled plate may be implemented with a myriad of gas injection ports that may be configured to flow an inert gas, such as one of the noble gases, hydrogen, nitrogen, and/or the like to create a cushion of the gas between the glass and the cooled plate. The presence of the gas in the gap enhances the energy removal from the glass by providing gas conduction heat removal, radiative heat removal, and/or the like.

In aspects, the gas cushion system gas cushion may be solely implemented for the glass transport. In aspects, the gas cushion system gas cushion may not provide any glass transport. In aspects, the gas cushion system gas cushion may provide limited glass transport. In aspects, a glass movement system may be implemented by a roller system while the temperature control system, such as a cooled plate, is implemented, which may be positioned between the rollers of the glass movement system. In aspects, the gas cushion system may implement a gas pressure between the temperature control system, such as the cooled plate, and the glass be higher than a chamber pressure. For example, the gas cushion system may implement a gas pressure of greater than or equal to a pressure of 1 torr in certain applications to ensure effective heat removal. In aspects, the gas cushion system may implement the gas, which may be any gas. However, in aspects, the gas cushion system may implement the gas as a non-reactive gas that may be effectively pumped, has high heat capacity, and/or the like.

The temperature control system, which may implement the cooling plate, may have a border that touches the glass to aid in trapping the gas, achieving a higher pressure in a plate gap and/or glass gap. Moreover, the gas cushion system may implement higher pressure, which may be beneficial to enhance heat removal rates. The border of the temperature control system may be configured as a non-marring material such as a solid fluorocarbon, a brush, a fabric, and/or the like.

The ribbon beam ion source may include a controller to control the voltage, current and/or divergence of the generated ion beam. In particular, the controller may control a divergence of the ion beam of the ribbon beam ion source such that the ion beam may achieve a maximum energy but spreads the energy over a larger area on the glass to prevent localized extremes of heating.

Additionally, the system may, by design, control a positioning of the ion beam of the ribbon beam ion source, such as the distance from the glass, a height of the ion beam of the ribbon beam ion source over the glass, and/or the like. In particular aspects, the controller may control a positioning of the ion beam of the ribbon beam ion source to be varied based on process conditions, a design of the extraction electrode assembly, the desired glass modification, a particular application, and/or the like. In typical ion beam sources, a beam divergence is minimized. However, the disclosed system and process may implement for certain applications a taller beam resulting in an overall lower density of energy per unit area.

The disclosed system and process may implement an ion beam control system. The ion beam control system may be configured to control an ion implant density, and ion implant depth, and/or the like. In particular aspects, the ion beam control system may be configured to control an ion implant density, an ion implant depth, and/or the like to control an effectiveness of the anti-reflective treatment to achieve a gradation of the index of refraction from the air/glass interface down to the limit of the implant.

The ion beam control system may be configured to adjust plasma conditions in the ion beam source. In aspects, the ion beam control system may be configured to generate multiply-charged ions that may be accelerated to greater energies and, therefore, be implanted to greater depths than singly charged ions. Implementation of this aspect may result in a graded index effect as desired for certain applications. In other aspects, the ion beam control system may be configured to utilize singly charged ions for certain other applications.

The disclosed system and process may implement use of a single gas or a gas mixture, such as one or more of nitrogen, argon, other noble gases, and/or the like to provide a variable depth implant of the ions. In aspects, the variable depth implant of the ions may generate a graded index structure.

Additionally, the disclosed system and process may be configured and/or implemented to create a nano-textured surface on the glass to enhance cleanability. Moreover, the disclosed system and process may be configured and/or implemented to tune or otherwise adjust process conditions to result in a graded index of refraction in the glass due to the presence of single and multiple-charged ions. Furthermore, the disclosed system and process may be configured and/or implemented to be a linearly scalable ion beam source capable of high ion currents and narrow beam outputs controllable from 100 eV up to 100 keV. Additionally, the disclosed system and process may be configured and/or implemented to enable cost effective ion beam treatments for high-throughput industrial processes.

In further aspects, the disclosed system and process may be configured and/or implemented to be linear scalable to any arbitrary treatment width. Moreover, the disclosed system and process may be configured and/or implemented to have a beam shape tunable to as narrow as 2° divergence. Additionally, the disclosed system and process may be configured and/or implemented to have ion currents up to 30 mA/cm². Furthermore, the disclosed system and process may be configured and/or implemented to implement ion energy output from 100 eV up to and exceeding 100 keV. Additionally, the disclosed system and process may be configured and/or implemented to have a single slit architecture that may enable cost effective implementation. The combination of linear scalability and high ion flux may result in the only ion beam source capable of supporting large area and high productivity ion-assisted, ion-milling, ion-implantation, and/or the like applications.

In further aspects, the disclosed system and process may be configured and/or implemented utilizing a simple filament that may be used to provide electron generation through thermionic emission. Additionally, the disclosed system and process may be configured and/or implemented with a triode electrode design that may provide ion extraction, suppression and ground to generate a neutral beam. Moreover, the disclosed system and process may be configured and/or implemented with a single slit architecture that may enable high ion fluxes and simplified alignment. Additionally, the disclosed system and process may be configured and/or implemented with a magnetic plasma confinement that may allow for arbitrary beam length.

In further aspects, the disclosed system and process may be configured and/or implemented with a wide process window and many potential applications. In particular, the disclosed system and process may be configured and/or implemented at 100 eV to 300 eV to support ion assisted deposition applications like thin Ag for low-E windows, Diamond-Like Carbon (DLC) coatings, transparent conductive oxides, surface activation, and/or the like. Additionally, the disclosed system and process may be configured and/or implemented at 300 eV to 10 keV that may support ion milling and/or ion etching for large format substrates, cutting tools, linear ion beam sputter deposition, and/or the like. Moreover, the disclosed system and process may be configured and/or implemented at up to 60 keV that may support ion implantation applications such as anti-reflection treatments, surface nitriding, and/or the like. Additionally, the disclosed system and process may be configured and/or implemented to operate, regardless of the specific ion energy, with a source that may be scalable to large area and high productivity.

In aspects, the disclosed system and process may be configured and/or implemented such that ion implantation can be used to alter the physical properties of a glass surface to induce an anti-reflection (AR) effect. The AR effect is incorporated into the glass itself, resulting in a robust, graded-index AR interface. While the fundamental technique is proven, implantation has not been commercialized for large area, high volume processing due to the lack of a source design capable of meeting cost metrics for applicable industries. The disclosed system and process may be configured and/or implemented for supporting cost effective AR and other surface treatments for solar applications, LED applications, display applications, automotive applications, and/or the like.

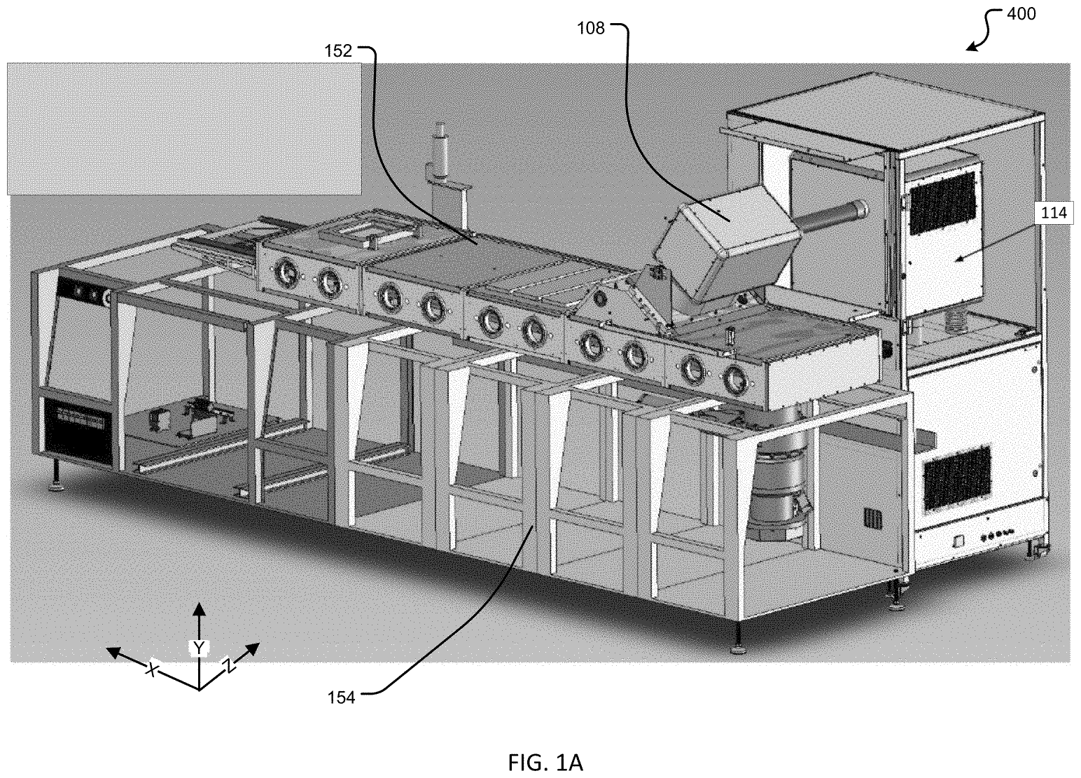

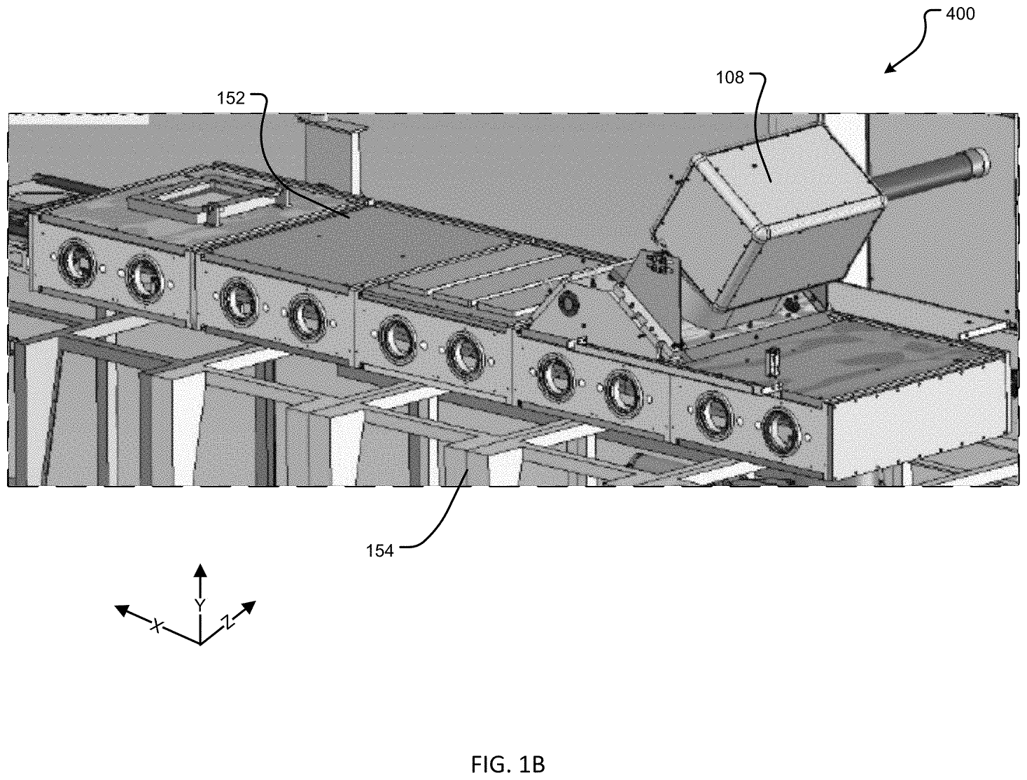

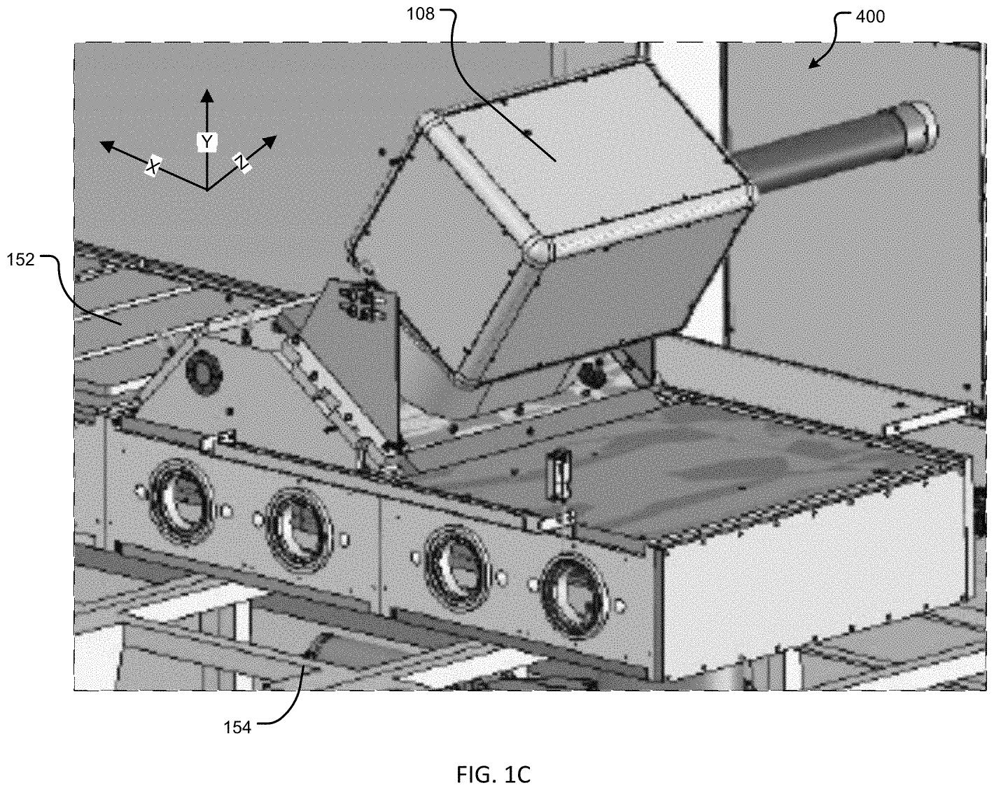

FIG. 1A illustrates a perspective view of a treatment system according to the disclosure.

FIG. 1B illustrates a more detailed perspective view of the treatment system according to FIG. 1A.

FIG. 1C illustrates a more detailed perspective view of the treatment system according to FIG. 1B.

The various aspects illustrated in FIG. 1A, FIG. 1B, and FIG. 1C and described herein may include any one or more aspects, components, and/or the like as described herein. In particular, FIG. 1A, FIG. 1B, and FIG. 1C, illustrate a treatment system 400 that may include a ribbon beam ion source 108, a processing chamber 152, a support structure 154, power equipment 114, and/or the like. In aspects, the treatment system 400 may be implemented as a glass surface treatment system, a product treatment system, a product surface treatment system, an industrial process treatment system, and/or the like. In aspects, the treatment system 400 may be implemented as a glass surface treatment system and may implement the ribbon beam ion source 108 that may be configured and/or implemented such that ion implantation may be used to alter the physical properties of a glass surface to induce an anti-reflection (AR) effect. The AR effect may be incorporated into the glass itself, resulting in a robust, graded-index AR interface. In aspects, the treatment system 400 implementing the ribbon beam ion source 108 may be configured and/or implemented for supporting cost effective AR and other surface treatments for solar applications, LED applications, display applications, automotive applications, and/or the like. In this regard, an untreated glass surface reflects a high percentage of an incident light. Accordingly, this characteristic high percentage of reflection in untreated glass reduces energy efficiency of solar applications, limits viewability and creates undesirable glare in displays, such as computer displays, mobile phone displays, and/or the like, limits viewability and creates undesirable glare in windows in automotive applications, building applications, and/or the like. Accordingly, the treatment system 400 may induce an anti-reflection (AR) effect in glass products to increase energy efficiency of solar applications, increase viewability and reduce undesirable glare in displays, such as computer displays, mobile phone displays, and/or the like, increase viewability and reduce undesirable glare in windows in automotive applications, building applications, and/or the like.

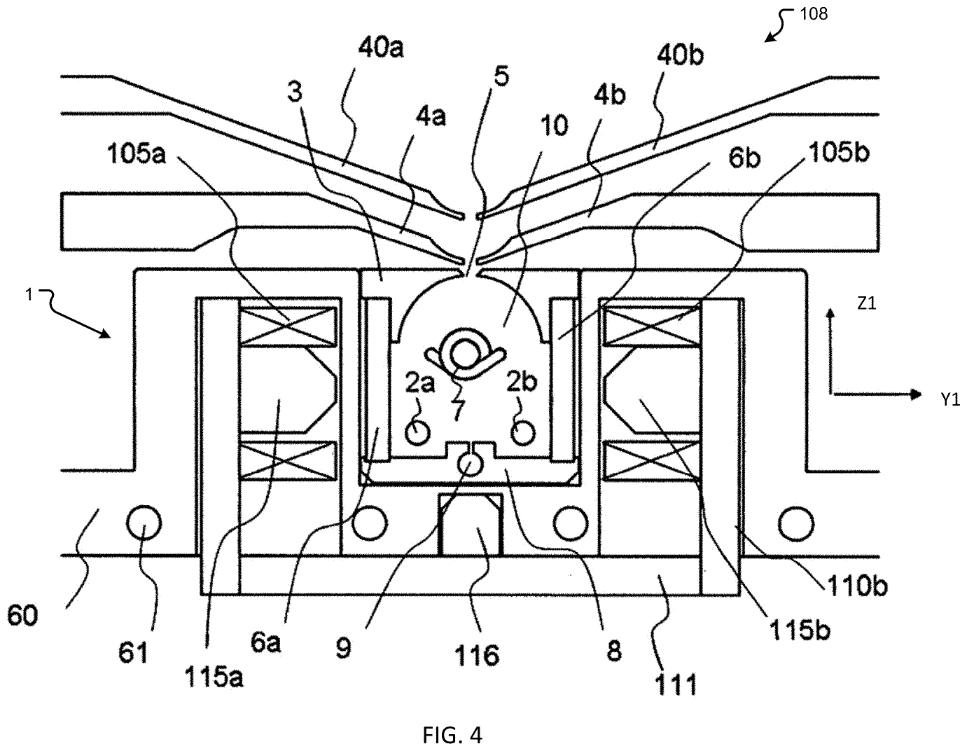

The ribbon beam ion source 108 may be implemented utilizing a number of different technologies. In this regard, the disclosure includes exemplary implementations of the ribbon beam ion source 108 with reference to FIGS. 4-12 and the associated description thereof that in combination with the various components of the treatment system 400 as described herein may achieve the disclosed implementations as well as others. However, the ribbon beam ion source 108 may be implemented utilizing other technology.

The power equipment 114 may include one or more of high voltage power supplies, a high current filament supply, an alternating current (AC) power distribution, a process gas manifold, an EtherCAT (Ethernet for Control Automation Technology) PLC (Programmable logic controller) control, a dedicated safety circuit, and/or the like. The power equipment 114 may be configured and/or implemented as a 60 K fully contained electrical enclosure. The power equipment 114 may be configured and/or implemented to utilize other levels of voltage as well.

The treatment system 400 may be implemented as an implant down in line treatment system. Moreover, the treatment system 400 may be configured for PVD (physical vapor deposition) sputter. Additionally or alternatively, the treatment system 400 may be configured with ion beam assist. In particular aspects, the treatment system 400 may be configured with ion beam assist with a 200 mm source. In this regard, the treatment system 400 may be implemented as a glass manufacturing system, a solar application manufacturing system, an LED application manufacturing system, a display application manufacturing system, an automotive part manufacturing system, and/or the like. The treatment system 400 may further include various systems for receiving partially manufactured components or products including one or more of robotic systems, conveyor systems, and/or the like. The treatment system 400 may further include various systems for delivering partially manufactured components or products including one or more of robotic systems, conveyor systems, and/or the like.

The support structure 154 may include a number of components to elevate the various components of the treatment system 400. In particular, the support structure 154 may elevate the processing chamber 152 and the ribbon beam ion source 108. Additionally, the support structure 154 may support and elevate various other components of the treatment system 400 described in further detail below. The support structure 154 may include various horizontal structures that may be parallel to the X-Z plane as illustrated and various vertical structures that may be arranged parallel to the X-Y plane as illustrated forming a sturdy structure to support the various components of the treatment system 400. Additionally, the support structure 154 may support the treatment system 400 in connection with the various systems for receiving partially manufactured components or products including one or more of robotic systems, conveyor systems, and/or the like. Moreover, the support structure 154 may support the treatment system 400 in connection with the various systems for delivering partially manufactured components or products including one or more of robotic systems, conveyor systems, and/or the like.

As noted in FIGS. 1-3, Cartesian coordinate axes (X, Y, and Z axes) are illustrated in the drawings simply to identify and describe an exemplary relative arrangement and relative orientation of the components of the treatment system 400.

However, the Cartesian coordinate axes illustrated in FIGS. 1-3 may not correspond to the Cartesian coordinate axes (X1, Y1, and Z1 axes) illustrated FIGS. 4-12.

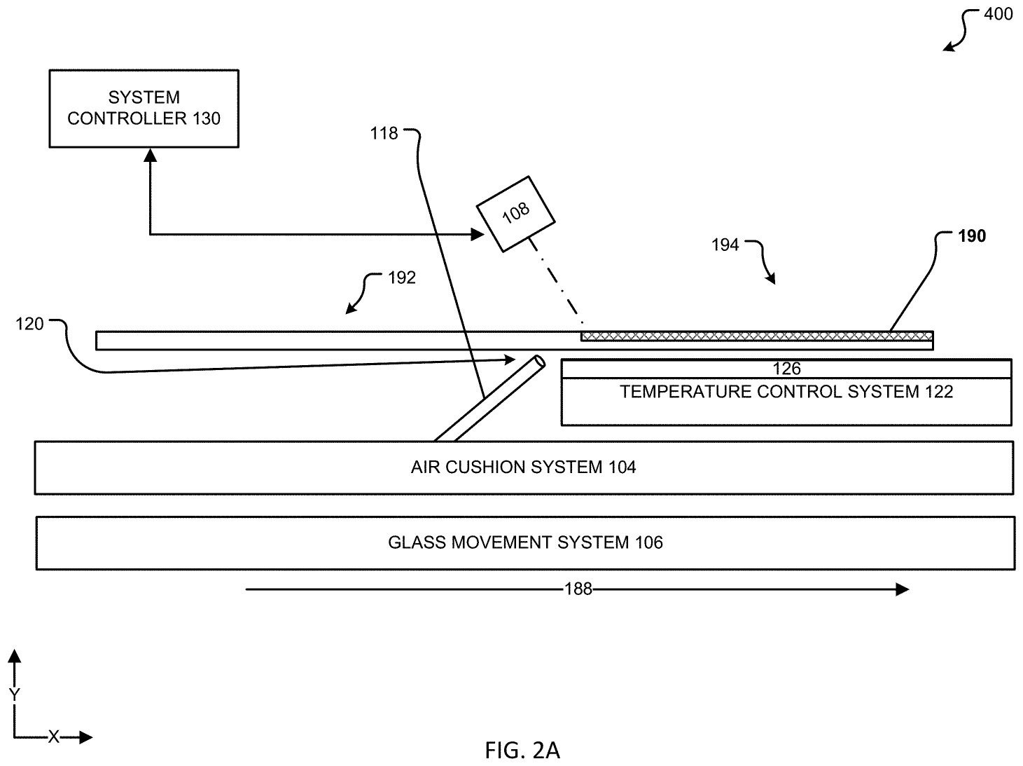

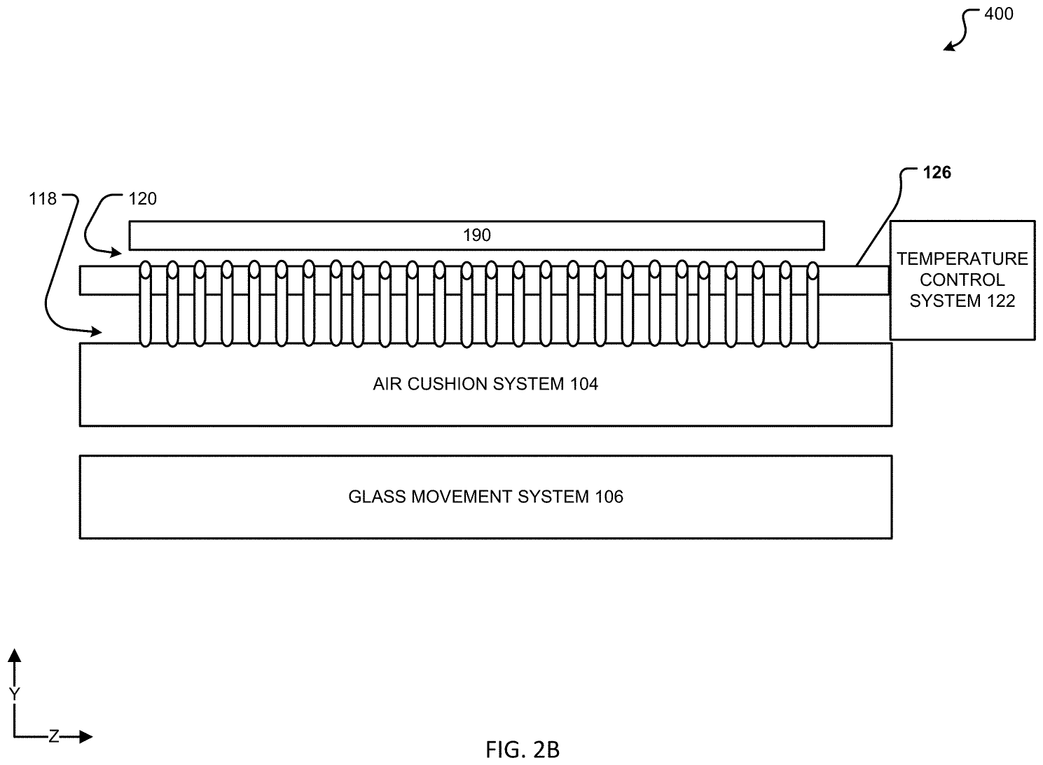

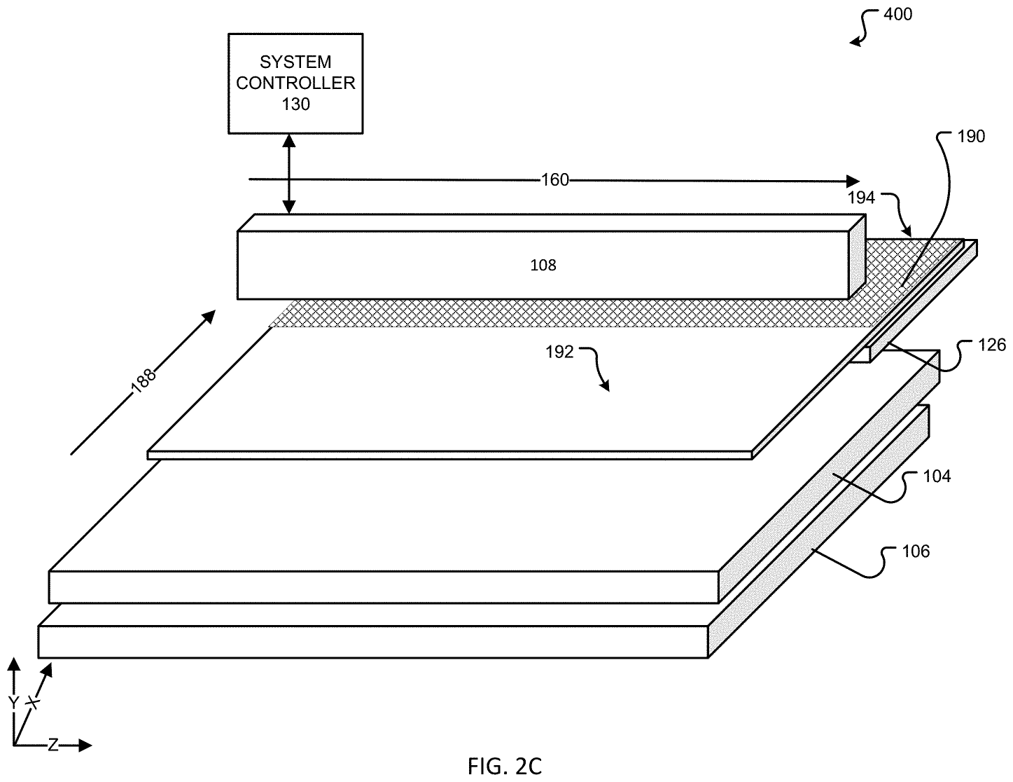

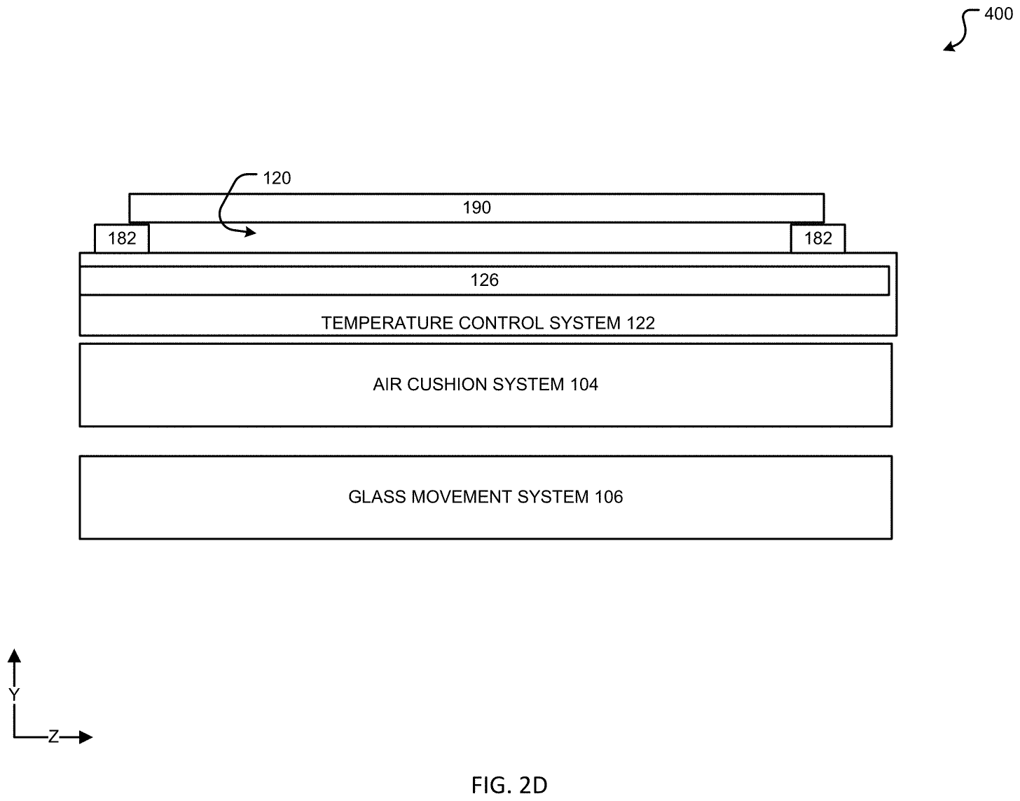

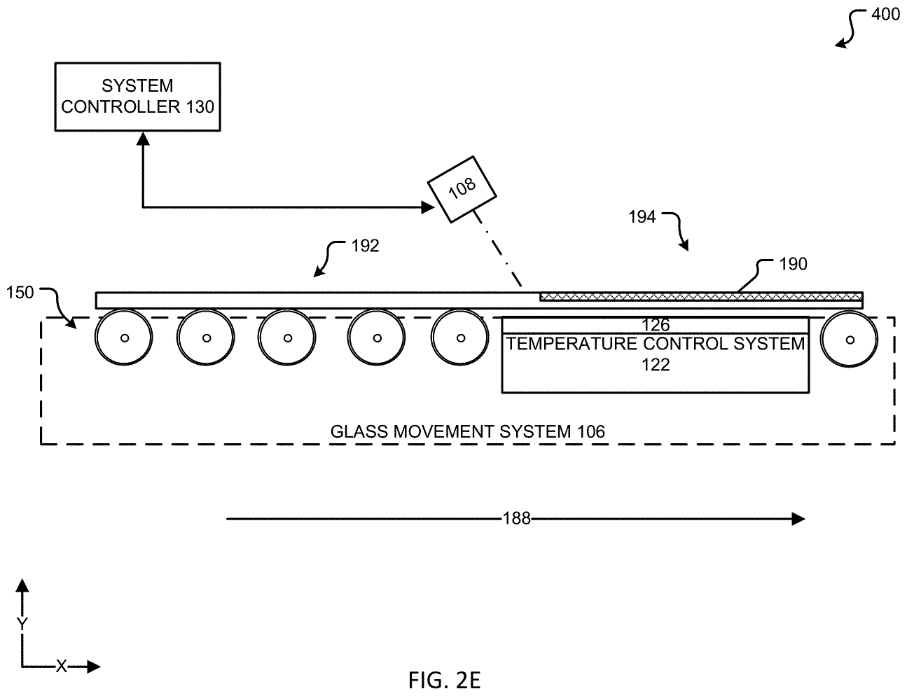

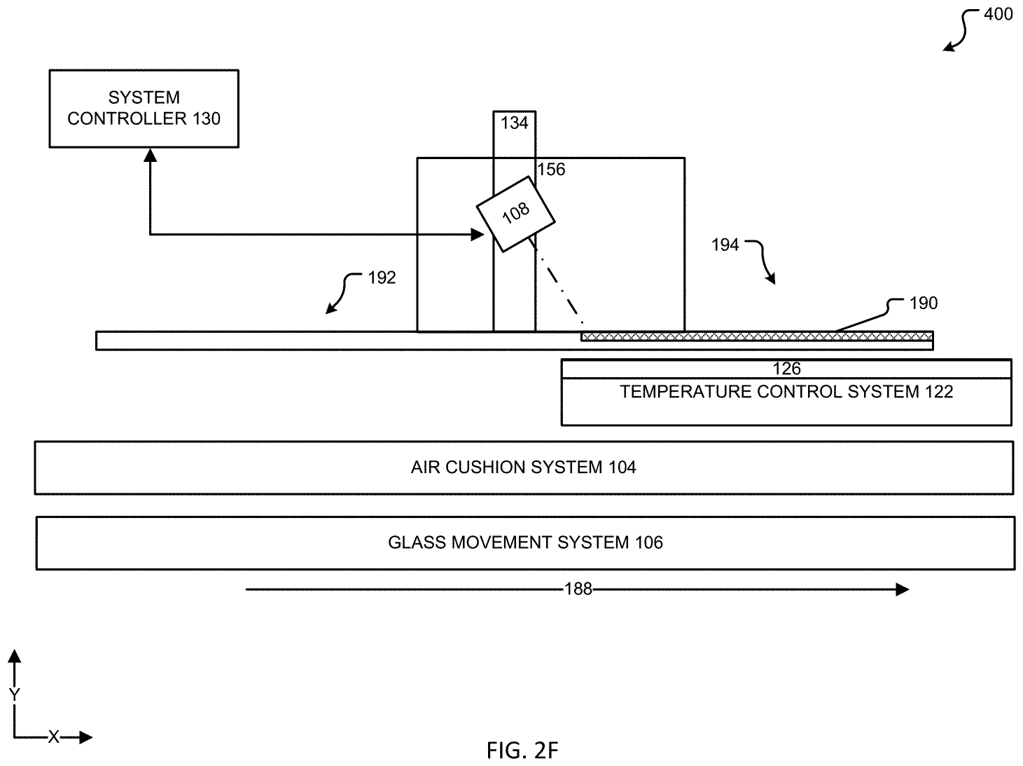

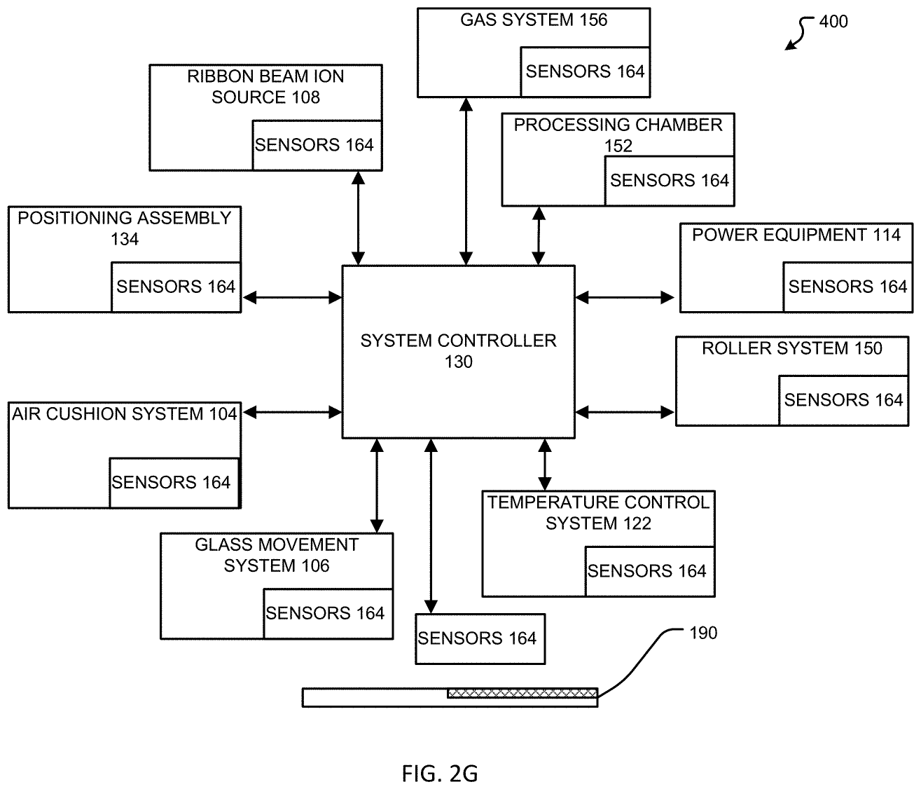

FIG. 2A illustrates a side view of a glass surface treatment system according to the disclosure.

FIG. 2B illustrates an end view of the glass surface treatment system according to FIG. 2A.

FIG. 2C illustrates a perspective view of the glass surface treatment system according to FIG. 2A.

FIG. 2D illustrates another end view of the glass surface treatment system according to FIG. 2A.

FIG. 2E illustrates another side view of the glass surface treatment system according to FIG. 2A.

FIG. 2F illustrates another side view of the glass surface treatment system according to FIG. 2A.

FIG. 2G illustrates a schematic of the glass surface treatment system according to FIG. 2A.

The various aspects illustrated FIG. 2A, FIG. 2B, FIG. 2C, FIG. 2D, FIG. 2E, FIG. 2F, and FIG. 2G and described herein may include any one or more aspects, components, and/or the like as described herein. In particular, FIG. 2A, FIG. 2B, FIG. 2C, FIG. 2D, FIG. 2E, FIG. 2F, and FIG. 2G illustrate the treatment system 400 that may include a temperature control system 122, a gas cushion system 104, a glass movement system 106, the ribbon beam ion source 108, a system controller 130, a heatsink 126, and/or the like. As described herein, the treatment system 400 in conjunction with the ribbon beam ion source 108 and/or the system controller 130 may be configured and/or implemented to modify a portion of a product.

In one aspect, the treatment system 400 in conjunction with the ribbon beam ion source 108 and/or the system controller 130 may be configured and/or implemented to modify an unmodified portion of a product to have a modified portion. In aspects, the product may move through the treatment system 400 along a processing path 188 is illustrated by FIG. 2A and FIG. 2C while modifying the product to have the modified portion. In one aspect, the treatment system 400 in conjunction with the ribbon beam ion source 108 and/or the system controller 130 may be configured and/or implemented to modify an unmodified portion 192 of glass 190 to have a modified portion 194. In aspects, the glass 190 may move through the treatment system 400 along the processing path 188 while modifying the glass 190 to have the modified portion 194.

In this regard, the treatment system 400 implementing the ribbon beam ion source 108 and/or the system controller 130 may be configured and/or implemented to generate ions and direct the ions into the glass 190 such that ion implantation can be used to alter the physical properties of a surface of the glass 190 to induce an anti-reflection (AR) effect to create the modified portion 194 on a surface of the glass 190. More specifically, the modified portion 194 may exhibit the AR effect that may be incorporated into the glass 190 itself, resulting in a robust, graded-index AR interface. In aspects, the glass 190 having the modified portion 194 may be utilized in solar applications, LED applications, display applications, automotive applications, and/or the like. Additionally, the treatment system 400 implementing the ribbon beam ion source 108 and/or the system controller 130 may be configured and/or implemented for surface treatment of the glass 190 to have the modified portion 194 in a high-volume manufacturing environment.

The ribbon beam ion source 108 may be implemented by a single implementation of the ribbon beam ion source 108 as illustrated in FIG. 2E. In other aspects, the ribbon beam ion source 108 may include a plurality of implementations of the ribbon beam ion source 108 along the X axis and/or the processing path 188 (not shown). Additionally, a plurality of implementations of one or more of the heatsink 126, the temperature control system 122, the gas cushion system 104, the glass movement system 106, and/or the like may likewise be implemented along the X axis and/or the processing path 188 in the treatment system 400 to provide serial processing of the glass 190 or other product (not shown). Additionally or alternatively, the ribbon beam ion source 108 may include a plurality of implementations of the ribbon beam ion source 108 along the Z axis. Additionally, a plurality of implementations of one or more of the heatsink 126, the temperature control system 122, the gas cushion system 104, the glass movement system 106, and/or the like may likewise be implemented along the Z axis in the treatment system 400 to provide parallel processing of the glass 190 or other product.

In aspects, the temperature control system 122 may be configured to control the temperature of the glass 190 during the ion implantation by the ribbon beam ion source 108. In this regard, a bombardment of the glass 190 or other products by highly energetic ions from the ribbon beam ion source 108 to form the modified portion 194 may cause substantial heating of the glass 190 or other products. In particular, implementation of the treatment system 400 implementing the ribbon beam ion source 108 may result in the glass 190 reaching temperatures that can cause breakage, warping, melting, and/or the like. The temperature control system 122 may be a device or system to provide a desired temperature-controlled environment for the treatment system 400 for processing the glass 190 or other product. The temperature control system 122 may include one or more of a water-cooled plate, a cold plate, a cooling device, a heatsink, a heat exchanger, a heat spreader, a heat transfer device, a heat reservoir, a component having high thermal conductivity, a component with fin structures, a thermal interface, and/or the like.

The temperature control system 122 may include a cooling device, a cooling device controller, a temperature sensor, and/or the like. The temperature control system 122 may utilize a heatsink 126, for example a water-cooled plate, for energy removal from the glass 190 so that a glass temperature can be controlled during the process to form the modified portion 194. In aspects, the temperature control system 122 may utilize the heatsink 126, for example a water-cooled plate, a cold plate, and/or the like, that may include a high emissivity coating adjacent to a backside of the glass 190, which may be configured to not physically touch the glass 190. The cooling device controller may be implemented in part by the system controller 130 and may be responsive to the temperature sensor to control the cooling device and/or the temperature control system 122. The heatsink 126 and/or the temperature control system 122 may include a water source, a pump, and conduits connecting the water source to the pump configured to implement the water-cooled plate implementation of the heatsink 126, and/or the like. Additionally, the heatsink 126 may utilize other coolants. In particular aspects, the temperature control system 122 may be controlled by the system controller 130.

In aspects, the system controller 130 may be implemented as a single device or the system controller 130 may be implemented as a plurality of distributed devices. In aspects, the system controller 130 may implement one or more modules. More specifically, with reference to FIG. 2G, the system controller 130 may monitor one or more sensors 164 configured to measure various physical characteristics including voltage, current, power, temperature, pressure, flow, mass, optical reflectance, movement, location, and/or the like of the gas cushion system 104, the ribbon beam ion source 108, the temperature control system 122, the heatsink 126, the glass movement system 106, other components of the treatment system 400 as illustrated, and/or the like. Additionally, the system controller 130 may utilize signals from the one or more sensors 164 as feedback for subsequent control of the gas cushion system 104, the ribbon beam ion source 108, the temperature control system 122, the heatsink 126, the glass movement system 106, other components of the treatment system 400 as illustrated, and/or the like. In a particular aspect, the system controller 130 may control the temperature control system 122 based on the various physical characteristics measured by the one or more sensors 164 located to measure a temperature of the glass 190, the temperature control system 122, and/or the like. In a particular aspect, the system controller 130 may control the ribbon beam ion source 108 based on the various physical characteristics measured by the one or more sensors 164 located to measure optical reflectance of the glass 190, the temperature control system 122, other components of the treatment system 400 as illustrated, and/or the like. Accordingly, the system controller 130 may control the components of the treatment system 400 based on the various physical characteristics measured by the one or more sensors 164 located throughout the treatment system 400.

Additionally, the treatment system 400 may include the gas cushion system 104. In aspects, the temperature control system 122 may address the heating problem by replacing a roller transport system used in typical glass processing equipment with the gas cushion system 104, which may be implemented as a gas cushion transport system. In this regard, as illustrated in FIG. 2A and FIG. 2B, the gas cushion system 104 and/or the temperature control system 122 may be additionally, and/or alternatively be implemented with one or more gas injection ports 118 that may be configured to flow an inert gas, such as one of the noble gases, hydrogen, nitrogen, and/or the like to create a cushion of gas in a gap 120 between the glass 190 and the temperature control system 122 and/or the heatsink 126. The presence of the gas in the gap 120 may enhance the energy removal from the glass by providing gas conduction heat removal, radiative heat removal, and/or the like. In one aspect, the one or more gas injection ports 118 may be configured to flow the gas in the processing path 188 to assist in movement of the glass 190 through the treatment system 400.

In particular aspects, the gas cushion system 104 and/or the one or more gas injection ports 118 may be controlled by the system controller 130. More specifically, the system controller 130 may monitor the one or more sensors 164 configured to measure various physical characteristics including voltage, current, power, temperature, pressure, flow, mass, optical reflectance, movement, location, and/or the like of the gas cushion system 104, the ribbon beam ion source 108, the temperature control system 122, the heatsink 126, the glass movement system 106, and/or the like. In one aspect, the system controller 130 may control the gas cushion system 104 and/or the one or more gas injection ports 118 based on the various physical characteristics measured by the one or more sensors 164 including a flow rate of the gas through the one or more gas injection ports 118 and/or the gas cushion system 104, a temperature of the glass 190, the heatsink 126, the temperature control system 122, and/or the like. Accordingly, the system controller 130 may control the gas cushion system 104 and/or the one or more gas injection ports 118 based on the various physical characteristics measured by the one or more sensors 164 located throughout the treatment system 400.

With reference to FIG. 2D, the temperature control system 122, which may implement the cooling plate, may have a border 182 that touches the glass to aid in trapping the gas from the one or more gas injection ports 118, the glass movement system 106, and/or the like, achieving a higher pressure in the gap 120, such as a plate gap and/or a glass gap between the heatsink 126, the temperature control system 122, and/or the glass 190. Moreover, the gas cushion system 104 may implement a higher pressure, which may be beneficial to enhance heat removal rates. The border 182 of the temperature control system 122 may be configured with a non-marring material such as a solid fluorocarbon, a brush, a fabric, and/or the like.

In aspects, the gas cushion system 104 may be solely implemented for transport of the glass 190. In aspects, the gas cushion system 104 may not provide any transport of the glass 190. In aspects, the gas cushion system 104 may provide limited transport of the glass 190.

In aspects with reference to FIG. 2E, the glass movement system 106 may be implemented by a roller system 150 while the temperature control system 122, such as a cooled plate, is implemented. In particular, the temperature control system 122 and/or the heatsink 126 may be arranged between the roller system 150 of the glass movement system 106. The roller system 150 may include one or more rollers, one or more drive devices, such as motors, for rotating the one or more rollers, a controller to control the roller system 150 and the one or more rollers, and/or the like.

In particular aspects, the roller system 150 may be controlled by the system controller 130. More specifically, the system controller 130 may monitor the one or more sensors 164 configured to measure various physical characteristics including voltage, current, power, temperature, pressure, flow, mass, optical reflectance, movement, location, and/or the like of the gas cushion system 104, the ribbon beam ion source 108, the temperature control system 122, the heatsink 126, the glass movement system 106, and/or the like. In particular aspects, the system controller 130 may monitor the one or more sensors 164 configured to measure various physical characteristics including a movement and/or a speed of the roller system 150 and/or the glass 190, a location of the glass 190, and/or the like in the treatment system 400 and/or the like. Accordingly, the system controller 130 may control the roller system 150 based on the various physical characteristics measured by the one or more sensors 164 located throughout the treatment system 400.

Referring back to FIG. 2A, the gas cushion system 104 may be configured and/or implemented to provide a gas to the treatment system 400 such as the processing chamber 152 of the treatment system 400. In aspects, the gas cushion system 104 may be configured and/or implemented to provide a gas pressure, through for example the one or more gas injection ports 118, between the temperature control system 122, such as the cooled plate, and the glass 190 that may be higher than a chamber pressure of the processing chamber 152 of the treatment system 400. For example, the gas cushion system 104 may implement a gas pressure of greater than or equal to a pressure of 1 torr in certain applications to ensure effective heat removal from the glass 190 being processed by the treatment system 400. In aspects, the gas cushion system 104 may implement the gas, which may be any gas. However, in aspects, the gas cushion system 104 may implement the gas as a non-reactive gas that may be effectively pumped, has high heat capacity, and/or the like. The gas cushion system 104 may include a gas source, a pump for pressurizing the gas from the gas source, one or more conduits connecting one or more of the pump, the gas source, the one or more gas injection ports 118, a gas collection system, one or more valves, and/or the like.

The ribbon beam ion source 108 may include a controller to control an ion beam of the ribbon beam ion source 108 and may be implemented as the system controller 130. In particular, the system controller 130 may control a divergence of the ion beam of the ribbon beam ion source 108. In particular, the system controller 130 may control a divergence of the ion beam of the ribbon beam ion source 108 such that the ion beam may achieve a maximum energy but spreads the energy over a larger area on the glass 190 to prevent localized extremes of heating. In other words, the system controller 130 may control the ribbon beam ion source 108 to generate the modified portion 194 in the glass 190 yet avoid and/or reduce breakage, warping, melting, and/or the like of the glass 190.

In further aspects, the system controller 130 may control the ribbon beam ion source 108 to control one or more of a divergence of an ion beam, change a length of an ion beam, plasma conditions, an ion implant density, an ion implant depth, an ion beam breadth, an ion energy, an ion current, an ion power, an ion distribution, an implantation axis, an ion acceleration voltage, an ion dose, an atomic concentration of ions, an implant thickness, and/or the like of the ion beam of the ribbon beam ion source 108. More specifically, the system controller 130 may monitor the one or more sensors 164 configured to measure various physical characteristics including voltage, current, power, temperature, pressure, flow, mass, optical reflectance, movement, location, and/or the like of the gas cushion system 104, the ribbon beam ion source 108, the temperature control system 122, the heatsink 126, the glass movement system 106, and/or the like. Accordingly, the system controller 130 may control the ribbon beam ion source 108 based on the various physical characteristics measured by the one or more sensors 164 located throughout the treatment system 400. Additionally, the system controller 130 may control the ribbon beam ion source 108 utilizing various process protocols, process times, and/or the like by utilizing an on-board script processor. The system controller 130 may allow user-defined on-board script execution for controlling process sequencing, process flow, decision making, and/or the like of the ribbon beam ion source 108.

Additionally, the system controller 130 may control a positioning of the ribbon beam ion source 108, such as a distance from the glass 190, a height of the ribbon beam ion source 108 over the glass 190, and/or the like. In this regard, the system controller 130 may control a positioning of the ribbon beam ion source 108, which may be a dimension orthogonal to a beam length. In particular aspects, the system controller 130 may control a positioning of the ribbon beam ion source 108 to be varied based on process conditions, a design of an extraction electrode assembly of the ribbon beam ion source 108, a desired glass modification of the glass 190, a particular application, and/or the like. In typical ion beam sources, a beam divergence is minimized. However, the system controller 130 may be configured and/or implemented to control the ribbon beam ion source 108 for certain applications to have a longer and/or taller beam resulting in an overall lower density of energy per unit area of the glass 190 or other processed product.

With reference to FIG. 2F, the ribbon beam ion source 108 may be operably connected to a positioning assembly 134. The positioning assembly 134 may be configured to translate the ribbon beam ion source 108 relative to the glass 190 along one, two, or three directional axes that are each orthogonal to any of the other axes. In some aspects, the positioning assembly 134 may be configured to rotate the ribbon beam ion source 108 about the one, two, or three directional axes. The positioning assembly 134 can include a carriage, a gantry, guide rails, a drive coupled to independently controllable motors (not shown) in a known manner, and/or the like. The positioning assembly 134 may be configured to move the ribbon beam ion source 108 with respect to the glass 190. Movement of the ribbon beam ion source 108 may align the ribbon beam ion source 108 with the glass 190 based on a desired orientation. Moreover, the positioning assembly 134 may be configured to position the ribbon beam ion source 108 to change a length of an ion beam, for example have a taller beam, a longer beam, and/or the like.

In further aspects, the system controller 130 may control the positioning assembly 134. More specifically, the system controller 130 may monitor the one or more sensors 164 configured to measure various physical characteristics including voltage, current, power, temperature, pressure, flow, mass, optical reflectance, movement, location, and/or the like of the gas cushion system 104, the ribbon beam ion source 108, the temperature control system 122, the heatsink 126, the glass movement system 106, and/or the like. In one aspect, the system controller 130 may monitor the one or more sensors 164 configured to measure various physical characteristics including movement, location, and/or the like of the ribbon beam ion source 108, the positioning assembly 134, and/or the like. Accordingly, the system controller 130 may control the positioning assembly 134 based on the various physical characteristics measured by the one or more sensors 164 located throughout the treatment system 400. Additionally, the system controller 130 may control the ribbon beam ion source 108 and/or the positioning assembly 134 utilizing various process protocols, process times, and/or the like by utilizing an on-board script processor. The system controller 130 may allow user-defined on-board script execution for controlling process sequencing, process flow, decision making, and/or the like of the positioning assembly 134.

The system controller 130 may configured and/or implemented as an ion beam control system. The ion beam control system may be configured to control a divergence of an ion beam, change a length of an ion beam, plasma conditions, an ion implant density, an ion implant depth, an ion beam breadth, an ion energy, an ion current, an ion power, an ion distribution, an implantation axis, an ion acceleration voltage, an ion dose, an atomic concentration of ions, an implant thickness, and/or the like of the ribbon beam ion source 108. In particular aspects, the ion beam control system may be configured to control an ion implant density, an ion implant depth, and/or the like of the ribbon beam ion source 108 to control an effectiveness of the anti-reflective treatment to achieve a gradation of the index of refraction from the gas/glass interface down to the limit of the implant.

More specifically, the system controller 130 may monitor the one or more sensors 164 configured to measure various physical characteristics including voltage, current, power, temperature, pressure, flow, mass, optical reflectance, movement, location, and/or the like of the gas cushion system 104, the ribbon beam ion source 108, the temperature control system 122, the heatsink 126, the glass movement system 106, and/or the like. Accordingly, the system controller 130 may control the ribbon beam ion source 108 based on the various physical characteristics measured by the one or more sensors 164 located throughout the treatment system 400 to control a divergence of an ion beam, change a length of an ion beam, plasma conditions, an ion implant density, an ion implant depth, an ion beam breadth, an ion energy, an ion current, an ion power, an ion distribution, an implantation axis, an ion acceleration voltage, an ion dose, an atomic concentration of ions, an implant thickness, and/or the like of the ribbon beam ion source 108.

The system controller 130 implementing ion beam control system may be configured to adjust plasma conditions in the ribbon beam ion source 108. In aspects, the system controller 130 implementing the ion beam control system may be configured to operate in conjunction with the ribbon beam ion source 108 to utilize multiply-charged ions that may be accelerated to greater energies and, therefore, be implanted to greater depths in the glass 190 than singly charged ions. Implementation of this aspect may result in a graded index effect of the glass 190 as desired for certain applications. In other aspects, the system controller 130 implementing the ion beam control system may be configured control the ribbon beam ion source 108 to utilize singly charged ions for certain other applications.

In particular aspects, the system controller 130 may control the ribbon beam ion source 108 utilizing various process protocols, process times, and/or the like by utilizing an on-board script processor for controlling process sequencing, process flow, decision making, and/or the like of the ribbon beam ion source 108 to adjust plasma conditions, to utilize multiply-charged ions, to modify implant depth, to utilize singly charged ions, and/or the like. Additionally, the system controller 130 may control the ribbon beam ion source 108 based on the various physical characteristics measured by the one or more sensors 164 located throughout the treatment system 400 to adjust plasma conditions, to utilize multiply-charged ions, to modify implant depth, to utilize singly charged ions, and/or the like.

In aspects with reference to FIG. 2F, the treatment system 400 may implement a gas system 156 to implement use of a single gas or a gas mixture, such as one or more of nitrogen, argon, other noble gases, and/or the like to provide a variable depth implant of the ions by the ribbon beam ion source 108. The gas system 156 may include a gas source, a pump for pressurizing the gas from the gas source, one or more conduits connecting one or more of the pump, the gas source, a gas collection system, one or more valves, and/or the like. In aspects, the variable depth implant of the ions may generate a graded index structure in the glass 190.

In particular aspects, the system controller 130 may control the gas system 156 utilizing various process protocols, process times, and/or the like by utilizing an on-board script processor for controlling process sequencing, process flow, decision making, and/or the like of the ribbon beam ion source 108 to control various aspects of the gas system 156. Additionally, the system controller 130 may control the ribbon beam ion source 108 based on the various physical characteristics measured by the one or more sensors 164 located throughout the treatment system 400 to control the gas system 156 and/or associated components of the gas system 156 including the gas source, the pump for pressurizing the gas from the gas source, one or more conduits connecting one or more of the pump, the gas source, a gas collection system, one or more valves, and/or the like.

Additionally, the treatment system 400 may be configured as a system that may implement a process configured and/or implemented in conjunction with the ribbon beam ion source 108 to create a nano-textured surface on the glass 190 to, for example, enhance cleanability. In particular aspects, the system controller 130 may control the ribbon beam ion source 108 and/or the treatment system 400 based on the various physical characteristics measured by the one or more sensors 164 located throughout the treatment system 400 to create a nano-textured surface on the glass 190 to enhance cleanability.

Moreover, the treatment system 400 may be configured as a system that may implement a process to tune or otherwise adjust process conditions of the ribbon beam ion source 108 and/or other components of the treatment system 400 to result in a graded index of refraction in the glass 190 due to the presence of single and multiple-charged ions. In particular aspects, the system controller 130 may tune the ribbon beam ion source 108 utilizing various process protocols, process times, and/or the like by utilizing an on-board script processor for controlling process sequencing, process flow, decision making, and/or the like of the ribbon beam ion source 108 to tune or otherwise adjust process conditions of the ribbon beam ion source 108 including tuning a divergence of an ion beam, change a length of an ion beam, plasma conditions, an ion implant density, an ion implant depth, an ion beam breadth, an ion energy, an ion current, an ion power, an ion distribution, an implantation axis, an ion acceleration voltage, an ion dose, an atomic concentration of ions, an implant thickness, and/or the like.

Furthermore, the treatment system 400 may be configured as a system that may implement a process utilizing the ribbon beam ion source 108 configured and/or implemented to be a linearly scalable ion beam source capable of high ion currents and narrow beam outputs controllable from 100 eV up to 60 keV. Additionally, the treatment system 400 may be configured as a system that may implement a process configured and/or implemented to enable cost effective ion beam treatments utilizing the ribbon beam ion source 108 for high-throughput industrial processes. In this regard, the disclosure includes exemplary implementations of the ribbon beam ion source 108 with reference to FIGS. 4-12 and the associated description thereof that in combination with the various components of the treatment system 400 as described herein may be implemented as a linearly scalable ion beam source capable of high ion currents, narrow beam outputs controllable from 100 eV up to 60 keV, and/or the like and further may enable cost effective ion beam treatments utilizing the ribbon beam ion source 108 for high-throughput industrial processes, and/or the like.

In further aspects, the treatment system 400 may be configured as a system that may implement and/or configure the ribbon beam ion source 108 to be linear scalable to any arbitrary treatment width of the glass 190 and/or other product. With reference to FIG. 2C, the ribbon beam ion source 108 may be linear scalable to a treatment width 160 of the glass 190 and/or other product of 0 inches-20 inches, 0 inches-40 inches, 0 inches-60 inches, 0 inches-80 inches, 0 inches-100 inches, 0 inches-120 inches, 0 inches-160 inches, 0 inches-200 inches, or more. Moreover, the treatment system 400 may be configured as a system that may implement a process in conjunction with the ribbon beam ion source 108 to have a beam shape tunable to as narrow as 2° divergence. In this regard, the disclosure includes exemplary implementations of the ribbon beam ion source 108 with reference to FIGS. 4-12 and the associated description thereof that in combination with the various components of the treatment system 400 as described herein may be configured to be linear scalable to any arbitrary treatment width of the glass 190 and/or other product, have a beam shape tunable to as narrow as 2° divergence, and/or the like.

Additionally, the treatment system 400 may be configured as a system that may implement a process in conjunction with the ribbon beam ion source 108 to have ion currents up to 30 mA/cm². Furthermore, the treatment system 400 may be configured as a system that may implement a process in conjunction with the ribbon beam ion source 108 to implement ion energy output from 100 eV up to and exceeding 60 keV. Additionally, the treatment system 400 may be configured as a system that may implement the ribbon beam ion source 108 to have a single slit architecture, single slot architecture, single exit aperture, and/or the like that may enable cost effective implementation and/or processing of the glass 190. The combination of linear scalability and high ion flux of the ribbon beam ion source 108 may support large area and high productivity ion-assisted, ion-milling, ion-implantation, and/or the like applications. In this regard, the disclosure includes exemplary implementations of the ribbon beam ion source 108 with reference to FIGS. 4-12 and the associated description thereof that in combination with the various components of the treatment system 400 as described herein may have ion currents up to 30 mA/cm², may implement ion energy output from 100 eV up to and exceeding 60 keV, may implement a single slit architecture, a single slot architecture, a single exit aperture architecture, and/or the like that may enable cost effective implementation and/or processing of the glass 190, may implement a combination of linear scalability and high ion flux to support large area and high productivity ion-assisted, ion-milling, ion-implantation, and/or the like applications.

In further aspects, the treatment system 400 and/or the ribbon beam ion source 108 may be configured and/or implemented utilizing a simple filament that may be used to provide electron generation through thermionic emission. Additionally, the treatment system 400 and/or the ribbon beam ion source 108 may be configured and/or implemented with a triode electrode design that may provide ion extraction, suppression and ground to generate a neutral beam. Moreover, the treatment system 400 and/or the ribbon beam ion source 108 may be configured and/or implemented with a single slit architecture, single slot architecture, a single exit aperture architecture, and/or the like that may enable high ion fluxes and simplified alignment. Additionally, the treatment system 400 may be configured and/or implemented with a magnetic plasma confinement that may allow for arbitrary beam length. In this regard, the disclosure includes exemplary implementations of the ribbon beam ion source 108 with reference to FIGS. 4-12 and the associated description thereof that in combination with the various components of the treatment system 400 as described herein may be configured and/or implemented utilizing a simple filament that may be used to provide electron generation through thermionic emission, a triode electrode design that may provide ion extraction, suppression and ground to generate a neutral beam, a single slit architecture, a single slot architecture, a single exit aperture architecture, and/or the like that may enable high ion fluxes and simplified alignment, a magnetic plasma confinement that may allow for arbitrary beam length, and/or the like.

In further aspects, the treatment system 400 may be configured as a system that may implement a process in conjunction with the ribbon beam ion source 108 configured and/or implemented with a wide process window and many potential applications. In particular, the treatment system 400 may be configured as a system that may implement a process in conjunction with the ribbon beam ion source 108 that may be configured and/or implemented at 100 eV to 300 eV to support ion assisted deposition applications like thin Ag for low-E windows, Diamond-Like Carbon (DLC) coatings, transparent conductive oxides, surface activation, and/or the like. Additionally, the treatment system 400 may be configured as a system that may implement a process in conjunction with the ribbon beam ion source 108 that may be configured and/or implemented at 300 eV to 10 keV that may support ion milling and/or ion etching for large format substrates, cutting tools, linear ion beam sputter deposition, and/or the like.

In this regard, the disclosure includes exemplary implementations of the ribbon beam ion source 108 with reference to FIGS. 4-12 and the associated description thereof that in combination with the various components of the treatment system 400 as described herein may be configured and/or implemented with a wide process window and many potential applications, configured and/or implemented at 100 eV to 300 eV to support ion assisted deposition applications like thin Ag for low-E windows, Diamond-Like Carbon (DLC) coatings, transparent conductive oxides, surface activation, and/or the like, configured and/or implemented at 300 eV to 10 keV that may support ion milling and/or ion etching for large format substrates, cutting tools, linear ion beam sputter deposition, and/or the like.

Moreover, the treatment system 400 may be configured as a system that may implement a process in conjunction with the ribbon beam ion source 108 that may be configured and/or implemented at up to 60 keV that may support ion implantation applications such as anti-reflection treatments, surface nitriding, and/or the like. Additionally, the treatment system 400 may be configured as a system that may implement a process in conjunction with the ribbon beam ion source 108 that may be configured and/or implemented to operate, regardless of the specific ion energy, with a source that may be scalable to large area and high productivity. In this regard, the disclosure includes exemplary implementations of the ribbon beam ion source 108 with reference to FIGS. 4-12 and the associated description thereof that in combination with the various components of the treatment system 400 as described herein may be configured and/or implemented at up to 60 keV that may support ion implantation applications such as anti-reflection treatments, surface nitriding, and/or the like, operate, regardless of the specific ion energy, with a source that may be scalable to large area and high productivity, and/or the like.

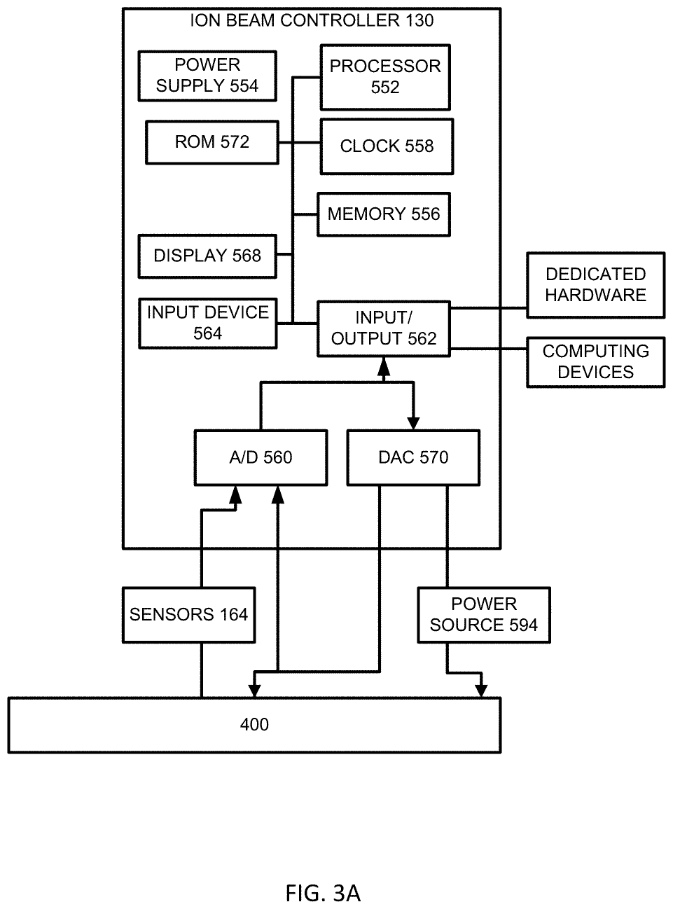

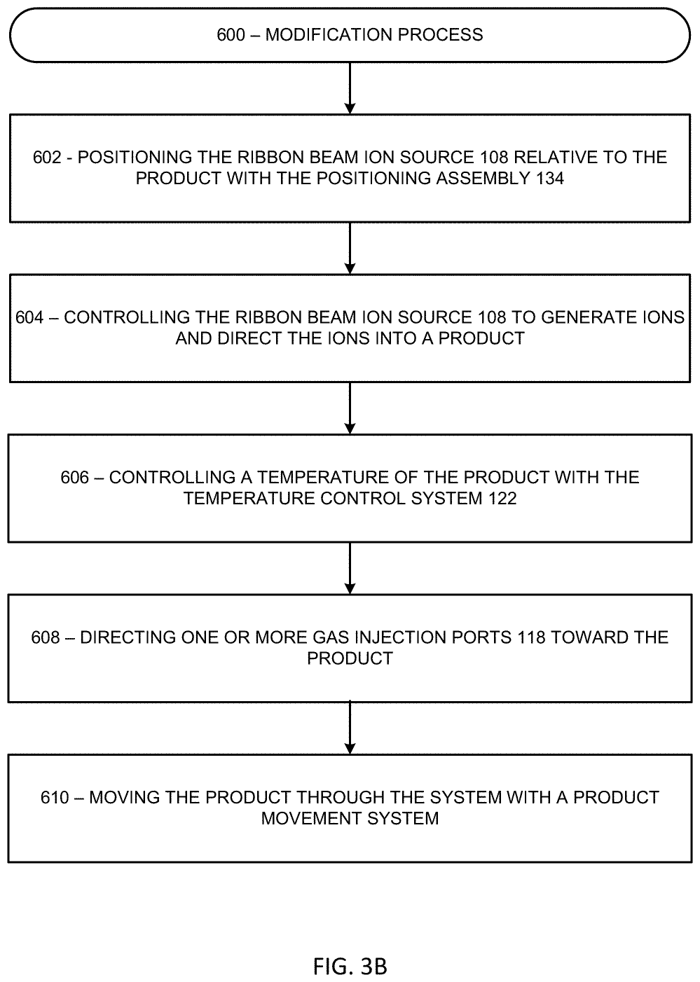

FIG. 3A illustrates an exemplary processing device that may be utilized at least in part for the processes according to the disclosure.

The various aspects illustrated in FIG. 3A and described herein may include any one or more aspects, components, and/or the like as described herein. In particular, FIG. 3A illustrates an exemplary implementation of the system controller 130 for use with various aspects of the disclosure including the treatment system 400. The system controller 130 may be implemented, may be controlled, may control, and/or the like in conjunction with other dedicated hardware in the treatment system 400. The system controller 130 may be implemented, may be controlled, may control, and/or the like in conjunction with the treatment system 400 and other computing devices as defined herein, and/or the like.

The system controller 130 may include one or more of a processor 552, a power supply 554, a memory 556, a display 568, a read-only memory 572, an input device 564, an input/output device 562, an analog-to-digital converter 560, a digital to analog converter 570, a clock 558, the one or more sensors 164, a power source 594, and/or the like.

The processor 552 may be configured to process at least in part a modification process 600, which may be implemented as a glass modification process. The one or more sensors 164 may measure various physical characteristics including voltage, current, power, temperature, pressure, flow, mass, optical reflectance, movement, location, and/or the like. More specifically, the one or more sensors 164 may measure various physical characteristics of components within the treatment system 400. In particular, the one or more sensors 164 may be implemented as one or more temperature sensors to measure a temperature of the ribbon beam ion source 108, the glass movement system 106, the gas cushion system 104, the ribbon beam ion source 108, the power equipment 114, the glass 190, a component of the treatment system 400, and/or the like. The one or more temperature sensors may be implemented as a Negative Temperature Coefficient (NTC) thermistor, a Resistance Temperature Detector (RTD), a thermocouple, a semiconductor-based sensor, and/or the like.

The one or more sensors 164 may measure various physical characteristics including voltage, current, power, and/or the like of the ribbon beam ion source 108, the glass movement system 106, the roller system 150, the temperature control system 122. For example, the one or more sensors 164 may measure various physical characteristics including pressure, a flow, and/or the like of the gas cushion system 104, the one or more gas injection ports 118, and/or the like. Thereafter, the system controller 130 may control the gas cushion system 104, the one or more gas injection ports 118, and/or the like based on pressure, a flow, and/or the like of the gas cushion system 104, the one or more gas injection ports 118, and/or the like. The one or more sensors 164 may measure various physical characteristics including optical reflectance, movement, location, and/or the like of the glass 190. In particular, the optical reflectance may be indicative of a physical nature of the modified portion 194 of the glass 190. Thereafter, the system controller 130 may control the ribbon beam ion source 108, the gas cushion system 104, the glass movement system 106, the roller system 150, and/or the like based the optical reflectance. For example, the system controller 130 may control the ribbon beam ion source 108, the gas cushion system 104, the glass movement system 106, the roller system 150, and/or the like based the optical reflectance of the modified portion 194 of the glass 190 to ensure the modified portion 194 exhibits the desired physical characteristics.

The system controller 130 may implement instrument integration, communication, process protocols, process time, and/or the like by utilizing an on-board script processor. The system controller 130 may allow user-defined on-board script execution for controlling process sequencing, process flow, decision making, and/or the like of the treatment system 400 and any of the associated components. Moreover, the system controller 130 may execute implementation of the modification process 600, and/or the like.

Additionally, the system controller 130 may implement an operating system, a touchscreen controller, a communications component, a graphics component, a contact/motion component, and/or the like to provide full functionality. In particular, the processor 552 may be configured to execute a software application configured to control the treatment system 400, the modification process 600 as described herein, and/or the like.

In one aspect, the software application may be configured to interact with the one or more sensors 164 and/or the like as described herein. In particular, the one or more sensors 164 may provide signals to the processor 552 through the analog-to-digital converter 560. Additionally, the digital to analog converter 570 in conjunction with the power source 594 may control and/or drive any component of the treatment system 400. In particular, the system controller 130 may provide signals via the digital to analog converter 570 in conjunction with the power source 594 to control the ribbon beam ion source 108, the gas cushion system 104, the glass movement system 106, the temperature control system 122, and/or the like.

The system controller 130 may implement a processing protocol that may include the modification process 600. The processing protocol may determine controls, signaling, and/or the like for delivery to the treatment system 400, the ribbon beam ion source 108, and/or the like. The system controller 130 may be configured to utilize outputs from the one or more sensors 164 in conjunction with the modification process 600.

The system controller 130, the dedicated hardware, system controller 130, the computing devices, and/or like may determine glass processing information for the glass 190 and provide the glass processing information to an output device such as the display 568, a printer, a database, an analysis system, and/or the like. In one aspect, the system controller 130, the dedicated hardware, system controller 130, the computing devices, and/or like may determine glass processing information and may store the glass processing information to the memory 556, another memory device, a database, and/or the like. Additionally, the glass processing information may be utilized by the system controller 130, the dedicated hardware, system controller 130, the computing devices, and/or the like to determine further control, feedback, and/or the like for the treatment system 400.

FIG. 3B illustrates an exemplary process in accordance with aspects of the disclosure.

The various aspects illustrated in FIG. 3B and described herein may include any one or more aspects, components, and/or the like as described herein. In particular, FIG. 3B shows an exemplary modification process (box 600) of the disclosure. In one or more aspects, the modification process (box 600) may be a glass modification process. In one or more aspects, the modification process (box 600) may be implemented by the system controller 130, the processor 552, the treatment system 400, the dedicated hardware, the computing devices, and/or the like.

In particular, it should be noted that the modification process (box 600) is merely exemplary and may be modified consistent with the various aspects disclosed herein. Moreover, the modification process (box 600) of the disclosure may include a process of manufacturing the glass 190 or other product. It should be noted that the modification process (box 600) may be performed in a different order consistent with the aspects described above. Moreover, the modification process (box 600) may be modified to have more process steps, combined process steps, or fewer process steps consistent with the various aspects disclosed herein.

The modification process (box 600) of the disclosure may include positioning the ribbon beam ion source 108 relative to the product with the positioning assembly 134 (box 602). In this regard, the positioning the ribbon beam ion source 108 relative to the product with the positioning assembly 134 (box 602) may include any one or more materials, structures, arrangements, processes, and/or the like as described herein.

For example, with reference to the description of the positioning assembly 134 described herein, the positioning the ribbon beam ion source 108 relative to the product with the positioning assembly 134 (box 602) may include operating the positioning assembly 134 to translate the ribbon beam ion source 108 relative to the product, such as the glass 190, along one, two, or three directional axes that are each orthogonal to any of the other axes. In some aspects, the positioning assembly 134 may be configured to rotate the ribbon beam ion source 108 about the one, two, or three directional axes. Additionally, the positioning the ribbon beam ion source 108 relative to the product with the positioning assembly 134 (box 602) may include any one or more materials, structures, arrangements, processes, and/or the like as described herein. The modification process (box 600) of the disclosure may include controlling the ribbon beam ion source 108 to generate ions and direct the ions into a product (box 604). In this regard, the controlling the ribbon beam ion source 108 to generate ions and direct the ions into a product (box 604) may include any one or more materials, structures, arrangements, processes, and/or the like as described herein.

For example, with reference to the description of the ribbon beam ion source 108 described herein, the controlling the ribbon beam ion source 108 to generate ions and direct the ions into a product (box 604) may include implementation of the ribbon beam ion source 108 and/or the system controller 130 to generate ions and direct the ions into the product, such as the glass 190, such that ion implantation can be used to alter the physical properties of a surface of the product. In further aspects, the system controller 130 may control the ribbon beam ion source 108 to control one or more of a divergence of an ion beam, change a length of an ion beam, plasma conditions, an ion implant density, an ion implant depth, an ion beam breadth, an ion energy, an ion current, an ion power, an ion distribution, an implantation axis, an ion acceleration voltage, an ion dose, an atomic concentration of ions, an implant thickness, and/or the like of the ion beam of the ribbon beam ion source 108.

Additionally, the controlling the ribbon beam ion source 108 to generate ions and direct the ions into a product (box 604) may include implementation of the gas system 156 to implement use of a single gas or a gas mixture, such as one or more of nitrogen, argon, other noble gases, and/or the like to provide a variable depth implant of the ions by the ribbon beam ion source 108. Additionally, the controlling the ribbon beam ion source 108 to generate ions and direct the ions into a product (box 604) may include any one or more materials, structures, arrangements, processes, and/or the like as described herein.

The modification process (box 600) of the disclosure may include controlling a temperature of the product with the temperature control system 122 (box 606). In this regard, the controlling a temperature of the product with the temperature control system 122 (box 606) may include any one or more materials, structures, arrangements, processes, and/or the like as described herein.

For example, with reference to the description of the temperature control system 122, the controlling a temperature of the product with the temperature control system 122 (box 606) may include implementing the temperature control system 122 to control the temperature of the product during the ion implantation by the ribbon beam ion source 108. Additionally, the controlling a temperature of the product with the temperature control system 122 (box 606) may include any one or more materials, structures, arrangements, processes, and/or the like as described herein.

The modification process (box 600) of the disclosure may include directing one or more gas injection ports 118 toward the product (box 608). In this regard, the directing one or more gas injection ports 118 toward the product (box 608) may include any one or more materials, structures, arrangements, processes, and/or the like as described herein.

For example, with reference to the description of the one or more gas injection ports 118, the one or more gas injection ports 118 to flow an inert gas, such as one of the noble gases, hydrogen, nitrogen, and/or the like to create a cushion of gas in a gap 120 between the product and the temperature control system 122 and/or the heatsink 126. Additionally, the directing one or more gas injection ports 118 toward the product (box 608) may include any one or more materials, structures, arrangements, processes, and/or the like as described herein.

The modification process (box 600) of the disclosure may include moving the product through the system with a product movement system (box 610). In this regard, the moving the product through the system with a product movement system (box 610) may include any one or more materials, structures, arrangements, processes, and/or the like as described herein.

For example, with reference to the description of the glass movement system 106, the moving the product through the system with a product movement system (box 610) may include implementing the glass movement system 106 utilizing the roller system 150 while the temperature control system 122, such as a cooled plate, is implemented. In particular, the temperature control system 122 and/or the heatsink 126 may be arranged between the roller system 150 of the glass movement system 106. Additionally, the moving the product through the system with a product movement system (box 610) may include any one or more materials, structures, arrangements, processes, and/or the like as described herein.

FIG. 4 is a cross sectional view of a source assembly according to an aspect of the disclosure.

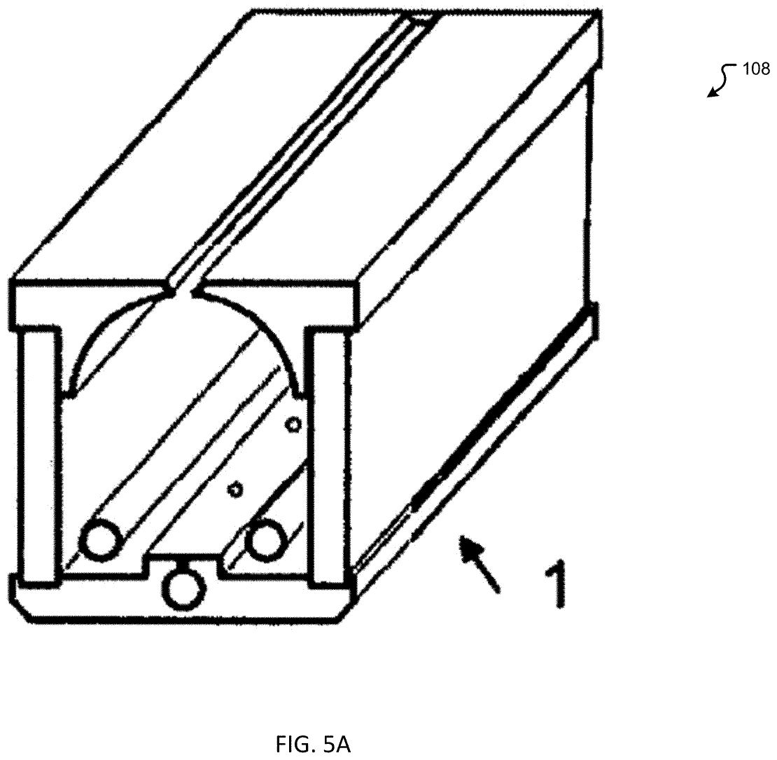

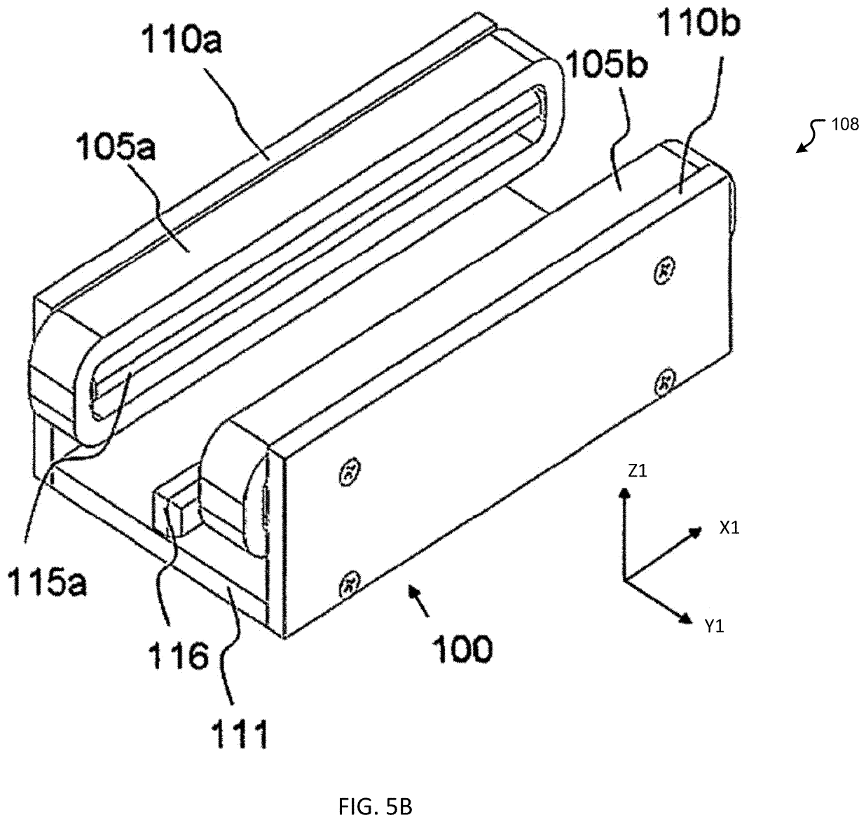

FIG. 5A is a perspective sectional view of an arc discharge chamber according to FIG. 4.

FIG. 5B is a perspective overhead view of a magnetic field generating yoke subassembly according to FIG. 4.

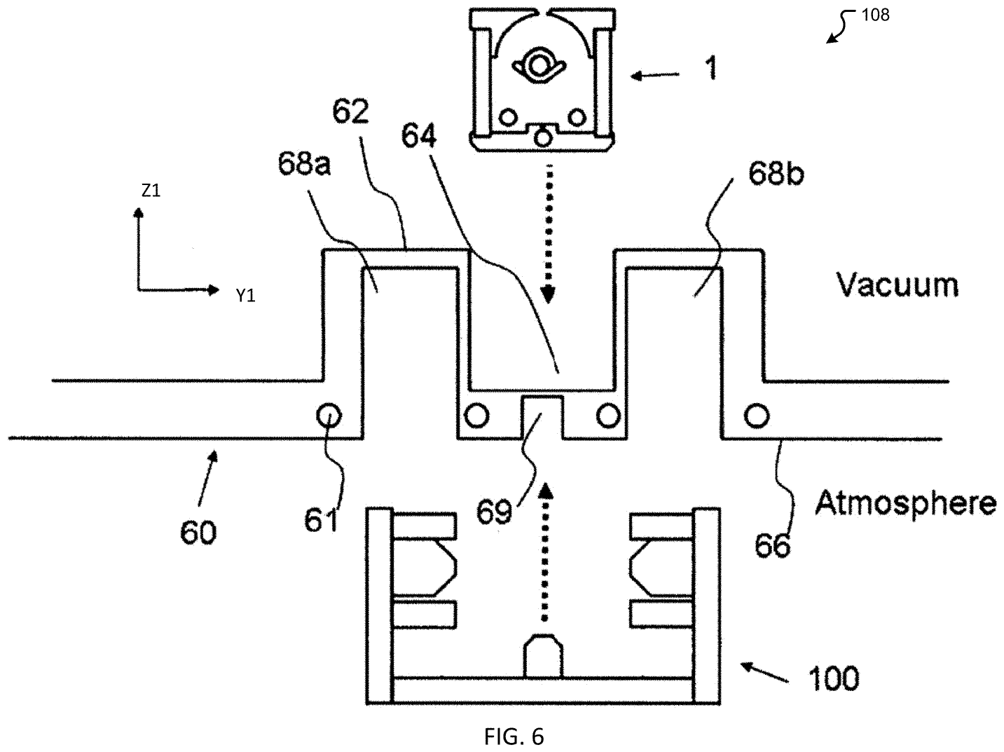

FIG. 6 is an exploded section view showing structural arrangements of and aligned inter-fittings for an arc discharge chamber and a primary electron trap assembly that includes an intervening partition barrier and a magnetic field generating yoke subassembly according to FIG. 4.

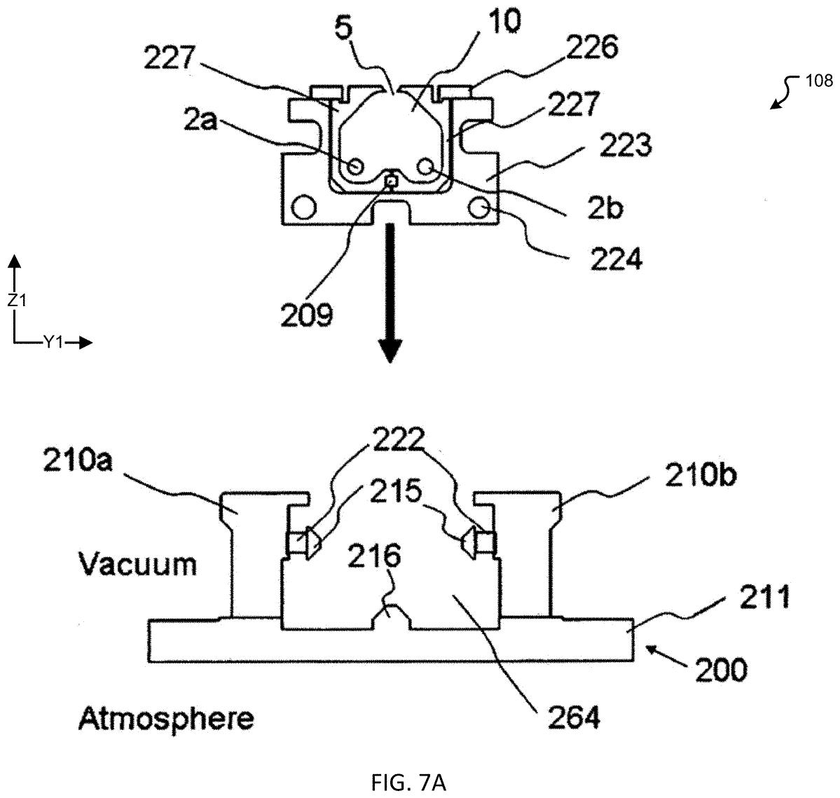

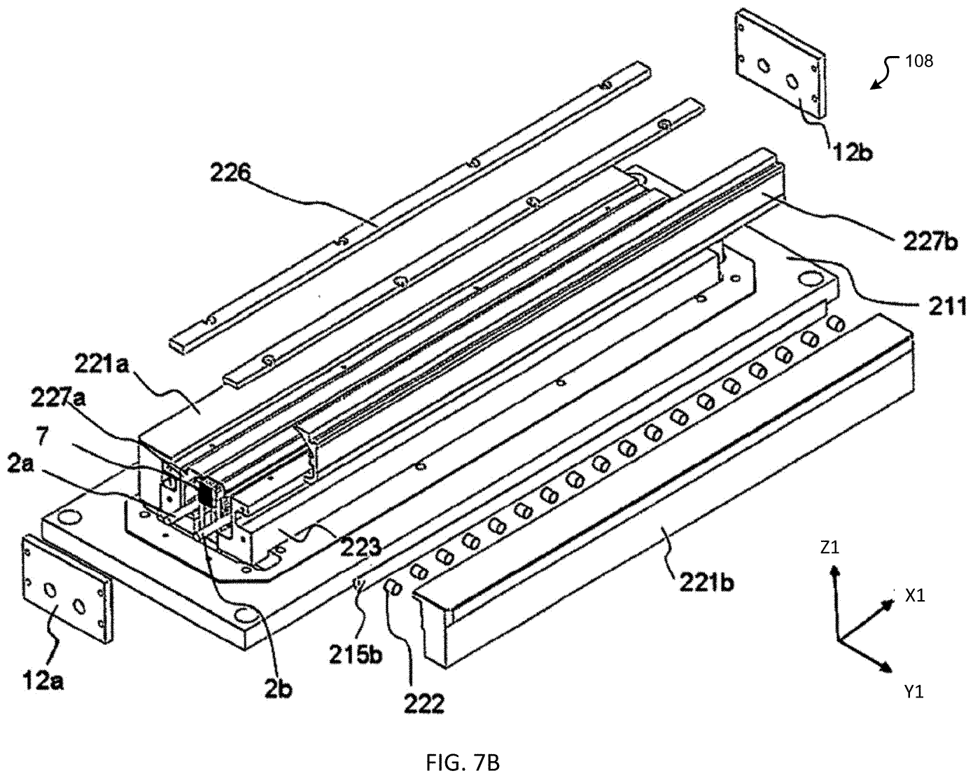

FIG. 7A is a partially exploded section view of an ion source according to the disclosure.

FIG. 7B shows a perspective view of an ion source, partially disassembled, according to FIG. 7A.

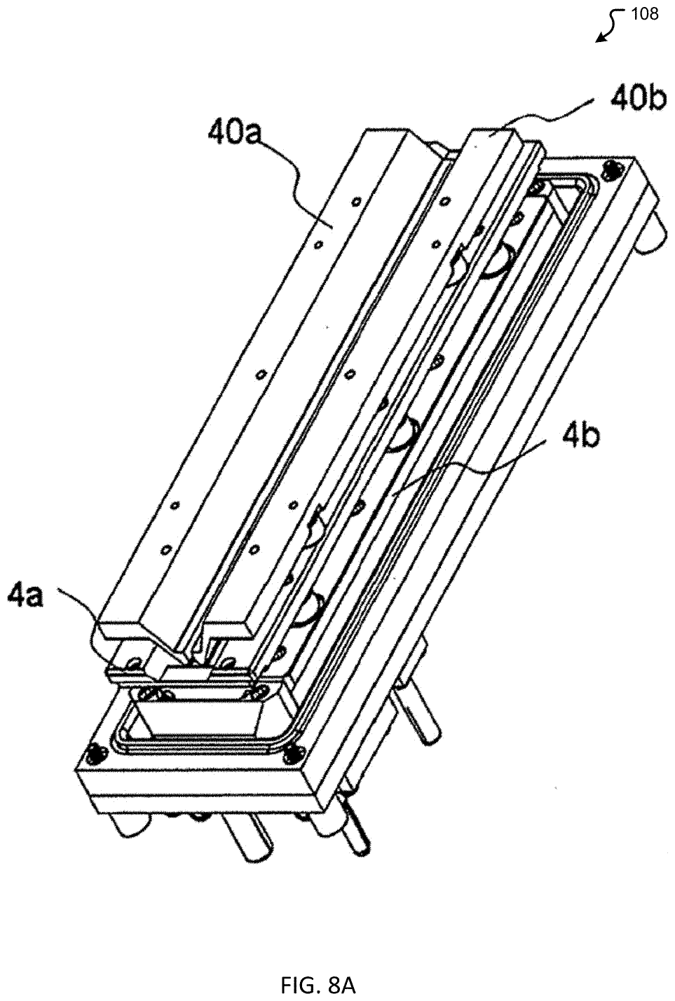

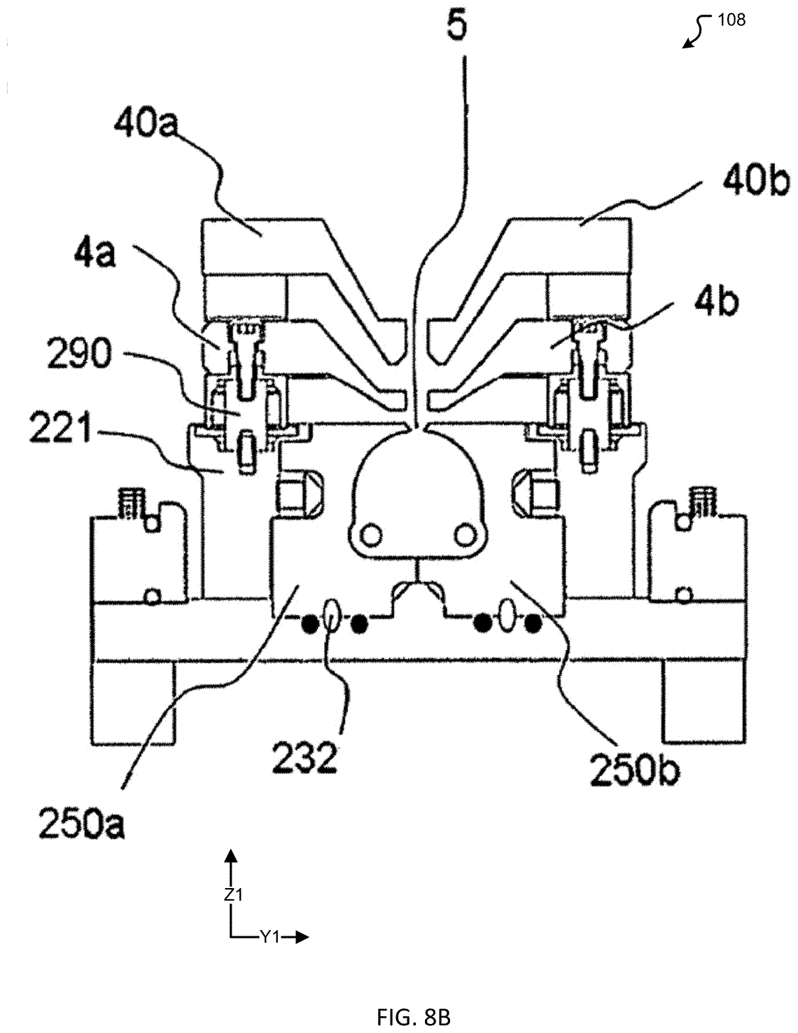

FIG. 8A is a perspective view of a second aspect which shows a positioning of extraction electrodes according to the disclosure.

FIG. 8B is a cross section view of the second aspect showing the detailed mounting of the extraction electrodes according to FIG. 8A.

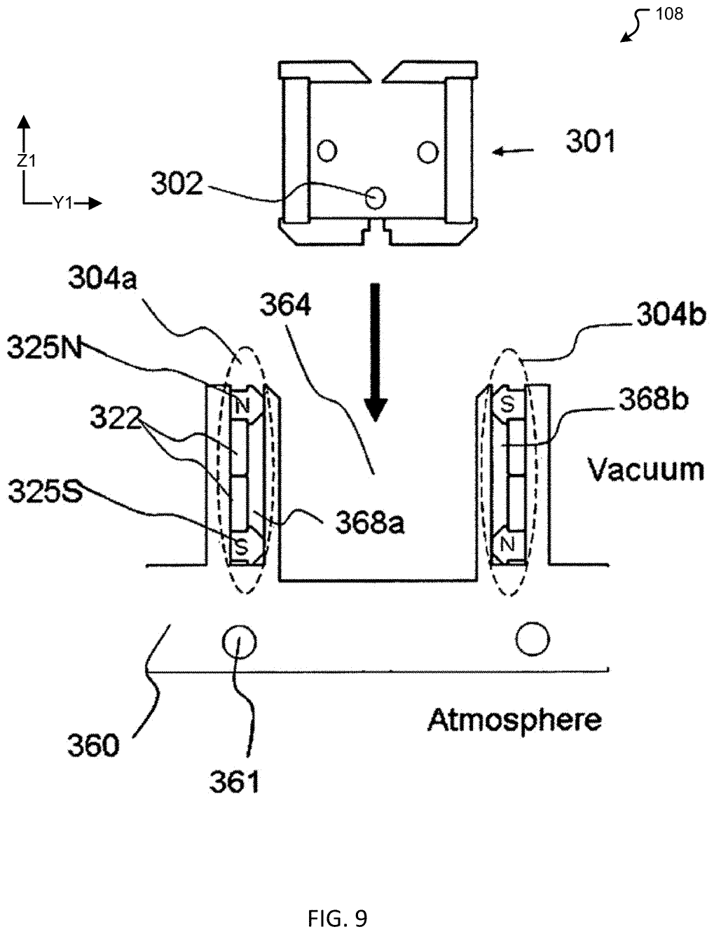

FIG. 9 is a partially exploded cross-sectional view of a third aspect of the ion source according to the disclosure.

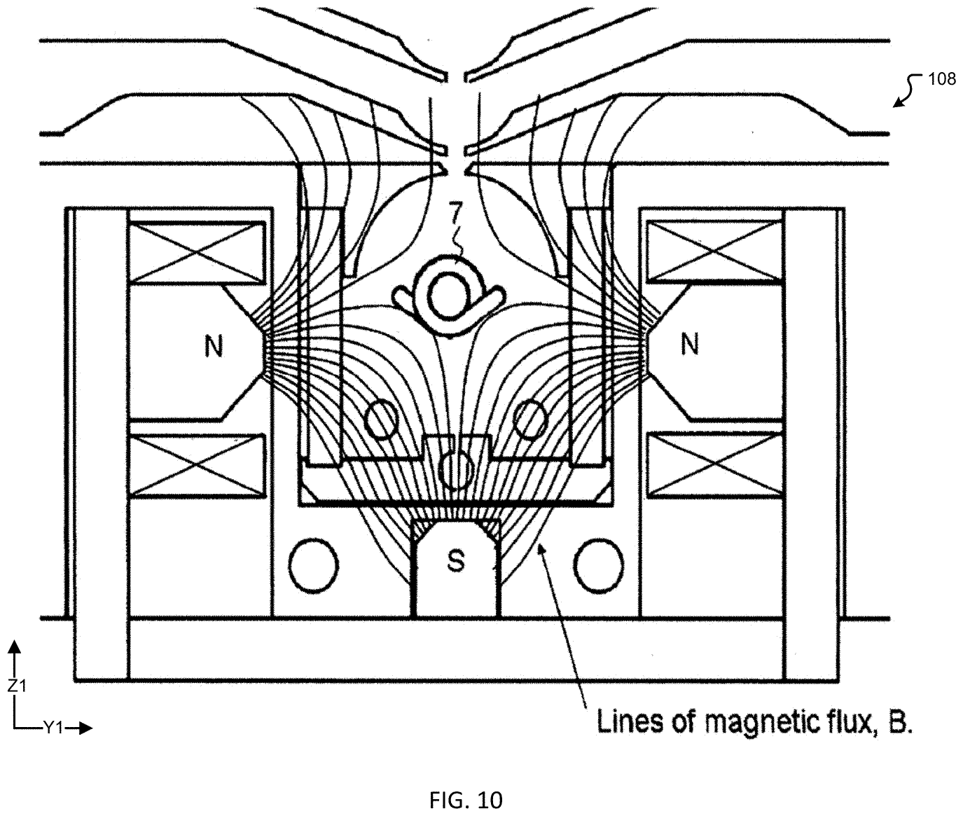

FIG. 10 shows lines of magnetic flux superimposed over a cross-section of an arc discharge chamber in the first aspect according to FIG. 4.

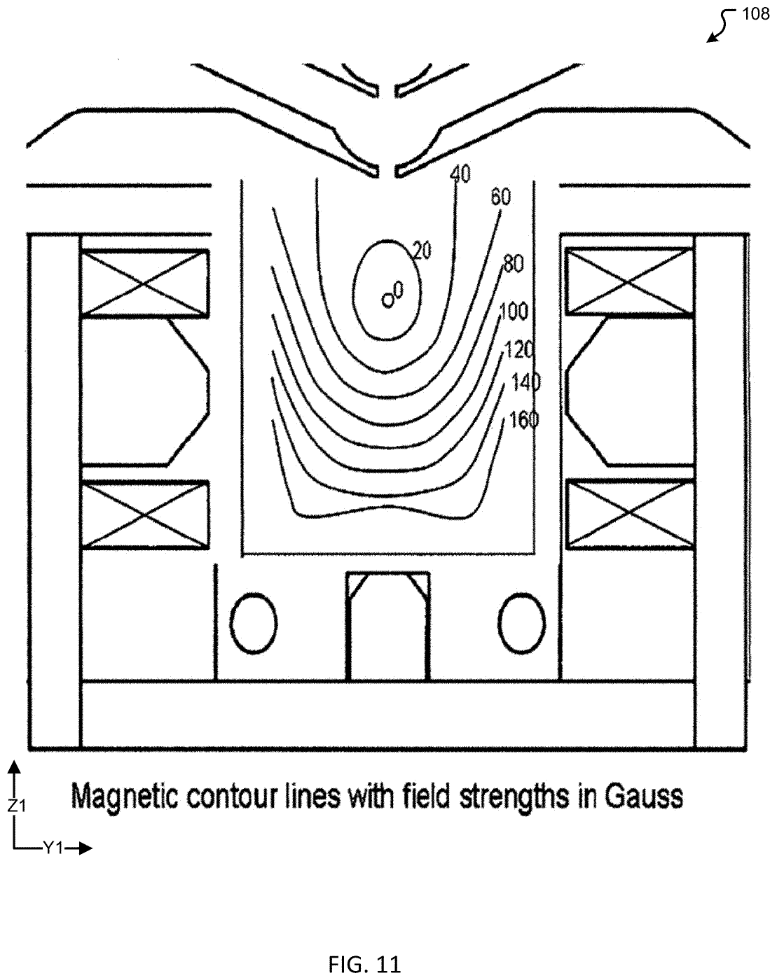

FIG. 11 shows contours of magnetic field strength and a null point at zero value in the magnetic field superimposed on the cross section of the arc discharge chamber in the first aspect according to FIG. 4.

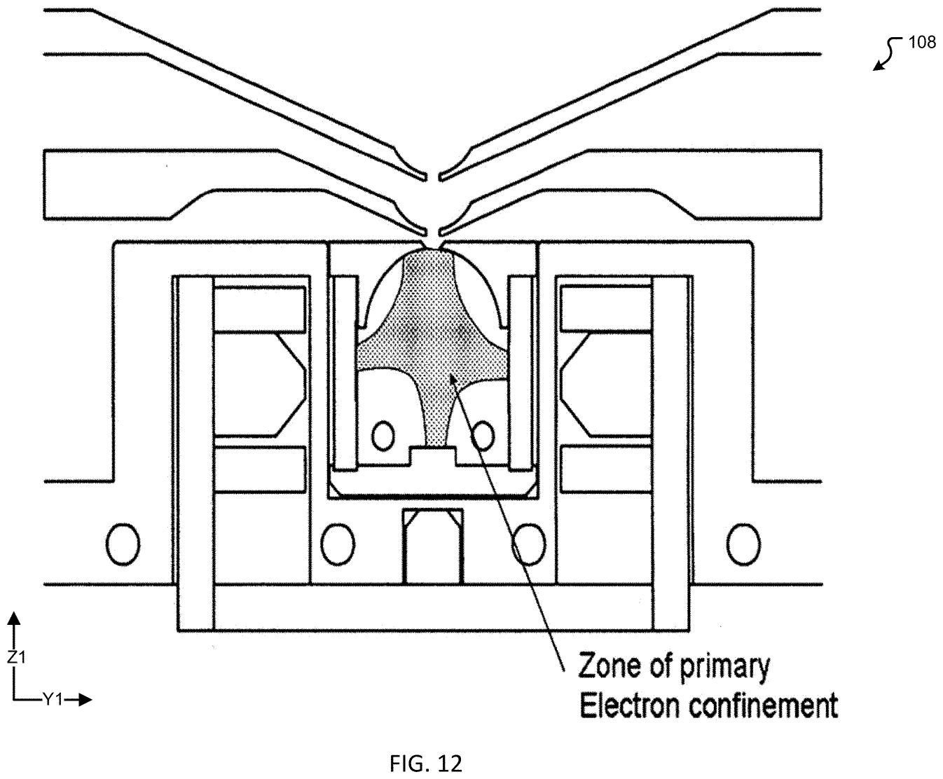

FIG. 12 shows a portion of the spatial zone within the cavity volume of the arc discharge chamber in which primary electrons from the thermionic cathode are trapped by the combined magnetic fields, superimposed on the cross section of the arc discharge chamber in the first aspect according to FIG. 4.

The various aspects illustrated in FIG. 4, FIG. 5A, FIG. 5B, FIG. 6, FIG. 7A, FIG. 7B, FIG. 8A, FIG. 8B, FIG. 9, FIG. 10, FIG. 11, and FIG. 12 and described herein may include any one or more aspects, components, and/or the like as described herein.

The ribbon beam ion source 108 may include a closed, solid wall, prism-shaped implementation of the arc discharge chamber 1 having limited width and depth dimensions, and which concurrently may have an arbitrarily chosen and predetermined length dimension which can be as small as 80 millimeters and alternatively may exceed 3,000 millimeters in size; and a primary electron trap assembly that may include at least an adjacently located magnetic field generating yoke subassembly able to provide a discernible quadrupole magnetic field internally within a confined cavity volume existing within the measurable dimensions of the arc discharge chamber walls.

The ribbon beam ion source 108 may include structural features that may include an intervening cooled partition barrier which may serve to orient, align, and separate the magnetic field generating yoke subassembly at a fixed distance from and in a surrounding adjacent position around the arc discharge chamber 1, and cools the magnetic components to protect them from heat and high temperatures; and a triode or tetrode beam extraction electrode system where each electrode may include two separate pieces, one on each side of the beam, connected electrically to appropriate power supplies, and mounted using insulators to the magnetic yoke subassembly or to the cooled partition barrier, in order to maintain precise control of the spacing in the Y1-axis and Z1-axis directions of the different electrodes from each other, along the full breadth of the beam, notwithstanding the effects of thermal expansion caused by heat radiation and accidental beam strike on the electrodes.

The closed arc discharge chamber 1 may be an elongated, prismatic shaped, solid wall housing traditionally made of refractory material(s); may have a confined cavity volume of fixed configuration and determinable dimensions; may include at least one discrete rod-shaped anode electrode and at least one discrete cathode electrode individually placed upon the walls within the chamber's confined cavity space; provides one or more controlled conveyance ports through which a gaseous substance can be introduced to the confined cavity space of the chamber; and may present at least one open exit aperture at the front of the arc chamber, through which ions can be extracted to form a traveling ribbon-shaped beam.

Within the internal cavity space of the prismatic shaped implementation of the arc discharge chamber 1 may be at least one thermionic cathode, which may be implemented with a 10 mm diameter loop of tungsten wire or slab of tungsten, and heated to over 2000 degrees C., disposed upon or close to one end wall surface and set at or slightly positive with respect to the electrical potential of the arc discharge chamber 1; and at least one rod-shaped anode, and possibly may include two elongated anode rods, individually disposed close to an interior face surface of a laterally positioned adjoining sidewall, and which extends over the entire arbitrarily chosen length dimension of the arc chamber. The rod-shaped anode(s) may be connected to the positive terminal of a recognized source of electrical power at between 40 V and 120 V; and the cathode(s) may be connected to the negative terminal of the same source of electrical power, and the arc chamber may be connected by resistive connection to be between about 0 and 5 V positive with respect to the cathode.

Because the prism-shaped implementation of the arc discharge chamber 1 may reside in a vacuum environment, while the adjacently located magnetic field generating yoke subassembly of the primary electron trap assembly may be located in an ambient gas environment, the two components may be operatively oriented, correctly aligned and properly held in separated adjacent positions.

For achieving this purpose, a non-magnetic partition barrier may be tangibly placed as an intervening divider between the two components. This partition barrier may be employed as an intervening rampart and dividing bulwark by which to orient and align properly the arc discharge chamber 1 at a fixed spatial distance adjacently to the magnetic field generating yoke subassembly—while concomitantly maintaining the physical separation of the vacuum environment from the ambient gas environment.

In such environment-separation instances, it may be beneficial that the intervening partition barrier also provide internal coolant passages to maintain it at or near room temperature in spite of the substantial radiated heat from the arc discharge chamber 1; and it may be beneficial that the partition barrier be correspondingly shaped so as to surround the exterior faces of the arc chamber structure over its back wall and at least two of its oppositely situated adjoining sidewalls.

The discrete magnetic field generating yoke subassembly of the primary electron trap assembly may thus form a discrete operational article and tangible structure that can appear in a variety of different construction formats:

A first operative format is a multipole array that may include at least three discrete ferromagnetic pole constructs of alternating polarity, which may be individually disposed in series upon an open U-shaped yoke framework. All three ferromagnetic poles in the multipole array may be physically separated and lie apart from each other each on one internal face of the yoke frame.

This multipole array and yoke framework may constitute the yoke subassembly, which may then be positioned at a set distance apart from, and may become adjacently located around and over the exterior faces of the adjoining sidewalls and back wall of the arc discharge chamber 1; and then may in a direction of magnetization orthogonal (or perpendicularly, or normal) to the length dimension of the arc discharge chamber 1. Of the three ferromagnetic poles in this format of the magnetic field generating yoke subassembly, one of these poles may be an elongated shaft or bar formed of ferromagnetic matter, while two of these magnetic pole constructs may be elongated shafts or bars formed of ferromagnetic matter around which are placed elongated wire winding coils.

In marked difference, a second format of the magnetic field generating yoke subassembly is an arrangement of a U-shaped ferromagnetic yoke framework, upon each of two opposing sides of which may be mounted an elongated ferromagnetic pole, connected to the yoke with a linear array of permanent magnets, so as to magnetize the two opposed ferromagnetic poles with the same polarity. A third ferromagnetic pole may be attached to the internal face corresponding to the base of the U-shape, thereby presenting to the interior a pole of the opposing polarity to the side poles. Again the direction of magnetization presented by this yoke framework may be everywhere substantially orthogonal (or perpendicularly, or normal) to the length dimension of the arc discharge chamber 1.

In this format, at least three discrete ferromagnetic poles may be disposed in sequential series upon a U-shaped yoke framework, and at least two of the three incorporate permanent magnets. The entire open yoke subassembly may then be placed at a known distance apart from but adjacent to the exterior faces and exterior perimeter of three co-joined walls in the arc discharge chamber 1, with the direction of each pole's magnetization being orthogonal (i.e., perpendicular or normal) to the arc chamber's X1-axis and length dimension.

Alternatively, a spaced multipole array of four or more ferromagnetic rods magnetized by connected commercially available permanent magnets disposed individually in sequential series may be used as a third desirable structural format of the magnetic field generating yoke subassembly.

This particular third format and arrangement has the extra advantage that the total number of individual permanent magnets may be increased as needed for the production of different strengths of generated quadrupole magnetic field. This third multiple permanent magnet construction model is transversely integrated upon a supporting yoke framework to form a subassembly; and this yoke subassembly may then be transversely positioned with respect to the chosen length dimension and X1-axis of the arc discharge chamber 1.

Because the beam is extracted as one continuous ribbon, not a series of beamlets, it can have a very low emittance and consequently deliver such advantages, depending on the application, as ease of focusing, high resolving power in mass-analyzing systems, and accurate delivery to a target. The methods of extracting the ion beam overcome known difficulties of maintaining uniformity and low divergence, and include the formation of very low energy beams suitable for a wide variety of applications: implantation, sputtering, IBAD, and material modification.

In a third alternative use circumstance, the disclosure can be closely integrated into the structure of a flange or plate forming a part of the vacuum wall. The ribbon beam ion source 108 typically and routinely will lie disposed within a volume confined and dimension limited, closed vacuum environment which is able to provide an ambient vacuum ranging from about 10⁻² Pa to about 10⁻⁴ Pa, while within the arc chamber of the ribbon beam ion source 108 the pressure is of the order of 1 Pa, these values being determined by the necessary supply of gas to the ribbon beam ion source 108, and assuming the provision of generous vacuum pumping.

The arc chamber may be attached to and enclosed within structures integrated into the vacuum wall. Furthermore, the magnet assembly may be nested on the opposite (atmospheric) side of the vacuum wall and enclose three sides of the arc chamber. Where applicable, this is simpler and more compact than many existing ion source designs.

In a fourth alternative use circumstance, of use where the only desired process gases are gaseous elements, such as the noble gases, oxygen, and nitrogen, the arc chamber itself may be water-cooled.

In an alternate fifth circumstance, the desired species may include elements which can condense on surfaces at room temperature, and elevated temperatures are preferred or essential. In some instances, an elevated wall temperature changes the chemistry to favor a particular ion from a mixture of gases/vapors or gaseous molecules. Under these conditions the arc chamber is made of refractory material and is located within a cooled metal heat-shield structure.

In a sixth expected use circumstance, no extraction electrodes or voltage are used, and the plasma may be allowed to diffuse out of the ribbon beam ion source 108 and is used for controlling potentials in an ion beam extracted from another ion source, or on the surfaces of exposed materials.

II. Pertinent Points of Information

For proper reference as well as for accurate understanding of the essential alignments, different planes and axes, and individual disclosure components, the following orientations, nomenclature and terminology is presented as the proper language and jargon; is identified accurately and described precisely as to its proper and appropriate usage; and is consistently and uniformly employed hereinafter.

The Arc Discharge Chamber Nomenclature

By definition, a right prism is a three-dimensional configuration formed and bounded by two polygonal surfaces which are joined together by a series of lateral planes; and a cross-sectional view of this configuration may result in the exact shape of its two identical ends. In mathematical prism geometry terms, each polygon is traditionally called a “base”, and each laterally disposed straight line unit is called a “side”.

If the right prismatic shaped implementation of the arc discharge chamber 1 is a regular and symmetrical geometric form, the chamber can appear in the alternative as a triangular prism, a rectangular prism, a square prism, a pentagonal prism, a hexagonal prism, an octagonal prism, etc. A triangular form is not ideal; a rectangular form is the basis of the discussion, but the number of sides could be increased. Thus, as the shape of the polygonal base varies, so may the number of juxtaposed lateral sides. Moreover, while two lateral sides are the minimal number, the true existing number of sides in any single prismatic format may be as great as eight or the laterally juxtaposed sides.

Consequently, for each of these alternative chamber prismatic shapes, there therefore may always be:

(a) Not less than five exterior faces, and six discrete faces, in the rectangular prismatic shaped arc chamber;

(b) Not less than two laterally positioned adjoining sidewalls in the prismatic shaped chamber;

(c) Two contiguous end walls, in the rectangular prismatic shaped chamber these are bases; and

(d) Identifiable, measurable and fixed depth, width, and length dimensions for the prismatic shaped chamber.

Orientations, Dimensions and Cartesian Coordinates Pertaining to the Arc discharge chamber 1

It is critical and essential that the practitioner in the technical field always be able to identify and distinguish between the front wall and the back wall of the arc chamber structure; as well as to separate and correctly identify each laterally positioned adjoining sidewall as being different and distinct from each contiguous and abutting end wall in the arc chamber construction.

For proper orientation purposes, that particular exterior face and recognizable solid wall of the prismatic shaped geometry for the rectangular implementation of the arc discharge chamber 1 which presents the open channels, unobstructed slits, or apertures through which the beam is intended to exit is correctly identified as and may be referred to herein as the ‘front’ or forward wall; and the directly opposite closed wall and exterior face in the chamber construction is properly referred to as the ‘back’ or rearward wall. The remainder of the prismatic shaped chamber geometry presents a plurality of oppositely situated and laterally juxtaposed solid adjoining sidewalls identifiable as such; as well as two discernible solid contiguous end wall(s).

As noted in one or more of FIGS. 4-13, Cartesian coordinate axes (X1, Y1, and Z1 axes) are illustrated in the drawings simply to identify and describe an arrangement and orientation of the components. However, the Cartesian coordinate axes illustrated in FIGS. 4-12 may not correspond to the Cartesian coordinate axes (X, Y, and Z axes) illustrated FIGS. 1-3.

Accordingly, for the disclosure, the direction extending from the back wall to the front wall of the prismatic shaped arc chamber is the Z1-axis and the travel pathway for the extracted ion beam. The minor distance dimension and direction existing between a first laterally placed adjoining sidewall and an oppositely situated second laterally positioned adjoining sidewall is the Y1-axis and presents the width dimension in the arc discharge chamber 1; and the plane, major distance dimension and direction extending from at least one contiguous end wall (and often to another to the other oppositely placed contiguous end wall side-wall) is the X1-axis and arbitrarily chosen length dimension of the arc discharge chamber 1 (corresponding to the breadth dimension of the extracted beam).

The major distance dimension of the prismatic shaped geometry in the arc discharge chamber 1 is the length measurement—which is arbitrarily chosen in size, always extends over and along the X1-axis, and is a direct function of and corresponds with the measurable breadth aspect of the extracted ribbon shaped ion beam. This length dimension can arbitrarily be chosen and increased in magnitude at will to almost any meaningful size as desired or needed by the intended application; can range from about 80 mm to more than 3,000 mm; and typically, may be about 500 mm to about 2,000 mm in size.

The minor distance dimension of the prismatic shaped geometry in the arc discharge chamber 1 is the width measurement—which may be fixed in size and always lies over and along the Y1-axis, and may correspond in direction with the thickness aspect of the extracted ribbon-shaped ion beam.

Definitions, Phrasing & Terminology

A ‘dipole magnetic field’ is the field produced by a pair of poles of opposite polarity. If the poles are quasi-infinite planes, the field is uniform.

A ‘quadrupole magnetic field’ is the field produced by four poles symmetrically disposed around an axis. The poles alternate in polarity, and in the purest from are assumed to have the shape of a right hyperbolic surface asymptotic to a pair of planes through the origin. In this form, if one plots the magnitude and direction of the field around a circle centered on the origin, the magnitude is found to be constant, but the direction rotates once in passing around the circle. The magnitude of the field is proportional to the radius of the circle.

A ‘sextupole magnetic field’ is constructed in a similar manner but with six alternating poles, and the hyperbolae are asymptotic to planes inclined 60 degrees to each other instead of 90 degrees. The magnitude of the field is again constant around a circle, but the field direction changes twice in passing round the circle. The magnitude of the field is proportional to the square of the distance from the center.

The terms ‘interior faces’, ‘vertex corners’ and ‘marginal edges’ of the internal cavity volume in the arc discharge chamber 1 geometry are consistently identified and recognized as being individually distinguishable internal cavity volume locations, which are: Those spatial areas existing between a first laterally positioned adjoining sidewall and the back wall; and a second separate internal spatial area which concurrently exists between an oppositely situated second laterally positioned adjoining sidewall and the back wall. The corner may or may not have a fillet radius.

It is also self-evident that these terms—‘interior faces’, ‘vertex corners’ and ‘marginal edges’—pertain to the spatial relationships existing between each of the two laterally positioned adjoining sidewalls with the front and backs walls respectively; and the end walls as such of the arc chamber are not involved in identifying what are these portions of the internal cavity volume

III. The Operative Ion Source

In all intended applications and alternative circumstances of use, the disclosure is to the ribbon beam ion source 108 wherein at least one gaseous substance is ionized into a plasma state within an arc discharge chamber 1 and a resulting ribbon-shaped charged ion beam is extracted, the beam then traveling in the Z1-axis direction. However, to achieve its purpose, the ribbon beam ion source 108 may comprise and include not less than at least two discrete structural moieties—a prismatic-shaped implementation of the arc discharge chamber 1 and a primary electrode trap assembly.

In prior art practice, an ion beam may be obtained by using a conventional triode or tetrode beam formation system. In these conventional systems however, owing to the need to maintain very small levels of variation of the electrode spacing—combined with the production of an arbitrarily large sized bream breadth in the presence of substantial heating by beam collision, radiation, and other heat mechanisms—there are multiple substantive challenges which must be confronted and directly addressed. These well recognized multiple substantive challenges are confronted and solved by the disclosure disclosed below, as exemplified and illustrated by the different embodiments described in detail herein.

A. The Prismatic-Shaped Arc Discharge Chamber

The Prism Geometry of the Chamber

The arc discharge chamber 1 may be a preformed, rectangular prism-shaped, solid-wall closed box fabricated of a conductive material, such as a refractory material; or else is an actively cooled structure, such as cooling by means of internal water passages.

The arc chamber geometry may have the shape of a rectangular prism, inside which a confined cavity space exists; and from which the ion beam may emerge. As a rectangular prism, its configured box geometry includes a front wall having at least one exit aperture, a back wall, two oppositely situated and laterally placed adjoining sidewalls, and two discrete and oppositely located contiguous end walls. Bounded within this geometric construction is an internal cavity space which is confined in volume and limited in its configured dimensions.

The overall box geometry of the rectangular prism arc chamber is elongated in the X1-axis direction and has an internal cavity volume which is suitable for the at-will introduction therein of a pre-chosen gaseous substance, which is ionized in-situ into a plasma state. For gas ionization purposes, the internal cavity volume configuration is typically either rectangular or rounded in cross-sectional shape; but can be configured in almost any shaped format whenever needed or desired.

Typically, the box-like geometry of the chamber may have internal size dimensions in which the two oppositely situated and laterally positioned adjoining sidewalls of the chamber are about 20-50 mm apart in width along the Y1-axis direction, and extend about 20-50 mm in depth from the front wall to the back wall in the Z1-axis direction; while the internal spacing between the two contiguous and abutting end walls may vary from about 80 millimeters to 3 meters or more in measurable length along the X1-axis direction.

Traditionally, that wall of the arc discharge chamber 1 containing the exit aperture is referred to as the ‘front’. The front wall of the chamber may contain at least one elongated exit aperture or slit structure running in the X1-axis direction; and provide for the egress of ions from the plasma, an egress which can be accelerated and be formed to emerge as a ribbon beam.

The arc chamber box may be constructed in a variety of different ways; but a particular technique is to fabricate two identical or near-identical discrete halves or split-sections, the split passing through the exit aperture. It would be possible to substitute an array of open slots or channels for one continuous exit aperture. When the length of the arc chamber exceeds about 1 m and a continuous open slot is used, maintaining the wall portions of the slot opening in parallel, in good alignment, and uniformly together is challenging; and for this reason, the specific embodiments described below directly address this challenge. Internal corners may be rounded in shape.

The Heated Cathode(s)

A heated cathode able to emit primary electrons is provided and lies tangibly disposed at one identifiable interior end wall face within the cavity volume of the arc discharge chamber 1.

As is described more fully below, the quadrupole magnetic field shape may include four line-cusps, three of which are near the externally located magnetic poles. It is necessary for correct functioning of the ion trap that the magnetic field lines at these four cusps intersect defined potential surfaces which are at or negative with respect to the cathode potential; and for simplicity this potential value may be defined and provided by the arc chamber walls. To meet this requirement the heated cathode may have a potential value between 0 and about 5V positive with respect to the measurable potential of the arc chamber.

Cathode Operation and Function

Typically, the cathode disposed at one end wall of the arc discharge chamber 1 may be heated electrically until it emits a stream of moving electrons into the cavity volume of the arc chamber; and those initially emitted electrons are often referred to as ‘primary electrons’. Other kinds of electrons are also present, including those primary electrons which have lost significant energy in an inelastic collision with an atom, electrons detached in such collisions, and electrons detached from the walls by ion impacts; and these are typically referred to as ‘secondary electrons’.

For a very long arc chamber, an additional cathode may be placed at the opposite end, and if required an intermediate cathode or cathodes may be used. The cathode may be an electrically heated filament of tungsten or tungsten alloy; or it may be an indirectly heated cathode, or be a more massive cathode—such as that shown in FIG. 7b which is a 6 mm thick block of tungsten cut to form an interdigitated shape which can be directly electrically heated. The cathode is located so that the null field axis passes through it near its center, a circumstance which ensures that the primary electrons encompass this axis and are correctly trapped. The arc current can be regulated by adjusting the power delivered to the cathode.

The total ion current may be measured, and this signal may be compared to a reference signal; and the difference may be used to adjust the cathode temperature, hence the arc current, hence the ion beam current. The cathode should present a large area to substantially overlay the area in which electrons can be trapped, as shown in FIG. 11.

The Rod-Shaped Anode(S)

The anode may typically take the form of one or more rods, bars or shafts which extend along the X1-axis and run over the full-length dimension of the arc chamber. The anode structure may, for example, extend through holes to a pair of mounting locations which lie external to the arc chamber structure. The rod-shaped anodes are individually connected to the positive terminal of an arc power supply, whose negative terminal may then be connected to the cathode and to the arc chamber. This supply can be adjusted to supply many amperes at 40 to about 120V.

Anode Placement within the Cavity Volume

It is essential that the primary electrons emitted from the cathode cannot directly reach the anode(s) then disposed within the cavity volume—so that the primary electrons may become spatially trapped within the central spatial zone of the cavity volume; and then pass back and forth repetitiously within the central spatial zone of the cavity volume until the electrons suffer an inelastic collision with a gas atom or molecule, lose energy, and create charged ions in-situ.

The anode rod(s) may therefore be tangibly located close to the inner face surfaces of one or more laterally positioned adjoining sidewalls within the chamber's cavity volume, wherein the quadrupole magnetic field lines isolate and separate it (or them) from the central spatial zone of the cavity volume—i.e., that spatial region into which the primary electrons are initially emitted by the cathode. This circumstance is illustrated by FIG. 10 which shows several magnetic flux lines passing between the anode rods and the central spatial zone.

The particular placement of the rod-shaped anode(s) and its territorial interaction with the discernible quadrupole magnetic field then existing within the cavity volume of the arc chamber forms the magnetic electron trap circumstance and initiates the primary electron trapping event—by confining the moving primary electrons to a four-lobed central spatial zone (as illustrated in FIG. 12).

The installed quadrupole magnetic field serves an essential operating role by preventing the moving primary electrons from reaching the rod-shaped anode(s) then positioned upon the inner wall face(s) of the laterally positioned adjoining sidewall(s) of the arc discharge chamber 1; and provides a magnetic trapping effect by redirecting electrons away from the rod-shaped anode(s) and effectively confining all the moving electrons (both the primary electrons and the secondary electrons) to the four-lobed central spatial zone of the cavity volume.

The magnetic field protection created for the disposed rod-shaped anode(s) may be very effective: After the trapped electrons have lost some energy, the probability for large-angle repulsive elastic scattering from other electrons may rise in inverse proportion to their velocity; and the trapped electrons may more rapidly share their energy and reach a thermal equilibrium within the confines of the spatial magnetic trap. Inelastic collision processes also play a substantive role for the electrons moving within the discernible limits of the magnetic trap.

In addition, the increased rate of scattering permits a few of the moving electrons to diffuse across the magnetic field lines and actually reach the rod-shaped anode. Thus, the electron current supplied to the anode(s) may be very largely constituted of electrons which have successfully ionized an ion specie, plus the electrons detached from the ions, which have lost sufficient energy to diffuse effectively. The observed current may be greater than, but proportional to, the number of ions created.

Introduction of an Ionizable Gas

A prechosen gas may be introduced into the internal cavity volume through a plurality of small holes or controlled orifices in the solid walls of the arc chamber for ionization purposes. The current density of ions generated from this introduced gas depends upon the local chamber pressure; and in a very long and narrow arc chamber front wall with an open exit slit, such as a single slit architecture, single slot architecture, single exit aperture, and/or the like, it is very possible to vary the pressure within the chamber's cavity volume by changing the flow rate of gas passing through each controlled orifice.

Thus, the uniformity of the current density in the broad breadth ion beam which may be extracted from the arc chamber can be adjusted by adjusting the flow speed of gas through each hole passageway. However, the total flow rate of gas would need to bear a more-or-less constant relationship to the total ion current required.

Removal of Heat Generated within the Arc Discharge Chamber Structure

The power delivered to the arc discharge chamber 1 can reach or exceed 100V×3 A per 100 mm of length, which may be of the order of 1 kW per 300 mm of arc chamber length plus an additional 600 W. In ordinary operation therefore, the arc chamber may reach several hundred degrees C. degrees of heat, unless the chamber is actively cooled.

The practitioner can choose whether to let the arc chamber run hot, or actively cool the chamber with cold water passageways. But always in the disclosure, it may be beneficial that this heat be prevented from reaching the magnets—because permanent magnets lose their magnetization, and electrical coils lose their electrical insulation, if the temperature rises to a fraction of the arc chamber temperatures.

To this end, a cooling metal envelope may lie between the arc discharge chamber structure and any adjacently surrounding magnetic field generating yoke subassembly. There are several possible methods of accomplishing this end, and three concrete examples are included herein.

Extraction Electrodes

A conventional triode extraction system for ion beam extractions is shown by FIG. 4 (as well as other figures of the Drawing). For certain applications such as ion implantation where the energy and current range of operation requirements is very large, the use of a tetrode extraction system has certain advantages:

The length of the electrodes in the X1-axis direction may exceed the beam breadth dimension.

Thermal expansion makes it difficult to maintain a constant beam shape, but small deviations in electrode shape produce large changes in beam divergence, because of the sensitivity to precise dimensional control (discussed below). To maintain dimensional stability, the stack of electrodes can be mounted to the front of the ribbon beam ion source 108 on precision ground ceramic insulators.

The insulators are well shielded by metal cups to prevent fast coating of their surface with conductive films such as those sputtered by the beam from the electrodes through imperfect beam transmission.

Each extraction electrode may be made as two independent halves, each mounted to its own array of insulators. The electrodes may be aligned to the standoff insulators using pin-in-slot alignment, so that thermal expansion of the electrode parallel to the ion source slot is permitted, and does not cause significant electrode stress or buckling.

The Child Langmuir law states that for a flat ion emitting surface, the current density is related to other parameters as follows:)

J=(4∈₀/9)(2q/M)^{1/2}V₁^{3/2}g²

where J is the current density, ∈₀ is the permittivity of free space, q is the charge on each ion, M is its mass, V is the voltage across the first acceleration gap, and g is the gap between the ion emitting surface and the first extraction electrode.

This equation is difficult to apply to a plasma extraction system because the emitting surface may be neither flat nor located in one fixed position—the plasma boundary from which the ions are emitted shifts depending on the various parameters so that the emitting surface is the fitting parameter to ensure that the equation is locally accurate. The current density may also match the ion production rate in the plasma.

As a result, the divergence of the ion beam is a sensitive function of the parameters in the equation. If the current density available from the plasma increases, the plasma boundary may move forward and eventually bulge from the extraction aperture or slot. The ion trajectories are strongly influenced in their initial direction by this effect.

However, the lowest divergence ion beam may be formed by a slightly concave plasma surface, which may form when the current density is slightly lower current density than the equation requires for a plane surface. The practical current density at minimum divergence from a plasma ion source may be slightly less than the Child Langmuir law gives assuming a planar plasma boundary. Once one operating point is well-established, others can be calculated. The equation will have the form:

Iₘₐₓ=lw/g²V₁^{3/0}(4∈₀/9)(2q/M)^{1/2}

where w is the slot width, I is the slot length, and g is the electrode gap, which cannot be less than about 1.5 w in practice, and the numerical factor may always be modified by geometrical shape issues.

If the beam current is raised, the voltage across the first extraction gap may be raised, in order to satisfy the scaling of this equation. The electrode spacing may be selected so that the equation can be met across the range of operating conditions. If this range is wide, the use of a four-electrode system (tetrode system) in place of the triode system shown in the figures, may be advisable.

For very low beam energies, the extraction voltage (the voltage across the first gap), which is the sum of the voltages on two power supplies, may be 1 to 5 kV, but the beam is then decelerated in the second gap to a final energy as low as 50 eV. Under these conditions the precise gaps between the electrodes may be well controlled and tailored to the specific conditions, and optimization of the shape of the electrodes using computer codes such as OPERA/SCALA is advisable.

B. The Primary Electron Trap Assembly

The Magnetic Field Generating Yoke Subassembly

A discrete quadrupole magnetic field with a uniform cross section in the X1-axis direction may be provided and installed internally within the configured cavity volume along the length dimension and X1-axis of the plasma chamber via an adjacently disposed magnetic field generating yoke subassembly.

The open yoke subassembly uses a multipole array of at least three, and sometimes four or more, discrete magnetic pole constructs of alternating polarity. These pole constructs demonstrate an alternating polarity; and may be individually disposed in series over and along an open supporting yoke framework. The resulting yoke subassembly can generate a discernible quadrupole magnetic field on-demand—and may provide a field which is sometimes slightly distorted by the presence of a significant sextupole component, so as to be weaker in the Z1-axis direction of beam extraction.

It is noted particularly here that a suitable yoke subassembly fully operative to generate a discernible quadrupole magnetic field on-demand may be fabricated using only three discrete magnetic poles in series, which are disposed apart from each other upon a substantially U-shaped yoke frame. Moreover, a variety of other different yoked structural arrangements, arrays, and multipole displays which utilize three, or four, or even greater numbers of discrete magnetic pole constructs of alternating polarity in series may be employed at will.

Thus, the sole essential requirement for any of these alternative formats and designs is that the open yoke subassembly be functionally able to generate and install a discernible quadrupole magnetic field on-demand within the internal cavity volume of the arc discharge chamber 1.

It must be borne in mind also that the requirement for a clear and unobstructed path for the extracted ion beam mandates that no magnetic pole be disposed close to or lie forward of the front wall face of the arc chamber. Accordingly, any three-sided yoke subassembly which can generate significant quadrupole field components and weak sextupole field components may meet and satisfy the requirement.

The Different Classes of Moving Electrons

Ionization requires a collision between a gas atom and an energetic electron with a threshold energy. Cross-section values for ionization are a measure of the probability for ionization under certain given conditions. One source of such data is publications by NIST.

The cross sections for ionization for various gases tend to be greatest for electron energies around 60 to 100 eV—i.e., 4 or 5 times the threshold for ionization. For this reason, primary electrons are effective to ionize the gas, but secondary electrons are not. The background plasma typically has an electron temperature of 1 to 2 eV, and such electrons cannot act to and do not ionize the gas molecules in-situ.

The Trapping of Primary Electrons

It is important to understand fully the mode and manner of primary electron trapping which occurs within the internal cavity volume of the arc chamber. The electric potential within the cavity space may be generally slightly positive in value, because of the presence of the anode rod(s); and because once a plasma state may be established in-situ—the chamber volume is filled full of plasma to within <1 mm distance of the inner wall faces; and as is well known, the plasma tends to reach an equilibrium potential somewhat positive with respect to the anode.

The quadrupole magnetic field may be imposed on this electrostatic field arrangement: The quadrupole fields may lie parallel to the Y1-Z1 lane but extend uniformly along the X1-axis direction over the full length dimension of the cavity volume; and the magnetic field has a null value along an approximate center or midline of the cavity configuration which runs the entire measurable length of the chamber (in the position shown by the number zero or “0” in FIG. 11), and is referred to herein as the null field axis.

The highly non-uniform quadrupole field which extends over the length dimension of the cavity volume—as is well-known—has the effect of focusing a moving charged particle toward the null line in two opposite quadrants of the magnetic field, and concurrently also of defocusing a moving charged particle in the opposite two quadrants.

Toward the outer edges of the plasma, there is a weak electric field generally directed away from the center of the plasma, and this tends to accelerate electrons inwardly. In certain locations, this electric field is orthogonal (or nearly so) to the magnetic field lines; and, as a result, the electron cycloidal motion may be impelled toward one end of the arc chamber at a measurable drift velocity which is mathematically calculated as V=E/B.

In alternating quadrants of the magnetic field, the drift velocity direction reverses. This reversing drift velocity tends to enhance the mixing and uniformity of the distribution of primary electrons. Unlike the ALPA source where the electrons can drift indefinitely in a close orbit—at the arc chamber walls, the drifting electrons are reflected somewhat randomly from the inner wall faces. By modeling, one knows that their motion may be somewhat chaotic and that drifting electrons transition with a high probability to another region of the trapped distribution, where they can drift in the opposite direction.

A moving primary electron introduced on this null line once a plasma is established encounters essentially zero electric or magnetic fields, so is free to travel the full length of the arc chamber undeflected; but upon approaching the inner face of a contiguous end wall, it may be electrostatically reflected, re-directed, and returned toward the center of the internal cavity volume. Accordingly, the cathode is always placed so as to encompass the null field axis. However, a moving electron which may be displaced from this central null line of the cavity volume may encounter and become deflected by the quadrupole magnetic field.

Consequently, all primary electrons emitted from the cathode and encountering the quadrupole magnetic field within the confined cavity column of the arc chamber may exhibit the following characteristics:

The primary electrons are accelerated toward the anode rod(s) and/or toward the center of the of the plasma formed by electron-impact ionization within the arc chamber;

The primary electrons have insufficient kinetic energy to reach any part of the arc chamber walls except the anode rod(s);

The primary electrons are deflected by the quadrupole magnetic field. Depending on their location within the field, they may be deflected towards or away from the null field axis. Those deflected away from the null field axis are increasingly rapidly deflected with a gyro-radius many times smaller than the distance of the anode rod(s) from the zero-strength field line, and are directed into cycloidal and oscillatory paths which cannot intersect the anode rod(s);

The primary electrons are imparted with a positive or negative X1-axis directed motion [referred to as a drift velocity of magnitude E/B] in regions of crossed electric and magnetic field;

The primary electrons are prevented from reaching the solid chamber walls because the electrostatic potential of the walls may be a negative value with respect to the potential of the cathode; and

The primary electrons become trapped in a central cross-shaped zone and are uniformly distributed along the length dimension of the cavity space by the combination of electrostatic and magnetic confinement and the axially directed E×B drift.

Accordingly, in this instance, the field strength may be sufficient in magnitude that the defocused electrons are deflected to move in a cycloidal path, and cannot escape the central spatial zone. The fields have insufficient strength to have a significant effect upon the heavier ions, which thus are free to strike the walls or exit the arc chamber through the aperture. Also, the quadrants are separated by surfaces coplanar with the field lines and passing through the null line.

Furthermore, as illustrated by FIG. 12, the circumstance and effect of primary electron trapping presents a visibly asymmetric shape. This asymmetric shape applies to moving electrons then traveling into the plane of the diagram; and moving electrons then traveling out of that plane which become trapped in a cavity spatial zone with mirror-image asymmetry.

Since electrons are reflected from the inner faces of both contiguous end walls of the chamber repeatedly, many multiple times, the overall configuration of the trapping volume may be symmetric; and comprises the asymmetric shaped spatial zone (illustrated by FIG. 12) superimposed upon its own reflection in the central X-Z plane of symmetry.

A further consideration is that these electron travel pathways are highly convoluted and often looped; and that the electrons may travel a distance of about 3 cm for each 1 cm of net progress within the arc chamber over the X1-axis direction. This travel distance increases the probability of an ionizing collision in each passage over the length dimension of the arc chamber.

No Requirement for Magnetic Cusp Field Plasma Confinement

It is recognized here also that magnetic cusp field plasma confinement has been used in the technical field for many years; but in the present instance, one can reduce the need for high magnetic fields and simultaneously improve the trapping efficiency by choosing not to rely upon the magnetic cusps of the multipole field for electron reflection. The ribbon beam ion source 108 is therefore fundamentally different from conventionally known constructions [such as those exemplified by K. N. Leung, Multicusp Ion Sources, Proc. 5th. Int. Conf. Ion Sources, Beijing, 1983, Rev. Sci. Inst., 65:1165 (1984)].

Accordingly, instead of relying on cusp confinement, the disclosure is so arranged that each of the weak magnetic cusps of the magnetic field also coincides with a solid metal wall at the most negative potential within the cavity volume of the arc chamber. In this way, the primary electrons emitted by and flowing from the cathode are electrostatically trapped, and the magnitude of the quadrupole magnetic field requirement becomes markedly reduced.

The Installed Quadrupole Magnetic Field

The installed quadrupole magnetic field of the primary electron trap assembly, even if somewhat distorted, may extend uniformly within the chamber's internal cavity volume in the X1-axis direction over the full linear length dimension of the arc chamber. The true extent of the discernible quadrupole magnetic field may thus vary directly with the linear length dimension of the arc chamber; and, as the prechosen length dimension of the arc chamber may be arbitrarily increased from about 80 mm to more than 3,000 mm, the linear length of the ensconced quadrupole magnetic field within the internal cavity volume of the arc chamber may corresponding increase in size. Because of the field orientation, this circumstance requires no increase in ampere turns for the wire winding coils; or if permanent magnets are used, no increase in the size of the permanent magnets used, but merely an increased number of permanent magnets in a linear array.

The discernible quadrupole magnetic field which is installed and extends within the limited confines of the cavity volume in the arc chamber effectively functions as a volumetric shield of magnetic flux lines which overlies and encompasses the anode potential (tangibly appearing as long length anode rods). It is not very effective at trapping electrons at the magnetic cusp zones; but in these zones, one elects to provide a negative electrostatic potential.

Via this arrangement and in this manner, the installed volumetric shield of magnetic field lines acts in combination with the selected electrostatic wall potential and together effectively function as a primary electron trap, confining the primary electrons to a defined volume within the limited confines of the cavity volume of the arc chamber.

The discernible quadrupole magnetic field generated by the primary electron trap assembly and installed within the internal cavity volume of the arc discharge chamber 1 may demonstrate and provide the following traits and properties:

(i) The installed quadrupole magnetic field may extend uniformly along the X1-axis direction (i.e., over the length dimension of the arc chamber);

(ii) The ensconced quadrupole magnetic field has Y1-axis and Z1-axis directed field components, but presents no significant X1-axis component;

(iii) In a Y1-Z1 cross section view, the instituted quadrupole magnetic field has a zero strength and a central null axis parallel to the X1-axis which extends over the full-length dimension of the arc discharge chamber 1 and beyond, and is referred to as the null field axis;

(iv) The field strength of the invested quadrupole magnetic field increases continuously with increasing distance from the central null axis to the laterally positioned adjoining sidewalls walls of the arc discharge chamber 1;

(v) The established quadrupole magnetic field may cause an individual high strength magnetic field to pass over and along at least two peripheral spatial regions existing at the interior corners and marginal edges of the cavity volume in the arc discharge chamber 1;

(vi) The lodged quadrupole magnetic field is coplanar with and extends over any plane which is normal (i.e., lying perpendicular or at 90 degrees) to the arbitrarily chosen length dimension and X1-axis of the arc discharge chamber 1; and

(vii) The emplaced quadrupole magnetic field may not create or cause any magnetic field or field component to lie along or be parallel to the arbitrarily chosen length dimension and the X1-axis of the arc discharge chamber 1 box

C. The Extracted Ion Beam

The user is provided with a broad breadth ion beam which then can be employed in a number of different applications. In each instance, a streaming ribbon-shaped ion beam is produced which has a measurable breadth dimension which may be at least ten times greater than its width dimension, and preferably may be thirty or more times greater than its width dimension—the breadth and width dimensions of the extracted broad breadth beam being normal to the Z1-axis direction of travel for the beam.

In addition to its broad breadth range, the extracted ion beam may present a number of traits and properties which can be chosen in advanced as desired or need. Accordingly, the general characteristics of the stream of ions which can be extracted as a beam from the ribbon beam ion source 108 may include all of those factors and variables listed by Table 1 below.

TABLE 1
Ion Beam Property Variables

| | |
|---|---|
| Ion beam breadth | From about 80 mm to more than 3,000 mm. |
| range: | |
| Ion divergence: | At energies above about 3 keV: +/−2°; |
| | At lower energies, this value is greater. |
| Ion energy range: | From about 20.0 eV to about 100,000 eV using |
| | triode or tetrode beam extraction; |
| | Thermal plasma at 1 to 20 eV with no extraction |
| | voltage |
| Ion current range: | From about 0.001 to about 1 amperes of positive ions |
| | per meter of ion source length. |
| Ion current power | With suitable beam acceleration, beam powers |
| range: | of >100 kW; Applications may require up to 10 kw. |
| Ion energy | For monatomic species: ~2 eV FWHM; |
| distribution range: | For dissociated molecular species: <10 eV FWHM, |
| | depending on the molecular chemistry of the |
| | species. |

Within these general ranges, a highly particular set of values for ion implantation purposes is presented by Table 2 below.

TABLE 2
Preferred Beam Properties For Commercial
Ion Implantation Purposes

| | |
|---|---|
| Ion beam breadth range: | From about 150 mm to about 2,500 mm |
| Ion divergence range: | +/−2° |
| Ion energy range: | From about 5 keV to about 80 keV |
| Ion current range: | From about 0.001 A to about 0.1 A per meter |
| | of positive ions |
| Ion current power range: | From 50 W to about 22 kW |
| Ion resolving power | 20 is acceptable; 40 is good. |
| M/ΔM FWHM: | |

IV. A First Functional Embodiment of the Disclosure

In a first embodiment, the ribbon beam ion source 108 can produce a ribbon shaped ion beam having a breadth dimension of 200 to 2500 mm, and thickness on leaving the extraction electrodes of about 5 mm, diverging at +/−2 degrees, the beam's breadth and thickness dimensions being measured normal to the Z1-axis pathway and travel direction of the ion beam. However, other implementations may include different dimensions and/or other physical characteristics.

However, owing to its typical operative format within vacuum and ambient gas environments concurrently, the minimal components of the ribbon beam ion source 108 may also include an environment-separating, intervening partition barrier in combination with the arc discharge chamber 1 and the magnetic field generating yoke subassembly of the primary electron trap assembly.

Thus, in this first embodiment of the ribbon beam ion source 108, an environment-separating partition barrier may be used to divide, segregate and isolate the arc discharge chamber 1, then held within a high vacuum environment; and to physically separate the adjacently located and surrounding magnetic field generating yoke subassembly, then typically held in the ambient gas environment.

A. The Structural Entities

In this first embodiment shown by FIG. 4, FIG. 5, and FIG. 6 respectively, there are two essential structural entities which are carefully aligned and joined together. These are: (a) An arc discharge chamber 1; and (b) a primary electrode trap assembly including an intervening partition barrier and a magnetic field generating yoke subassembly.

The Arc Discharge Chamber Structure

The elongated arc discharge chamber 1, as illustrated in FIG. 5A, is a self-standing and independent article of manufacture. Externally, the arc discharge chamber 1 may have the shape of a rectangular prism, inside which a long uniform cavity volume may be provided. The cavity volume configuration may have rounded contours, but has a uniform extruded shape.

As seen in FIG. 4 and FIG. 6, an arc discharge chamber 1 of substantially rectangular prism configuration and having an enclosed interior portion of the cavity volume 10 of elongated shape is presented. The arc discharge chamber 1 may be a closed box structure bounded by six discrete solid walls: A front wall 3, a back wall 8, two discrete laterally positioned and oppositely situated adjoining sidewalls 6a and 6b; and two discrete oppositely situated contiguous and abutting end walls 12a and 12b (but not shown in the cross-sectional views of FIG. 4 and FIG. 6).

A single open slot or exit aperture 5 (which can alternately appear as an array of open slots or channels) appears in the front wall 3 and may be aligned with a pair of extraction electrodes 4a and 40a and 4b and 40b, which are individually placed apart a short distance from the exterior face of the front wall 3. The front wall may optionally comprise and be constructed of two separate halves.

In addition, the back wall 8 of the arc discharge chamber 1 may incorporate drilled passages 9 as shown in FIG. 4. Such passages serve as controlled orifices or portals which permit the at-will introduction of an ionizable gas or vapor to the cavity volume interior. The controlled orifices 9 provide a uniform distribution of the introduced gas or vapor within the cavity volume of the arc discharge chamber 1.

In this first embodiment, the arc discharge chamber 1 may be made to fit snugly in a recess machined in the base flange or plate which may be part of the vacuum wall. The box geometry of the arc discharge chamber 1 can be built of plates of refractory material (e.g. graphite, molybdenum, etc.), which interlock as shown in FIG. 5A and FIG. 6, and can be retained in place by spring clips. The contiguous and abutting end walls of the arc discharge chamber 1 are closed plates which have holes to allow the anode rod(s) to pass there-through to external securing clamps.

The arc discharge chamber 1, which may receive substantial power in operational use, may be shaped externally to minimize surface contact, and may reach many hundred degreed C in operation. The vacuum wall may be cool, and may include means to remove the heat, which are described below.

The arc discharge chamber 1 cavity may typically measure 32 mm front wall-to-back wall; 32 mm sidewall-to-sidewall; and be any length in the range from about 80 mm to 2,000 mm or more in the X1-axis direction—a sized dimension which corresponds directly to the breadth dimension of the extracted ion beam.

Within the limited cavity volume 10 of the arc discharge chamber 1 are two separate implementations of the rod-shaped anodes 2a and 2b. Each rod-shaped anode 2a and 2b individually lies disposed adjacent to one laterally positioned adjoining implementation of the sidewall 6a or sidewall 6b of the arc discharge chamber 1; linearly extends along the X1-axis over the full length dimension of the arc discharge chamber 1; and may be tangibly located within the peripheral spatial regions marginal spatial edges of the cavity volume 10 existing between the one of the adjoining sidewalls 6a and sidewalls 6b and the back wall 8.

Also disposed within the limited cavity volume 10 of the arc discharge chamber 1 is a single implementation of the cathode filament 7. This thermionic implementation of the cathode filament 7 may be disposed upon the inner face surface of the end wall 12a. The cathode may in this first embodiment instance be made from 0.090″ diameter tungsten rod wound into a small loop; and can be installed through the end wall of the arc chamber.

The Primary Electron Trap Assembly

The second major requisite component of the disclosure is the primary electron trap assembly. In this first embodiment, the trap assembly comprises two discrete structural entities: An intervening partition barrier 60; and a magnetic field generating yoke subassembly.

The Intervening Partition Barrier Structure

Because the arc discharge chamber 1 may be operationally contained within a closed vacuum environment (maintained at a negative pressure ranging from about 1 Pa to about 10⁴ Pa) while the magnetic field generating yoke subassembly may be routinely held and used in an ambient gas environment—an intervening partition barrier 60 may be preferably used as a structural component to orient and align the two structural entities.

However, in its broadest applications, the intervening partition barrier 60 can serve up to three different functions and purposes. These are:
(i) As a structural divider which effectively separates a vacuum environment from an ambient gas environment;
(ii) As a structural means for orienting and aligning the magnetic field generating yoke subassembly at a prechosen fixed distance and in an encompassing adjacent disposition around the arc discharge chamber 1;
(iii) As a structural entity incorporating passages for flowing cooling fluid such as water, capable of absorbing heat emanating from the operation of the arc discharge chamber 1, and preventing said heat from reaching the magnetic yoke and other sensitive components.

A particular form of environmental-separation barrier plate or partition barrier 60 is illustrated in cross-sectional view by FIG. 4 and FIG. 6 respectively; and its relationships to both the arc discharge chamber 1 and the adjacently located shaped yoke subassembly 100 are best shown by these illustrations.

As seen therein, the preformed barrier plate or partition barrier 60 serves as a structural divider and functions as a tangible environmental-separating partition, wherein the preformed barrier plate

(a) may be composed of solid matter which may be materially adequate to maintain its obverse face surface 62 in a vacuum environment while concurrently maintaining its reverse face surface 66 in an ambient gas environment;

(b) presents an obverse face surface 62 having a single implementation of the spatial recess 64, which may be contoured to receive and hold the exterior surfaces of the two laterally positioned and oppositely situated adjoining sidewalls 6a and sidewalls 6b and the back wall 8 of the arc discharge chamber 1 then in a vacuum environment; and

(c) concurrently presents a reverse face surface 66 having and spatial recesses of the housing 68a and 68b, which are collectively contoured to receive and hold the magnetic field generating yoke subassembly in a properly aligned position and orientation within the vacuum environment.

The intervening partition barrier 60 may be typically fabricated as a thick plate or bulwark made of aluminum or another high-thermal conductivity metal; into which two aligned spatial recesses and spatial recesses of the housing 68a and 68b(seen best in FIG. 6) which appear on the gas atmosphere side, and one aligned implementation of the spatial recess 64 which appears on the vacuum side, are individually machined.

Via this structure, the partition barrier serves to orient, align and hold the shaped yoke subassembly; acts physically to separate the discrete yoke subassembly then found in the gas environment at a fixed prechosen distance from the arc chamber then maintained in a vacuum environment; and concurrently also functions as a heat shield which effectively deflects the large quantities of heat emanating from the interior of the arc discharge chamber 1.

In addition to all of the foregoing, in this first embodiment of the disclosure, the intervening partition barrier also provides the structural means for absorbing and removing heat radiated by the adjacently positioned arc discharge chamber 1, in order to prevent the heat from damaging components including seals and the magnetic electron trap yoke. The particular purpose here is heat absorption and not to cool the arc chamber. Thus, the area of contact between the arc discharge chamber 1 and the partition barrier 60 may be minimized by provision of limited areas of contact.

Notably for achieving this particular goal and purpose, multiple discrete water conduits and passageways 61 are provided within the material substance of the partition barrier 60. Details of the water conduits, cooling passages and fluid inter-connections are not shown in FIG. 4 and FIG. 6, but are conventionally known as such and commonly used by practitioners in this field.

It will therefore be well recognized and appreciated that the placement of the intervening partition barrier 60 in this first embodiment serves three different functions and critical purposes, which are:
(i) The partition barrier 60 serves to orient, align, and properly adjacently position the prism shaped implementation of the arc discharge chamber 1 at a fixed prechosen distance from the adjacently disposed magnetic field generating yoke subassembly;
(ii) The partition barrier 60 serves to hold and maintain the prism shaped implementation of the arc discharge chamber 1 in a vacuum environment while concurrently separating and keeping the magnetic field generating yoke subassembly in an ambient gas environment; and
(iii) The partition barrier 60 functions as a tangible heat shield which guards and protects the magnetic field generating yoke subassembly (then disposed over its reverse face surface and multiple recesses) from the debilitating effects of exposure to extreme heat.

The Magnetic Field Generating Yoke Subassembly Structure

The magnetic field generating implementation of the yoke subassembly 100 of the primary electron trap assembly is shown best in FIG. 5B. The yoke subassembly 100 may be typically located in a gas atmosphere, external to the vacuum environment; and may be housed within the spatial recesses of the housing 68a and 68b on the reverse face of the partition barrier 60. This orientation and alignment allows the framework of the yoke subassembly adjacently and at a preset distance to partially surround the exterior faces and external perimeter of the arc discharge chamber 1, then contained in a vacuum environment.

As seen in FIG. 4, FIG. 5b, and FIG. 6 respectively, the yoke subassembly 100 adjacently surrounds three discrete exterior faces and discrete solid walls of the closed arc chamber at a preset fixed distance; and concurrently extends along and runs over the full-length dimension of the arc chamber. The two discrete implementations of the poles 115a and 115b may rest adjacent to the laterally positioned adjoining sidewalls 6a and 6b of the arc chamber are in fact inserted into in the recessed housings 68a and 68b on the reverse side of the partition barrier 60 that may be implemented as a barrier plate, which in this instance, may be part of the vacuum enclosure wall. Similarly, the third elongated implementation of the pole 116 may be inserted into spatial recess 69 on the reverse face of the partition barrier 60 that may be implemented as a barrier plate.

In general, the format and construction of the magnetic field generating yoke subassembly can comprise either wound wire coils or employ permanent magnets as the magnetic pole constructs. However, in this first functional embodiment illustrated by FIG. 5B, the yoke subassembly 100 comprises a substantially U-shaped supporting framework of the yoke framework 110 formed of ferromagnetic material—upon which are disposed in sequential series three elongated ferromagnetic poles implementing the pole 102, 115a and 115b of alternating polarity.

The structure of the single preformed ferromagnetic implementations of the pole 116 is shown in FIG. 5B. It is in essence an elongated solid shaft, dowel, or bar formed of a ferromagnetic material or metal alloy; may be a preformed elongated article which does not include or present any wire winding or coil as such; and may be sized to be at least co-extensive in measurable distance with the linear length dimension of the arc discharge chamber 1.

Note that only a single ferromagnetic implementation of a pole 116 appears in the U-shaped yoked subassembly 100; and in this instance, the pole 116 may always lie disposed upon the middle segment 111 of the framework of yoke subassembly 100. Consequently, when the U-shaped yoked subassembly 100 may be fitted to the reverse face surface of the environmental-separating barrier plate or partition barrier 60, the pole 116 may come to lie within the spatial recess 64 and be positioned adjacent to the exterior face of the back wall 8 in the arc discharge chamber 1.

In comparison, each of the two preformed ferromagnetic implementations of the poles 115a and 115b are made of ferromagnetic material; and a single continuous wire winding or discrete implementation of the obround coil 105a, and 105b may be transversely wound as a spiral loop around the axial length of pole 115a and b respectively, to enable magnetization of the poles and thereby the yoke subassembly 100.

Each obround coil 105a, 105b may be typically made from a continuous wire length of electrically conductive material; may be a transversely disposed wire winding formed as a substantially racetrack-shaped whorl; and appears as a closed spiral loop or obround coil which comprises two parallel straight length sections, as well as two curved ends each bending through 180 degrees. Together, the supporting shelf and the transversely placed wire winding coil form the operative ferromagnetic pole construct as a whole.

Also, each obround coil 105a, 105b may each be wound using enameled copper wire and may typically provide about 300 to 800 Ampere turns when excited. Each coil may be energized by a constant-current programmable power supply. Thus, if each obround coil contains about 50 turns, it may be operated at between 0 and 20 amperes.

Each discrete pole construct 115a and 115b may be individually mounted upon one upright arm section 103 of the U-shaped yoke framework implementation of the of the yoke framework 110; and together may appear as an oppositely-oriented pair of spaced-apart ferromagnetic poles disposed upon the structural arms of the three-sided yoke framework implementation of the of the yoke framework 110. The two discrete ferromagnetic pole constructs of the pole 115a and 115b are thus employed in combination as a tandem pairing; and each ferromagnetic pole construct 115 of the pair may come to be oriented towards and lie in parallel with the length dimension and X1-axis of the arc discharge chamber 1 when the yoke framework 110 may be adjacently fitted around the exterior faces and walls of the arc discharge chamber 1.

Operationally, the two obround coils 105a and 105b mounted upon the poles 115a and 115b may generate individual ‘North’ polarities on either side of the yoke framework 110; while the single magnetic pole implementation of the pole 102 mounted upon the base of the yoke framework 110 may generate a ‘South’ polarity at the rear; or vice versa. The specific field direction does not matter provided the two poles 115a and 115b present the same polarity.

B. Operating Features of the First Embodiment

Producing a Plasma

A high vacuum environment may be established for the arc discharge chamber 1 by means of pumps. The cathode filament 7 may be heated until it emits electrons by passing up to 200 amps through it from a 7.5V 200 A power supply. The negative side of the cathode filament may be connected to the negative side of the arc power supply, and may be also connected to the solid walls of the arc chamber; and a voltage of 40 to 120V may be applied between the anodes and the cathode filament.

The quadrupole magnetic field may be generated by the yoke subassembly and may be operationally installed within the cavity volume of the arc chamber by passing about 12 A through the two ferromagnetic configurations of the obround coils 105a and 105b mounted upon the side poles of the U-shaped yoke subassembly.

Gas may be then introduced into the cavity volume of the arc discharge chamber 1 to raise the internal cavity pressure to about 1 Pa, wherein the primary electrons emitted by the cathode filament ionize the gas and create a plasma in-situ.

The Extraction Electrodes

Potentials

The entire implementation of the ribbon beam ion source 108 (i.e., the arc discharge chamber 1 and the primary electron trap assembly) may be electrically biased at a positive value with respect to ground by a potential [usually in the range of 1 to 100 kV] which defines the beam energy.

Thus, in this first embodiment, the extraction electrodes 4a and 4bare connected to ground. The extraction electrodes 4a and 4b, which control the initial electric field by means of the potential applied to them and their spacing from the ribbon beam ion source 108, are biased negative with respect to ground by an accel/decel voltage of −1 to −5 kV. As shown in FIG. 4, the spacing may be optimum for about 5 keV final beam energy. The positive ions flowing from the plasma are extracted and pass through the exit aperture 5 and the gaps between the electrodes, and these form a streaming ion beam with a divergence of about +/−2 degrees.

Adjustments (Mass, Energy, Current)

The Child-Langmuir law is used to estimate the electrode spacing required to generate a given current. The electrode gap g may always be significantly larger than the electrode aperture width, or else geometric effects mean that the electric field at the center of the aperture may be drastically weaker than the equation implicitly assumes. One strong reason for using a narrow slot extraction rather than a round hole may be that the electrode gap may be made small while the long slot allows for a large emitting area.

With the electrode spacing set at a suitable gap for the desired current density, a plasma is established; and when the desired extraction voltage applied, a beam is extracted. The beam's divergence may be estimated by several methods—for example the ion current transmitted through a slot narrower than the beam may be maximized at or near the conditions giving the minimum beam divergence. The Decel voltage can be adjusted to maximize this current, within limits.

If a wide range of operating conditions is expected, the triode extraction arrangement can be replaced with a tetrode (4-electrode) arrangement. The voltage across the first gap may now be adjusted freely to minimize the beam divergence; but the total voltage still defines the energy. The accel/decel voltage applied to the third electrode can also be adjusted in conjunction with the accel voltage to give the best transmission of the beam through the exit aperture.

The Installed Quadrupole Magnetic Field

It is important to understand properly the mode and manner of how the quadrupole magnetic field installed within the cavity volume of the arc chamber appears and functions for this first embodiment of the disclosure. For this purpose, FIG. 10, FIG. 11 and FIG. 12 respectively are provided.

As seen therein, FIG. 10 is a cross-sectional view of the first embodiment which shows the lines of magnetic flux B constituting the installed quadrupole magnetic field as the flux fines are generated and then flow into and through the internal cavity volume of the arc discharge chamber 1. The field lines can be seen to pass from N to S pole; while toward the exit slit, the field lines curve in the opposite. The field null occurs in the zone where no field lines pass. The cathode filament 7 may be mounted so as to encompass or intersect the null field line.

FIG. 11 is a cross-sectional view of the first embodiment which shows the magnetic contour lines with the field strength values measured in Gauss The field null point is labeled “0”; and if the cathode were shown in FIG. 11, it would be seen to encircle or intersect the axis through this point. The field may be seen to rise fairly uniformly in three directions; while in the direction of the exit aperture, the field only rises to between 20 and 40 Gauss before leveling off.

FIG. 12 is a cross-sectional view of the first embodiment which shows the spatial zone of primary electron confinement created by the trap assembly within the internal cavity volume of the arc discharge chamber 1. By comparing the shape of this spatial zone with the field lines of FIG. 10, it can be seen that the electron confinement may be caused by the inability of the primary electrons significantly to cross the field lines. It can also be seen in FIG. 12 that four limited areas that this zone appears to reach to the walls. The electrostatic potential blocks the electrons from reaching the walls at these points—but only in the final fraction of a mm, which is not discernible within the figure.

V. A Second particular Embodiment

In this second particular embodiment, a number of dominant changes exist and pertain which markedly separate and distinguish this second embodiment from the first embodiment described above.

First, all of the requisite components and operative parts of the disclosure—i.e., both the prism shaped arc discharge chamber as well as most of the primary electron trap assembly—are situated in a negative pressure domain and lie completely contained within a high vacuum habitat. This circumstance is markedly different from the first embodiment described above in that the vacuum wall comprises a part of the magnet yoke, and all the active faces of the magnet yoke of the primary electron trap are in vacuum.

Second, the magnetic field generating yoke subassembly of the primary electron trap assembly may be constructed using two permanent magnet pole constructs disposed upon the upright arm sections of the framework. However, once again there are three poles (215a, 215b, and 216 respectively in FIG. 7a) presented toward the arc chamber of alternating polarity which lie spaced-apart in sequential series upon an open, substantially square-shaped, supporting framework.

Third, the water-cooled partition barrier which exists between the arc chamber and the magnet yoke may be a simple, smaller, U-shaped trough configuration of the housing 223, incorporating water channels 224 as illustrated in FIG. 7a. The arc chamber 227 comprises two identical halves made of refractory material which are retained within the trough.

Fourth, FIG. 8b illustrates a variant in which the arc chamber 250a and 250b itself may be cooled, and can be made in two halves which are then held together.

Fifth, the magnetic sidewalls 221 of the open yoke subassembly also function as structural components clamping the cooled trough configuration of the housing 223 or cooled arc chamber 250a and 250b in place; and further provide the anchorage point for insulators 290 which may hold the split extraction electrodes 4a and 4b in place, as shown in FIG. 8A and FIG. 8B.

Accordingly, although the disclosure fundamentally remains comprised of the same requisite structural components—the arc discharge chamber and the primary electron trap assembly—there are a number of meaningful alternations and distinct modifications in this second particular embodiment when compared to the first embodiment described above.

Noted Differences in the Primary Electron Trap Assembly then Located Entirely within the Vacuum Habitat

1. Differences in the Intervening Partition Barrier

In the second embodiment shown by FIG. 7a, the intervening partition barrier appears as a one-piece implementation of a housing 223 made of aluminum (or another non-magnetic metal or alloy). The partition barrier of the housing 223 contains multiple closed passageways and conduits 224 for cold water to pass there-through; may be shaped over its obverse face surface for positioning adjacent to and around the discrete adjoining sidewalls and back wall of the arc discharge chamber 1; and may be contoured on its reverse face surface for precise orientation, alignment and fitting with an open, substantially square-shaped, yoke subassembly 200 comprising three poles 215a, 215b and 216 and two linear arrays of permanent magnets 222 disposed on three internal faces over its open framework.

In this second particular embodiment, the intervening barrier plate housing serves two different functions: (a) It adjacently encompasses and surrounds three discrete solid walls of the arc discharge chamber; and (b) It acts as a heat barrier and thermal shield which guards and protects the permanent magnet field generating yoke subassembly from the extreme heat released by the arc chamber.

2. Differences in the Open Yoke Subassembly

The structure of the yoke subassembly 200 is markedly different in this second particular embodiment, as shown bit FIG. 7a and FIG. 7b. Three elongated poles are again provided, extending the length of the arc chamber in the x-direction, mounted on internal faces. Two linear arrays of permanent magnets 225a, 225b, lie arranged in sequential series and are individually disposed upon the two upright arm sections 210a, 210b of the substantially square-shaped, open framework implementation of the yoke subassembly 200.

Most notably in this second embodiment, the shaped yoke subassembly 200 presents a ferromagnetic base plate 211 which simultaneously combines the roles of a durable vacuum wall and the bottom portion of the square-shaped open yoke frame. A suitable material for this ferromagnetic base plate 211 may be Type 430 stainless steel—which may be magnetic, resistant to corrosion, and suitable for use in vacuum environments.

The two upright arm sections 210a, 210b of the yoke framework of the yoke subassembly 200 may also be made of type 430 stainless steel, or more economically is fabricated from plated mild steel. These upright arm sections are structurally joined with screws at a 90-degree angle to the planar base plate the ferromagnetic base plate 211; and together collectively form the open square-shaped yoke frame. These upright arm sections further serve as retaining clamps to hold the cooled barrier trough in place.

Upon each upright arm section 210a, 210b—in place of the wire winding obround coils shown in the first embodiment—is a discrete permanent magnet construct comprising a ferromagnetic pole 225 and a plurality of permanent magnets 222 in a linear array; which are oppositely situated upon each arm sector and act in tandem as aligned ferromagnetic poles. A third ferromagnetic pole 216 may be typically attached to the ferromagnetic base plate 220, or else may be incorporated into the base by machining. Although it could have additional permanent magnets incorporated in its structure, it can be sufficiently energized without additional magnets if the permanent magnets 222a, 222b have been appropriately sized

This set of three magnetized poles (which have alternating polarity) are spaced-apart from each other on three internal faces of the open yoke framework and together constitute the open implementation of the yoke subassembly 200; and the resulting yoke subassembly can generate and install on-demand a discernible quadrupole magnetic field within the limited confines of the internal cavity volume in the arc chamber. The installed quadrupole magnetic field may have the same distorted quadrupole field shape as described above for the first embodiment; but its magnetic strength cannot be adjusted in real time. Nevertheless, the generated magnetic strength can be adjusted in-situ by adding or subtracting permanent magnets 222a and 222b (in equal numbers) from the linear arrays.

Structural Modifications for the Second Embodiment of the Arc Discharge Chamber

A Hot Arc Chamber

As illustrated in FIG. 7b for this second particular embodiment, the arc chamber 227 (formed of refractory material such as graphite) may be fabricated by the juncture of two symmetrical halves; and may be carefully dimensioned to fit with the obverse face of the of the barrier trough housing in a central well of the heat shield. The arc chamber may be secured and retained by two screwed-in retainers 226 which hold each arc chamber half of the arc chamber 227 in place against a stable face surface of the heat shield structurally represented and provided by the barrier plate housing. The exit aperture 5 in the front wall of the arc chamber may be thus bounded by two separate pieces of refractory conductive material; and this method of arc chamber construction ensures stability of the exit aperture over the greatly increased length dimension of the arc chamber without relying on a far-weaker structure which links the two halves only at their ends.

A Cold Arc Chamber Option

FIG. 8b shows an alternative format for a cold arc chamber. This alternative format replaces the heat shield/barrier plate housing for the refractory arc chamber above with a simpler two-piece water-cooled arc chamber having the same (or a substantially similar) configuration both externally and internally; but presents the plasma produced in-situ with cool chamber walls, even when operating at several kW of power.

In this alternative format, the exit aperture 5 of the prismatic-shaped arc chamber may be again formed by the juncture of the two separate halves of the arc chamber 250a and 250b, as described above. Separate discrete implementations of the end walls 12a and 12b are attached to close the ends of the arc chamber; and as before, these two chamber half-sections each contain holes for the anodes and possibly for the cathode to be externally secured.

Structural Simplifications and Effective Cooling

A partially exploded view of these modifications is illustrated by FIG. 7B (hot arc chamber) and in FIG. 8B (cold arc chamber). As seen therein, water cooling conduits and passageways acts upon the magnetic base plate of the open yoke subassembly and markedly adds to the heat shield effect provided by the partition barrier housing. The magnetic base portion of the ferromagnetic base plate 211 and the heat shield/barrier plate of the housing 223 (or cooled arc chamber 250) have a large area of direct contact—and in this shared area, o-ring seals are placed; and recesses in both parts allow the passage of water into intimate contact with both parts in this area (as seen in FIG. 8b).

Thus, by these means utilizing a minimum number of components, the practitioner can provide a strong and durable vacuum wall; a cooled barrier housing for the arc chamber; a structural mounting for all the other desirable features via feed-throughs for electrical connections, water cooling fittings, and gas fittings; an aligned foundation for yoke subassembly able to generate a quadrupole magnetic field within the cavity volume of the arc chamber; and a firm structural support for properly mounting the extraction electrodes to lie over the exit aperture of the arc chamber (as shown in more detail by FIG. 8A and FIG. 8B).

VI. A Third Alternative Embodiment

In this third alternative embodiment, several unique structural differences appear which substantively distinguish this format from both of the first and second embodiments described above. Thus, although the disclosure essentially remains comprised of the same two structural components—the arc discharge chamber and the primary electron trap assembly—there are nevertheless several meaningful changes and distinct structural modifications in this third alternative embodiment.

In particular, the third alternative embodiment presents the following changes:

The entirety of the ribbon beam ion source 108—including both the arc discharge chamber and the primary electron trap assembly—are located solely within a vacuum environment,

The intervening partition barrier contains recesses for the location of two separate, disconnected, magnetic yokes. Thus, the magnetic field generating yoke subassemblies are located close to the arc chamber, but separated from it by a wall of high conductivity metal such as aluminum which again contains passages for cooling fluid.

A Split Yoke Framework

In many expected use circumstances, it is very desirable to generate a discernible quadrupole magnetic field whose installed location and boundaries within the cavity volume of the arc chamber can be rotated 45 degrees from those field orientations and alignment described by the first and second embodiments previously herein. Attention is again directly to FIG. 10, FIG. 11 and FIG. 12 respectively—which show the magnetic flux lines of the installed quadrupole magnetic field for the first embodiment of the disclosure.

Thus, in order to achieve a desired 45 degree rotation change for the installed quadrupole magnetic field internally within the cavity volume of the arc chamber, two similarly-constructed split yoke frame sections are used together in combination as the magnetic field generating yoke subassembly—wherein each yoke frame section may be individually positioned in an anti-symmetric pattern directly adjacent to the exterior faces and sold walls of the arc chamber, as shown in FIG. 9.

The term ‘anti-symmetric’ is used here appropriately because the term ‘symmetry’ would imply that both yoke sections were installed with the same polarity; whereas, it may be necessary to reverse (alternate) the polarity of one yoke frame section in the subassembly.

Accordingly, as seen in FIG. 9, a partition barrier structure 360 may be made from aluminum alloy or other high conductivity metal, and separates atmosphere from vacuum. It comprises coolant passages 361, and three discrete cavity spaces 368a, 368b and 364 on the vacuum side.

Fitted into the partition barrier of the dividing partition barrier structure 360 are two discrete split-yoke frame sections 304a and 304b. These two frame sections have been fabricated separately; and when installed in (non-magnetic) partition barrier of the dividing partition of the partition barrier structure 360 may collectively constitute and result in the complete open implementation of the yoke subassembly 300. Each split-yoke section 304a and 304b comprises a pair of extended ferromagnetic poles implementing the pole 325N and 325S, connected to each other by a linear array of permanent magnets.

As illustrated by FIG. 9, one of the magnetized poles 325N in one magnetic pole construct 304a is purposefully placed on the interior face of the recess 368a, and may be individually located to become adjacently aligned with and fitted close to the front wall of the arc chamber 301; while pole 325S may be individually located to become adjacently aligned with and fitted close to the back wall of the arc chamber 301. The other oppositely located magnetic pole construct 304b may be reversed, and pole 325N may be aligned and fitted close to the back wall of the arc discharge chamber 1. The polarity may be reversed appropriately, as shown in FIG. 9.

Thus, when placed properly within the dividing partition barrier structure 360, the magnetic pole constructs 304a and 304b may encompass recess 364, the prepared space into which arc chamber 301 may be ultimately positioned; and the serial arrayed sequence of four discrete poles encircling the arc chamber 301 runs ‘N-S-N-S” in alternating polarity; and a discernible quadrupole magnetic field may be generated and installed within the internal cavity volume 310 of the arc chamber 301, the orientation of the installed quadrupole magnetic field then being rotated about 45 degrees when compared with those magnetic field orientations provided by the first and second embodiments.

Structural Alternations in the Arc Discharge Chamber

In this third alternative embodiment, it may be also necessary to reposition the disposition of the anode rod (or multiple anode rods), since these anodes may have lines of flux passing between them and the central null position in the installed quadrupole magnetic field.

Thus, as shown in FIG. 9, a centrally placed anode rod 302 (which may be now located closer to the solid back wall of the arc chamber) serves as a structurally sufficient relocation. If desired, additional anode rods can also be located approximately halfway up the each of the oppositely situated adjoining sidewalls of the arc chamber. Many other similar anode rod re-arrangements have been evaluated and can be devised which would operative properly and be functional for use.

Although shown as a rectangular prism-shaped construction in FIG. 9, the arc chamber overall internal configuration could well be cylindrical. Such a cylindrical-shaped arc chamber would bring those portions of the chamber's walls closer to the center; which in turn, would reduce the cavity volume in which ionization may be occurring.

However, the rectangular prism shape shown by FIG. 9 permits and in fact encourages a much simpler model for the third alternative embodiment. In this instance therefore, a supporting flange as part of the dividing partition barrier structure 360 for the two split-yoke sections 304a and 304b (which with base of the dividing partition barrier structure 360 constitute the complete implementation of the yoke subassembly 300) may be present. The supporting flange of the dividing partition barrier structure 360 may be a plate or flat collar structure formed of resilient material; and may include multiple water cooling conduits and passages 311.

Specific Applications for the Third Alternative Embodiment

In this third alternative embodiment, the ions exiting the open aperture of the arc chamber are directionally traveling normal to quadrupole magnetic field lines; and the installed magnetic field would be effective to block fast electrons from leaving the arc chamber. For this reason, therefore, this alternative embodiment may be of major value as an auxiliary source of un-accelerated cool plasma—e.g., as a plasma bridge for controlling surface charging and the potentials in the environment during ion beam processing with another source.

VII. Operational Variables, Parameters & Other Considerations for the Disclosure as a Whole

Temperature Variation Considerations

The power delivered into the arc chamber by the heat to the cathode, plus the heat to the plasma, may be several kilowatts. Arc currents may be 50 A per meter of arc chamber length, at 40V to 120V; so depending upon the dimensional size of the arc chamber box, a considerable amount of power may be deposited.

It is desirable when certain ion species are being generated that the arc chamber's back wall and two adjoining sidewalls run hot. For example, temperatures greater than 400 degrees C. are desirable for the reliable use of arsenic or phosphorus vapors, in order to prevent their condensation. The arc chamber walls may be made of graphite, tungsten, or molybdenum or other refractory metal, and may reach 1000 degrees C. This heat may be removed without overheating the wire winding coils or permanent magnets of the open yoke subassembly; so either a re-entrant structural base or an interposed trough-shaped heat shield of aluminum containing internal water passages may be used to remove the heat and separate the arc chamber box from the yoked magnetic pole arrangement.

For other species (e.g. oxygen and argon) it may be desirable to have cold arc chamber walls. It is also possible to make the arc chamber froth aluminum or other metals, incorporating water passages in the chamber to keep it cool. In each instance, a water-cooled metal wall may be Interposed between the arc discharge and the magnetic yoke, to keep the latter cool.

The Internal Configuration of the Arc Discharge Chamber

The internal configuration of the arc chamber box may be often rectangular, or cylindrical, or a hybrid shape which may be partly cylindrical, but has recesses surrounding the anode rods. For example, the configuration shown by FIG. 4 has an internal shape comprising a half-cylinder in the upper half of the figure, and a half-square in the lower half, and the anode rods occupy spaces near the two corners in this lower half of the figure.

The factors affecting this shape are: minimize the cross-sectional area, allow the anode rods to be shielded by the flux lines from the region of near-zero field, and allow the flux lines to be almost parallel to the wall where their curvature makes this possible, as this enhances the E×B drift velocity of the electrons and promotes uniform ionization, as discussed above. Other minor variations in shape for convenience, reinforcement, dimensional stability, or ease of manufacture, are envisaged.

Control of the Ion Beam Output

Electron energies of up to 120 eV may be needed to efficiently produce ions of some species; in other cases lower energies may be utilized. The anode voltage controls this energy.

The fraction of the generated ions which are successfully extracted may be largely determined by the ratio of the width of the exit slot to the circumference of the arc chamber, which may be about 3%. When ions hit the walls of the arc chamber, they have a high probability of being neutralized; and many species may then vaporize and return to the ionizing zone. Thus, a high percentage of the total gas supplied may end up as ionized beam, although each ion may have been through this cycle thirty or more times.

For certain ion species, e.g. boron ions from BF₃, the source gas may be a fluoride molecule, and in these cases the use of fluoride gases may improve output by etching the deposited wasted ions from the walls and returning them to the discharge. Adjusting the gas flow changes the fractions of different ion species.

The rate of generation of ions may be determined by the current of primary electrons, the flow rate of gas introduced into the arc chamber, the arc voltage (which determines the primary electron energy), and in some instances by other factors such as the maximum magnetic field strength and the wall temperature. The ribbon beam ion source 108 output may be regulated by comparing a desired parameter to a reference signal, to generate an error signal which may be used to adjust the power to the therm ionic cathode in a closed control loop.

Initially this control loop may adjust the cathode power to deliver a specific electron current, but it may be desirable once a beam is being delivered to regulate the total ion beam current. Once the control loop is maintaining a constant ion beam current, the voltages on the electrodes may be readily adjusted to minimize beam divergence, and the gas flow may be adjusted, for example to minimize pressure in the vacuum system while maintaining stable beam production, or to optimize yield of a specific ion species in the ion beam.

Ion Beam Formation

The extraction of ion species from the ribbon beam ion source 108 to form a beam is conventional, and typically uses an acceleration/deceleration electrode structure to prevent back-streaming of electrons. The ribbon beam ion source 108 may be biased positively from ground, at, for example, 20,000V to produce a 20 keV ion beam.

The ribbon beam ion source 108 assembly may be able to produce beams of hundreds of milli-amperes of ions at the energy determined by the potential applied to the arc chamber with respect to ground. The ion beam may be a fairly uniform ribbon-shaped stream whose breadth size (and Y1-axis dimension of the chamber) may be determined and limited only by the arbitrarily chosen length dimension of the arc discharge chamber; and frequently may be 1-2 meters or more in size. The beam width (and the X1-axis dimension of the exit slot) may be much narrower, typically only 2-3 millimeters and diverging at +/−2 degrees or so, assuming that the optics of the extraction electrodes are well designed.

The Introduction of a Gaseous Substance

The pre-chosen gaseous substance may be introduced through use of several uniformly distributed drilled inlet orifices into the internal cavity volume of the arc discharge chamber. These inlet drillings are openings designed and placed to avoid large pressure variations in the central ionization portion of the spatial cavity.

Gas flow may be measured and controlled by a commercially available thermal mass flow controller, at a flow rate which typically lies in the range of 1 sccm per 20 to 100 mm of inlet orifice length. Fine-tuning of the distribution of the gas flow can be used to correct non-uniformities in the beam current profile.

Variances of Cathode Material

The cathode material may be tungsten or a tungsten alloy. Because of the gases used in the internal spatial volume of the arc chamber, other chemical compositions and materials have a relatively short use life. Directly or indirectly heated cathodes may be used, as is today well-known in the technical field.

Particular Potentials

The entire implementation of the ribbon beam ion source 108 may be biased at a positive potential which defines the final ion energy, so that positive ions may be accelerated from the slot in the chamber toward ground potential.

For most uses a triode electrode arrangement comprising the arc chamber exit slot plus two additional electrodes (each comprising two connected halves) may be used, including a negatively biased electrode which may be required to suppress back-streaming electrons, as is well known in this art and shown in FIG. 2. Addition of an additional electrode between the arc chamber and the negatively biased electrode allows a wider range of control without using dynamically movable electrodes. The use of moving electrodes is common, but the required precision and thermal expansion problems would be formidable for such large systems as we are concerned with.

VIII. A Summary of the Distinctive Features and Traits Presented by the First, Second & Third Embodiments Collectively

Most emphatically, the ribbon beam ion source 108 provides the following characteristics and properties in every instance and embodiment:

1. There can be no magnetic field component existing along the direction or axis of the major linear length dimension for the arc discharge chamber. Instead, it may be essential that any generated magnetic or electric field may lie coplanar with a plane or axis normal (i.e., existing perpendicularly or at a 90-degree angle) to the major linear length dimension (and X1-axis) of the arc discharge chamber. There can be no exception to this critical requirement beyond small accidental variations and termination details at the ends; it is an inviolate rule and absolute condition for every embodiment of the ribbon beam ion source 108 without regard to any other features.

2. The installed magnetic field cross section may have a multipole profile, with a line of zero field located a short distance behind the exit aperture of the arc chamber. The field strength should increase more-or-less linearly with distance from this null field axis, but it is desirable that it stays relatively weak in the direction of the extracted beam. The best field profile satisfying this requirement may be a quadrupole field with a small admixture of a sextupole profile, which can be generated with just three poles. A quadrupole field requires that opposite poles be of the same type (e.g. north opposite north).

3. A multi-sided, open shaped yoke subassembly may be employed to satisfy the critical requirement of a primary electron trap assembly. Structurally for this purpose, at least three discrete ferromagnetic poles are individually positioned upon and spaced apart within an open yoke framework—a configured structural arrangement which may be to be fitted to and adjacently surround the exterior faces surfaces and measurable perimeter of the solid back wall and the oppositely-situated adjoining sidewalls of the arc discharge chamber. The open shaped yoke subassembly does not intrude into the space on the front side of the arc chamber where the beam may be extracted. The magnetic poles may lie parallel with the X1-axis, and the length dimension of the arc chamber.

4. The anode or anodes are rods aligned with the X1-axis, and extend over the entire length dimension of the arc chamber. The anodes are located where magnetic flux lines curve around them and separate them from the region where the magnetic field may be effectively null in strength.

5. To enhance trapping of primary electrons from the cathode while using relatively small and thus inexpensive magnetic field strengths, the electron trap assembly and the anodes are so oriented that the four magnetic cusps intersect arc chamber surfaces, which are at or slightly negative with respect to the thermionic cathode.

IX. A Representative & Exemplary Ion Implanter System

A representative and exemplary ion implanter system which uses the ribbon beam ion source 108 of the disclosure and which may be closely coupled to a new analyzing magnet suitable for processing Generation 8 flat panel displays may be described in detail below.

Flat panel displays for a number of different applications incorporate transistors in a film of low-temperature polysilicon deposited on a glass substrate to control the emission or transmission of light in each pixel. The substrates can be very large. The so-called Generation “8” displays require ion implantation into discrete panels which are about 2.2 m X 2.5 m in size. To dope these transistors in such panels, ion beams of phosphorus and boron particles, having ion energies in the range of 15 to 80 keV, at high and low currents are required. Expectations for beam current are 1 mA to 4 mA per cm of beam length; and higher current values would raise productivity. Also, the ion beam may be mass-analyzed to remove unwanted contaminants, such as hydrogen from the phosphine, and fluorine/fluorides from the boron.

Notably, it is very difficult to mass-analyze broad breath ribbon beams,—because the conventional sector magnet approach taught in text-books implicitly assumes that the gap space distance between the magnetic poles may be much smaller in measurable size than the other dimensions. However, if the beam breadth dimension may be now >2.2 meters in size, the pole gap distance may be at least as large, and the other magnet dimensions become impossibly large in size.

It is conventionally recognized that a number of improvements have been made, including those of Aoki, White, and Glavish. But, although all these improvements have made analysis of beams of considerable breadth possible, they all still conform to and obey the basic scaling laws that presume all of the following:

(a) The number of ampere turns to produce a given field may be proportional to the pole gap;

(b) The weight of the magnet may be roughly proportional to the square of the pole gap; and

(c) The extent of unwanted fringe fields and aberrations grows as the pole gap gets larger.

However, such additional magnetic analysis of an arbitrarily long dimensioned, large breadth beam by a conventional dipole magnet may be very difficult, and the required equipment may be massively large and expensive to obtain. Instead, an operative and practical system of ion purification may employ a uniquely structured magnetic analyzer device in which the generated magnetic fields are entirely confined and limited to the y-z plane alone.

Accordingly, the disclosure has described a system and process that enables implementation of a ribbon beam ion source for surface treatment of glass in a high-volume manufacturing environment as well as other products. Moreover, the disclosure has described a system and process that enables implementation of a ribbon beam ion source providing numerous benefits, applications, implementations, and/or the like.

The following are a number of nonlimiting EXAMPLES of aspects of the disclosure. One EXAMPLE includes: EXAMPLE 1. A treatment system that is configured to provide a vacuum environment such that an ion source may be operated and product may be transported within the vacuum environment with the ion source and attendant process includes at least two of the following features: a ribbon beam ion source such that the ion source provides energetic ions to bombard or implant into a product to modify a surface region of the product; a temperature control system that includes a heatsink configured to control a temperature of the product during ion bombardment by the ribbon beam ion source; a gas cushion system configured to provide a gas cushion to the product such that the gas cushion promotes heat transfer from the product to the heatsink; a product movement system configured to move the product through the treatment system past the ribbon beam ion source; a mounting system for the ribbon ion source allowing a distance from the source to the product to be configured and the angle between the source and the product to be configured to provide distance from source to product of two to twenty inches and to provide an incident angle of the ion beam to the product to be chosen as between thirty degrees and ninety degrees; and a system controller configured to control at least one the following: the gas cushion system, the ribbon beam ion source, the temperature control system, the heatsink, and the product movement system.

The above-noted EXAMPLE may further include any one or a combination of more than one of the following EXAMPLES: 2. The treatment system of any EXAMPLE herein, where: the treatment system is implemented as a glass surface treatment system; and the product includes glass. 3. The treatment system of any EXAMPLE herein, where the ribbon beam ion source is configured such that ion implantation alters physical properties of a glass surface to induce an anti-reflection (AR) effect. 4. The treatment system of any EXAMPLE herein, includes one or more gas injection ports configured to flow a gas between the glass and the heatsink to promote heat transfer between the glass and the heatsink. 5. The treatment system of any EXAMPLE herein, includes a roller system configured to move the glass, where the temperature control system is arranged between rollers of the roller system; and where the roller system is controlled by the system controller. 6. The treatment system of any EXAMPLE herein, includes at least one sensor configured to measure at least one of the following in components of the treatment system: voltage, current, power, temperature, pressure, flow, mass, optical reflectance, movement, and location. 7. The treatment system of any EXAMPLE herein, where the system controller utilizes signals from the at least one sensor that includes temperature of the glass as feedback for subsequent control of at least one the following: the gas cushion system, the ribbon beam ion source, the temperature control system, the heatsink, and the product movement system. 8. The treatment system of any EXAMPLE herein, where the system controller is configured to control a divergence of an ion beam of the ribbon beam ion source. 9. The treatment system of any EXAMPLE herein, where the system controller is configured to adjust plasma conditions in the ribbon beam ion source to utilize multiply-charged ions. 10. The treatment system of any EXAMPLE herein, where the ribbon beam ion source is configured to have a beam shape tunable divergence. 11. The treatment system of any EXAMPLE herein, where: the ribbon beam ion source is configured to have a triode electrode arrangement with each of the three electrodes being controlled independently; the ribbon beam ion source is configured to have a single slit architecture; and the ribbon beam ion source is configured to have a filament configured to provide electron generation through therm ionic emission. 12. The treatment system of any EXAMPLE herein, where the system controller is configured to control at least one of the following: a divergence of an ion beam, plasma conditions, an ion implant density, an ion implant depth, an ion beam divergence, an ion energy, an ion current, an ion power, an ion distribution, an implantation axis, an ion acceleration voltage, an ion dose, an atomic concentration of ions, and an implant thickness. 13. The treatment system of any EXAMPLE herein, includes power equipment includes at least one of following: high voltage power supplies, a high current filament supply, an alternating current (AC) power distribution, a process gas manifold, a controls system to support programmed and automated control of all components, and a dedicated safety circuit. 14. The treatment system of any EXAMPLE herein, where: the product includes glass; and the treatment system is configured to form at least one of the following: a nano-textured surface on the glass and a graded index of refraction in the glass. 15. The treatment system of any EXAMPLE herein, where the treatment system is configured to form at least one of the following: thin Ag for low-E windows, Diamond-Like Carbon (DLC) coatings, transparent conductive oxides, and surface modification. 16. The treatment system of any EXAMPLE herein, where the treatment system is configured to implement at least one of the following: ion milling, ion etching, cutting, and linear sputter deposition by ion beam sputter. 17. The treatment system of any EXAMPLE herein, where the ribbon beam ion source includes: an arc discharge chamber including a front wall which presents a slit for ion beam egress with the slit functioning as a first electrode in a triode extraction configuration; at least one thermionic cathode disposed within an internal cavity volume of said arc discharge chamber, each cathode terminal being configured to emit a stream of moving primary electrons; a controlled orifice configured to introduce a gaseous substance into the internal cavity volume of the arc discharge chamber; a triode extraction electrode located as, and in front of, the front wall of the arc discharge chamber; and a primary electron trap assembly configured to generate at least one magnetic field within the internal cavity volume of the arc discharge chamber. 18. The treatment system of any EXAMPLE herein, where the primary electron trap assembly includes: at least one anode; and a magnetic field generating yoke subassembly.

One EXAMPLE includes: EXAMPLE 19. A process for treating a product, the process for treating a product implementing a treatment system, the process for treating a product includes: implanting ions into a product to modify a portion of the product with a ribbon beam ion source; controlling a temperature of the product during ion implantation by the ribbon beam ion source with a temperature control system that includes a heatsink; providing a gas cushion to the product with a gas cushion system; moving the product through the treatment system past the ribbon beam ion source with a product movement system; and controlling with a system controller at least one the following: the gas cushion system, the ribbon beam ion source, the temperature control system, the heatsink, and the product movement system.

One EXAMPLE includes: EXAMPLE 20. A treatment system includes: a ribbon beam ion source that is configured to implant ions into a product to modify a portion of the product; a temperature control system that includes a heatsink configured to control a temperature of the product during ion implantation by the ribbon beam ion source; an air cushion system configured to provide an air cushion to the product; a product movement system configured to move the product through the treatment system past the ribbon beam ion source; and a system controller configured to control at least one the following: the air cushion system, the ribbon beam ion source, the temperature control system, the heatsink, and the product movement system.

The above-noted EXAMPLE may further include any one or a combination of more than one of the following EXAMPLES: 21. The treatment system of any EXAMPLE herein, where: the treatment system is implemented as a glass surface treatment system; and the product includes glass. 22. The treatment system of any EXAMPLE herein, where the ribbon beam ion source is configured such that ion implantation alters physical properties of a glass surface to induce an anti-reflection (AR) effect. 23. The treatment system of any EXAMPLE herein, includes one or more gas injection ports configured to flow a gas between the glass and the heatsink. 24. The treatment system of any EXAMPLE herein where: the temperature control system includes a border configured to touch the glass to aid in trapping the gas from the one or more gas injection ports in a glass gap; and the border includes a non-marring material. 25. The treatment system of any EXAMPLE herein, includes a roller system configured to move the glass, where the temperature control system is arranged between the roller system; and where the roller system is controlled by the system controller. 26. The treatment system of any EXAMPLE herein, includes at least one sensor configured to measure at least one of the following in components of the treatment system: voltage, current, power, temperature, pressure, flow, mass, optical reflectance, movement, and location. 27. The treatment system of any EXAMPLE herein, where the system controller utilizes signals from the at least one sensor as feedback for subsequent control of at least one the following: the air cushion system, the ribbon beam ion source, the temperature control system, the heatsink, and the product movement system. 28. The treatment system of any EXAMPLE herein, where the system controller utilizes signals from the at least one sensor that includes optical reflectance of a modified portion of the glass as feedback for subsequent control of at least one the following: the air cushion system, the ribbon beam ion source, the temperature control system, the heatsink, and the product movement system. 29. The treatment system of any EXAMPLE herein, where the system controller utilizes signals from the at least one sensor that includes temperature of the glass as feedback for subsequent control of at least one the following: the air cushion system, the ribbon beam ion source, the temperature control system, the heatsink, and the product movement system. 30. The treatment system of any EXAMPLE herein, includes a positioning assembly configured to move the ribbon beam ion source relative to the glass, where the system controller is configured to monitor the at least one sensor to measure movement of the ribbon beam ion source by the positioning assembly. 31. The treatment system of any EXAMPLE herein, where the system controller is configured to control a divergence of an ion beam of the ribbon beam ion source. 32. The treatment system of any EXAMPLE herein, where the system controller is configured to adjust plasma conditions in the ribbon beam ion source to utilize multiply-charged ions. 33. The treatment system of any EXAMPLE herein, includes a gas system configured to implement use of at least one gas to provide a variable depth implant of ions by the ribbon beam ion source. 34. The treatment system of any EXAMPLE herein, where the ribbon beam ion source is configured to have a beam shape tuneable divergence. 35. The treatment system of any EXAMPLE herein, where: the ribbon beam ion source is configured to have a triode electrode; the ribbon beam ion source is configured to have a single slit architecture; and the ribbon beam ion source is configured to have a filament configured to provide electron generation through thermionic emission. 36. The treatment system of any EXAMPLE herein, where the system controller is configured to control at least one of the following: a divergence of an ion beam, change a length of an ion beam, plasma conditions, an ion implant density, an ion implant depth, an ion beam breadth, an ion energy, an ion current, an ion power, an ion distribution, an implantation axis, an ion acceleration voltage, an ion dose, an atomic concentration of ions, and an implant thickness. 37. The treatment system of any EXAMPLE herein, includes power equipment includes at least one of following: high voltage power supplies, a high current filament supply, an alternating current (AC) power distribution, a process gas manifold, an EtherCAT (Ethernet for Control Automation Technology) PLC (Programmable logic controller) control, and a dedicated safety circuit. 38. The treatment system of any EXAMPLE herein, where: the product includes glass; and the treatment system is configured to form at least one of the following: a nano-textured surface on the glass and a graded index of refraction in the glass. 39. The treatment system of any EXAMPLE herein, where the treatment system is configured to form at least one of the following: thin Ag for low-E windows, Diamond-Like Carbon (DLC) coatings, TCOs, and surface activation. 40. The treatment system of any EXAMPLE herein, where the treatment system is configured to implement at least one of the following: ion milling, ion etching, cutting, and linear sputter deposition. 41. The treatment system of any EXAMPLE herein, where the ribbon beam ion source includes: an arc discharge chamber including a front wall which presents a slit for ion beam egress; at least one thermionic cathode disposed within an internal cavity volume of said arc discharge chamber, each cathode terminal being configured to emit a stream of moving primary electrons; a controlled orifice configured to introduce a gaseous substance into the internal cavity volume of the arc discharge chamber; a triode extraction electrode located externally to the slit in the front wall of the arc discharge chamber; and a primary electron trap assembly configured to generate at least one magnetic field within the internal cavity volume of the arc discharge chamber. 42. The treatment system of any EXAMPLE herein, where the primary electron trap assembly includes: at least one anode; and a magnetic field generating yoke subassembly.

One EXAMPLE includes: EXAMPLE 43.A process for treating a product, the process for treating a product implementing a treatment system, the process for treating a product includes: implanting ions into a product to modify a portion of the product with a ribbon beam ion source; controlling a temperature of the product during ion implantation by the ribbon beam ion source with a temperature control system that includes a heatsink; providing an air cushion to the product with an air cushion system; moving the product through the treatment system past the ribbon beam ion source with a product movement system; and controlling with a system controller at least one the following: the air cushion system, the ribbon beam ion source, the temperature control system, the heatsink, and the product movement system.

The above-noted EXAMPLE may further include any one or a combination of more than one of the following EXAMPLES: 44. The process for treating a product of any EXAMPLE herein, includes configuring the treatment system as a glass surface treatment system, where the product includes glass. 45. The process for treating a product of any EXAMPLE herein, includes configuring the ribbon beam ion source such that ion implantation alters physical properties of a glass surface to induce an anti-reflection (AR) effect. 46. The process for treating a product of any EXAMPLE herein, includes configuring one or more gas injection ports to flow a gas between the glass and the heatsink. 47. The process for treating a product of any EXAMPLE herein includes configuring the temperature control system with a border configured to touch the glass to aid in trapping the gas from the one or more gas injection ports in a glass gap, where the border includes a non-marring material. 48. The process for treating a product of any EXAMPLE herein, includes: moving the glass with a roller system, arranging the temperature control system between the roller system; and controlling the roller system with the system controller. 49. The process for treating a product of any EXAMPLE herein, includes implementing at least one sensor configured to measure at least one of the following in components of the treatment system: voltage, current, power, temperature, pressure, flow, mass, optical reflectance, movement, and location. 50. The process for treating a product of any EXAMPLE herein, includes utilizing signals from the at least one sensor with the system controller as feedback for subsequent control of at least one the following: the air cushion system, the ribbon beam ion source, the temperature control system, the heatsink, and the product movement system. 51. The process for treating a product of any EXAMPLE herein, includes utilizing signals from the at least one sensor that includes optical reflectance of a modified portion of the glass as feedback for subsequent control of at least one the following: the air cushion system, the ribbon beam ion source, the temperature control system, the heatsink, and the product movement system. 52. The process for treating a product of any EXAMPLE herein, includes utilizing signals from the at least one sensor that includes temperature of the glass as feedback for subsequent control of at least one the following: the air cushion system, the ribbon beam ion source, the temperature control system, the heatsink, and the product movement system. 53. The process for treating a product of any EXAMPLE herein, includes implementing a positioning assembly configured to move the ribbon beam ion source relative to the glass, where the system controller is configured to monitor the at least one sensor to measure movement of the ribbon beam ion source by the positioning assembly. 54. The process for treating a product of any EXAMPLE herein, includes controlling a divergence of an ion beam of the ribbon beam ion source with the system controller. 55. The process for treating a product of any EXAMPLE herein, includes adjusting plasma conditions with the system controller in the ribbon beam ion source to utilize multiply-charged ions. 56. The process for treating a product of any EXAMPLE herein, includes implementing a gas system configured to use of at least one gas to provide a variable depth implant of ions by the ribbon beam ion source. 57. The process for treating a product of any EXAMPLE herein, includes configuring the ribbon beam ion source to have a beam shape tuneable divergence. 58. The process for treating a product of any EXAMPLE herein, where: the ribbon beam ion source is configured to have a triode electrode; the ribbon beam ion source is configured to have a single slit architecture; and the ribbon beam ion source is configured to have a filament configured to provide electron generation through thermionic emission. 59. The process for treating a product of any EXAMPLE herein, includes controlling with the system controller at least one of the following: a divergence of an ion beam, change a length of an ion beam, plasma conditions, an ion implant density, an ion implant depth, an ion beam breadth, an ion energy, an ion current, an ion power, an ion distribution, an implantation axis, an ion acceleration voltage, an ion dose, an atomic concentration of ions, and an implant thickness. 60. The process for treating a product of any EXAMPLE herein, includes implementing power equipment includes at least one of following: high voltage power supplies, a high current filament supply, an alternating current (AC) power distribution, a process gas manifold, an EtherCAT (Ethernet for Control Automation Technology) PLC (Programmable logic controller) control, and a dedicated safety circuit. 61. The process for treating a product of any EXAMPLE herein, where: the product includes glass; and the process for treating forms at least one of the following: a nano-textured surface on the glass and a graded index of refraction in the glass. 62. The process for treating a product of any EXAMPLE herein, where the process for treating forms at least one of the following: thin Ag for low-E windows, Diamond-Like Carbon (DLC) coatings, TCOs, and surface activation. 63. The process for treating a product of any EXAMPLE herein, where the process for treating implements at least one of the following: ion milling, ion etching, cutting, and linear sputter deposition. 64. The process for treating a product of any EXAMPLE herein, where the ribbon beam ion source includes: an arc discharge chamber including a front wall which presents a slit for ion beam egress; at least one thermionic cathode disposed within an internal cavity volume of said arc discharge chamber, each cathode terminal being configured to emit a stream of moving primary electrons; a controlled orifice configured to introduce a gaseous substance into the internal cavity volume of the arc discharge chamber; a triode extraction electrode located externally to the slit in the front wall of the arc discharge chamber; and a primary electron trap assembly configured to generate at least one magnetic field within the internal cavity volume of the arc discharge chamber. 65. The process for treating a product of any EXAMPLE herein, where the primary electron trap assembly includes: at least one anode; and a magnetic field generating yoke subassembly.

As may be appreciated by those skilled in the art, the illustrated structure is a logical structure and not a physical one. Accordingly, the illustrated modules can be implemented by employing various hardware and software components. In addition, two or more of the logical components can be implemented as a single module that provides functionality for both components. In one aspect, the components are implemented as software program modules.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the disclosure. The term “and/or” includes any and all combinations of one or more of the associated listed items.

The terminology used herein is for the purpose of describing particular aspects only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Aspects of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical aspects of the disclosure and, although specific terms are employed, they are used in a generic and descriptive sense only and not for purposes of limitation, the scope of the disclosure being set forth in the following claims.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure. In this regard, the various aspects, features, components, elements, modules, arrangements, circuits, and the like are contemplated to be interchangeable, mixed, matched, combined, and the like. In this regard, the different features of the disclosure are modular and can be mixed and matched with each other.

The disclosure may be implemented in any type of computing devices, such as, e.g., a desktop computer, personal computer, a laptop/mobile computer, a personal data assistant (PDA), a mobile phone, a tablet computer, cloud computing device, and/or the like, with wired/wireless communications capabilities via the communication channels.

Further in accordance with various aspects of the disclosure, the methods described herein are intended for operation with dedicated hardware implementations and/or computing devices including, but not limited to, PCs, PDAs, semiconductors, application specific integrated circuits (ASIC), programmable logic arrays, cloud computing devices, and other hardware devices constructed to implement the methods described herein.

It should also be noted that the software implementations of the disclosure as described herein are optionally stored on a tangible storage medium, such as: a magnetic medium such as a disk or tape; a magneto-optical or optical medium such as a disk; or a solid state medium such as a memory card or other package that houses one or more read-only (non-volatile) memories, random access memories, or other re-writable (volatile) memories. A digital file attachment to email or other self-contained information archive or set of archives is considered a distribution medium equivalent to a tangible storage medium. Accordingly, the disclosure is considered to include a tangible storage medium or distribution medium, as listed herein and including art-recognized equivalents and successor media, in which the software implementations herein are stored.

Additionally, the various aspects of the disclosure may be implemented in a non-generic computer implementation. Moreover, the various aspects of the disclosure set forth herein improve the functioning of the system as is apparent from the disclosure hereof. Furthermore, the various aspects of the disclosure involve computer hardware that it specifically programmed to solve the complex problem addressed by the disclosure. Accordingly, the various aspects of the disclosure improve the functioning of the system overall in its specific implementation to perform the process set forth by the disclosure and as defined by the claims.

This disclosure incorporates by reference U.S. Pat. No. 9,711,318 to Nicholas White in its entirety.

The computer may include at least one processing element, typically a central processing unit (CPU), and some form of memory. The processing element may carry out arithmetic and logic operations, and a sequencing and control unit may change the order of operations in response to stored information. The computer may include peripheral devices that may allow information to be retrieved from an external source, and the result of operations saved and retrieved.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

What is claimed is:

1. A treatment system that is configured to provide a vacuum environment such that an ion source may be operated and product may be transported within the vacuum environment with the ion source and attendant process comprising at least two of the following features:
a ribbon beam ion source such that the ion source provides energetic ions to bombard or implant into a product to modify a surface region of the product;
a temperature control system that comprises a heatsink configured to control a temperature of the product during ion bombardment by the ribbon beam ion source;
a gas cushion system configured to provide a gas cushion to the product such that the gas cushion promotes heat transfer from the product to the heatsink;
a product movement system configured to move the product through the treatment system past the ribbon beam ion source;
a mounting system for the ribbon ion source allowing a distance from the source to the product to be configured and the angle between the source and the product to be configured to provide distance from source to product of two to twenty inches and to provide an incident angle of the ion beam to the product to be chosen as between thirty degrees and ninety degrees; and
a system controller configured to control at least one the following: the gas cushion system, the ribbon beam ion source, the temperature control system, the heatsink, and the product movement system.

2. The treatment system of claim 1, wherein:
the treatment system is implemented as a glass surface treatment system; and
the product comprises glass.

3. The treatment system of claim 2, wherein the ribbon beam ion source is configured such that ion implantation alters physical properties of a glass surface to induce an anti-reflection (AR) effect.

4. The treatment system of claim 2, further comprising one or more gas injection ports configured to flow a gas between the glass and the heatsink to promote heat transfer between the glass and the heatsink.

5. The treatment system of claim 2, further comprising a roller system configured to move the glass,
wherein the temperature control system is arranged between rollers of the roller system; and
wherein the roller system is controlled by the system controller.

6. The treatment system of claim 2, further comprising at least one sensor configured to measure at least one of the following in components of the treatment system: voltage, current, power, temperature, pressure, flow, mass, optical reflectance, movement, and location.

7. The treatment system of claim 6, wherein the system controller utilizes signals from the at least one sensor that comprise temperature of the glass as feedback for subsequent control of at least one the following: the gas cushion system, the ribbon beam ion source, the temperature control system, the heatsink, and the product movement system.

8. The treatment system of claim 1, wherein the system controller is configured to control a divergence of an ion beam of the ribbon beam ion source.

9. The treatment system of claim 1, wherein the system controller is configured to adjust plasma conditions in the ribbon beam ion source to utilize multiply-charged ions.

10. The treatment system of claim 1, wherein the ribbon beam ion source is configured to have a beam shape tunable divergence.

11. The treatment system of claim 1, wherein:
the ribbon beam ion source is configured to have a triode electrode arrangement with each of the three electrodes being controlled independently;
the ribbon beam ion source is configured to have a single slit architecture; and
the ribbon beam ion source is configured to have a filament configured to provide electron generation through therm ionic emission.

12. The treatment system of claim 1, wherein the system controller is configured to control at least one of the following: a divergence of an ion beam, plasma conditions, an ion implant density, an ion implant depth, an ion beam divergence, an ion energy, an ion current, an ion power, an ion distribution, an implantation axis, an ion acceleration voltage, an ion dose, an atomic concentration of ions, and an implant thickness.

13. The treatment system of claim 1, further comprising power equipment comprising at least one of following: high voltage power supplies, a high current filament supply, an alternating current (AC) power distribution, a process gas manifold, a controls system to support programmed and automated control of all components, and a dedicated safety circuit.

14. The treatment system of claim 1, wherein:
the product comprises glass; and
the treatment system is configured to form at least one of the following: a nano-textured surface on the glass and a graded index of refraction in the glass.

15. The treatment system of claim 1, wherein the treatment system is configured to form at least one of the following: thin Ag for low-E windows, Diamond-Like Carbon (DLC) coatings, transparent conductive oxides, and surface modification.

16. The treatment system of claim 1, wherein the treatment system is configured to implement at least one of the following: ion milling, ion etching, cutting, and linear sputter deposition by ion beam sputter.

17. The treatment system of claim 1, wherein the ribbon beam ion source comprises:
an arc discharge chamber including a front wall which presents a slit for ion beam egress with the slit functioning as a first electrode in a triode extraction configuration;
at least one thermionic cathode disposed within an internal cavity volume of said arc discharge chamber, each cathode terminal being configured to emit a stream of moving primary electrons;
a controlled orifice configured to introduce a gaseous substance into the internal cavity volume of the arc discharge chamber;
a triode extraction electrode located as, and in front of, the front wall of the arc discharge chamber; and
a primary electron trap assembly configured to generate at least one magnetic field within the internal cavity volume of the arc discharge chamber.

18. The treatment system of claim 17, wherein the primary electron trap assembly comprises:
at least one anode; and
a magnetic field generating yoke subassembly.

19. A process for treating a product, the process for treating a product implementing a treatment system, the process for treating a product comprising:
implanting ions into a product to modify a portion of the product with a ribbon beam ion source;
controlling a temperature of the product during ion implantation by the ribbon beam ion source with a temperature control system that comprises a heatsink;
providing a gas cushion to the product with a gas cushion system;
moving the product through the treatment system past the ribbon beam ion source with a product movement system; and
controlling with a system controller at least one the following: the gas cushion system, the ribbon beam ion source, the temperature control system, the heatsink, and the product movement system.
